(19) United States
(12) Patent Application Publication
(10) Pub. No.: US 2023/0360898 A1
(43) Pub. Date: Nov. 9, 2023

(54) IMPULSE POWER SUPPLY FOR COMPACT SYSTEM FOR COUPLING RADIO FREQUENCY POWER DIRECTLY INTO RADIO FREQUENCY LINACS

(71) Applicant: Starfire Industries LLC, Champaign, IL (US)

(72) Inventors: Robert A. Stubbers, Savoy, IL (US); Brian E. Jurczyk, Champaign, IL (US); Ian F. Haehnlein, Champaign, IL (US); Elizabeth Atkinson, Champaign, IL (US); Thomas J. Houlahan, JR., Urbana, IL (US)

(21) Appl. No.: 18/143,597

(22) Filed: May 4, 2023

Related U.S. Application Data
(60) Provisional application No. 63/338,090, filed on May 4, 2022.

(51) Int. Cl. H01J 37/34; H01J 37/32; C23C 14/35; C23C 14/34; C23C 14/54

(52) U.S. Cl. CPC H01J 37/3467; H01J 37/3405; H01J 37/32146; C23C 14/35; C23C 14/3485; C23C 14/54; H01J 2237/332

(57) ABSTRACT

A system and associated method are described. The system includes a controlled power supply for generating electrical pulses for a plasma discharge source. The controlled power supply includes an output pulse rail, a direct current power source, and energy storage capacitors, coupled to the direct current power source. The energy storage capacitors are configured to supply: a main negative rail voltage, a positive kick rail voltage, and at least one intermediate rail voltage. A controlled pulse power transistor group includes: a plurality of transistors interposed between the energy storage capacitors and the output pulse rail, and a transmission control configured to control power transmission. The transmission control is configured to specify a positive kick pulse waveform defined by user-specified parameters that configure operation of the plurality of transistors to control timing and voltage of the positive kick rail voltage and the at least one intermediate rail voltage.

### CROSS-REFERENCE TO RELATED APPLICATIONS

This application is a non-provisional of, and claims priority to U.S. Provisional Application No. 63/338,090, filed May 4, 2022, entitled “IMPULSE POWER SUPPLY FOR COMPACT SYSTEM FOR COUPLING RADIO FREQUENCY POWER DIRECTLY INTO RADIO FREQUENCY LINACS” the contents of which are expressly incorporated by reference in their entirety, including any references contained therein.

This application relates to U.S. application Ser. No. 15/803,320, filed Nov. 3, 2017 (U.S. Pat. No. 10,624,199), entitled “A COMPACT SYSTEM FOR COUPLING RF POWER DIRECTLY INTO RF LINACS,” which is a non-provisional of U.S. Provisional Application Ser. No. 62/416,900, filed Nov. 3, 2016, entitled “A COMPACT SYSTEM FOR COUPLING RF POWER DIRECTLY INTO RF LINACS,” the contents of each of which are expressly incorporated herein by reference in their entirety, including any references therein.

This application relates to U.S. application Ser. No. 16/006,357, filed on Jun. 12, 2018, entitled “PULSED POWER MODULE WITH PULSE AND ION FLUX CONTROL FOR MAGNETRON SPUTTERING,” which is a non-provisional of U.S. Provisional Application Ser. No. 62/518,362, filed Jun. 12, 2017, entitled “PULSED POWER MODULE WITH PULSE AND ION FLUX CONTROL FOR MAGNETRON SPUTTERING,” the contents of each of which are expressly incorporated herein by reference in their entirety, including any references therein.

This application relates to U.S. application Ser. No. 16/801,002, filed Feb. 25, 2020, and entitled “METHOD AND APPARATUS FOR METAL AND CERAMIC NANOLAYERING FOR ACCIDENT TOLERANT NUCLEAR FUEL, PARTICLE ACCELERATORS & AEROSPACE LEADING EDGES,” which is a non-provisional of U.S. Provisional Patent Application No. 62/810,230, filed on Feb. 25, 2019, entitled “METHOD AND APPARATUS FOR METAL AND CERAMIC NANOLAYERING FOR ACCIDENT TOLERANT NUCLEAR FUEL,” the contents of each of which are expressly incorporated herein by reference in their entirety, including any references therein.

### TECHNICAL FIELD

The disclosure generally relates to injecting power into accelerator devices, and more particularly to relatively compact high-power radio frequency linear accelerator (RF LINAC) systems.

### BACKGROUND OF THE INVENTION

High-power RF cavities, such as those found in an RF LINAC, require not only tremendous RF powers (on the order to 10's to 100's of kW and above), but also a vacuum environment to prevent arcing and sparking within the RF cavity due to the intense electric fields associated with such high powers. The RF power needed to reach a specific electric field within the resonant cavity is governed by the quality factor (Q) which is integral energy stored divided by energy lost per cycle. For resonant RF cavities, the formula reduces to

$$Q = \frac{\sqrt{\frac{L}{C}}}{{R}_{surface}} = {( \frac{Δ ω}{{ω}_{o}} )}^{- 1}$$

since the RF energy propagates along the surface and is a function of the surface resistance

$${R}_{surface} = \frac{1}{Conductivity \times Skin Depth}$$

that is proportional to the square root of RF frequency. Higher quality factor leads to higher efficiencies, higher achievable voltages and accelerating gradients. However, there are engineering tradeoffs in cavity design and operation since electrical skin depths are on the order of microns for GHz frequencies. RF cavities are typically electroplated with copper for lower surface resistance or constructed out of solid blocks of base material for room-temperature cavities.

Typically, RF power is coupled into a high-power RF cavity via a waveguide and a hermetic RF window. This approach, while viable at high power LINAC applications, requires additional hardware, which increases the cost, size and complexity of compact high power RF LINAC systems. An alternative approach to the one described above is to couple RF power directly into the RF cavity via an RF amplifier assembly mounted on, and with an output stage coupled directly to, the RF cavity. This approach is described in Swenson, U.S. Pat. No. 5,084,682. However, the inclusion of the entire vacuum tube (and its associated tuning elements) within the vacuum envelope has led to an inability to operate at high powers due to processes such as multipactoring. For this reason, as much as possible of the RF and biasing circuitry needs to be at atmospheric pressure. In addition to this constraint, problems arise in the structure described in Swenson due to high powers dissipated both in the antenna and in the anode of the vacuum tube if these structures are not actively cooled. Swenson's approach to mounting the RF amplifier in a high power RF LINAC is further complicated by a vacuum tube anode commonly being held at high voltage, which necessitates the careful selection of a coolant.

Moreover, in high-power impulse magnetron sputtering (HiPIMS) arrangements, a large current pulse is applied to a magnetron target that causes intense sputtering and formation of a target material rich plasma environment characterized by a high ionization fraction relative to neutral species of sputtered target material particles. In some HiPIMS pulse arrangements, a sputtering gas (e.g. argon) is rarefied and displaced, with sputtered target material (metal) exceeding the local gas density, into the self-sputtering regime. Obtaining a high ionization fraction with a dominant metal plasma during HiPIMS may facilitate novel material deposition regimes and process conditions not achievable through thermal sputtering.

By way of further background, in HiPIMS arrangements, sputtered metal ions are localized near a sputter target within a magnetic confinement region (magnetic trap). The application of a rapid voltage reversal (e.g., a Positive Kick) to the target electrode generates a transient voltage drop across the magnetic trap and accelerates ions away from the target electrode and, for example, towards a substrate to be coated or processed. Such voltage drop is referred to as a Short Kick phase and typically occurs within the first 20 microseconds after the application of the rapid voltage reversal. During a Long Kick phase, dense plasma diffuses towards the substrate that results in generating a local sheath potential along surfaces and further accelerates gas and metal ions onto the substrate. The present disclosure provides improvements to the above-mentioned aspects of known HiPIMS operation.

### SUMMARY OF THE INVENTION

A system is disclosed that includes a controlled power supply for generating electrical pulses for a plasma discharge source. The controlled power supply includes an output pulse rail, a direct current power source, and energy storage capacitors, coupled to the direct current power source. The energy storage capacitors are configured to supply via corresponding power rails: a main negative rail voltage, a positive kick rail voltage, and at least one intermediate rail voltage at a voltage amplitude between the main negative rail voltage and the positive kick rail voltage. The system further includes a controlled pulse power transistor group comprising: a plurality of transistors interposed between the energy storage capacitors and the output pulse rail, and a transmission control configured to control power transmission from the energy storage capacitors to the output pulse rail. The transmission control is configured to specify, in accordance with user-specified input, a positive kick pulse waveform. The positive kick pulse waveform is defined by user-specified parameters that configure operation of the plurality of transistors to control timing and voltage of: the positive kick rail voltage; and the at least one intermediate rail voltage.

The present disclosure is also directed to a method of operating the above system to carry out generation of an output power in accordance with a user-specified positive kick pulse waveform using the system disclosed herein.

Additional features and advantages of the invention will be made apparent from the following detailed description of illustrative examples that proceeds with reference to the accompanying figures.

### BRIEF DESCRIPTION OF THE DRAWINGS

While the appended claims set forth the features of the present invention with particularity, the invention, together with its objects and advantages, may be best understood from the following detailed description taken in conjunction with the accompanying drawings of which:

FIG. 1 is a schematic drawing of a system suitable for incorporating the features of the invention;

FIG. 2A depicts a cross-sectional view of a hermetic break sub-assembly element of the system schematically depicted in FIG. 1, including an RF antenna, socket interface, and vacuum flange termination;

FIG. 2B depicts an illustrative RF power amplifier, which is, for example, a compact planar triode structure;

FIG. 2C depicts sub-assemblies from FIGS. 2A and 2B arranged as a power amplifier assembly for the RF LINAC system schematically depicted in FIG. 1;

FIG. 3 depicts a cross-sectional view of the RF LINAC system including four power amplifier assemblies (depicted in FIG. 2C) attached to an RF LINAC cavity and a vacuum chamber containing the RF LINAC cavity;

FIG. 4 schematically depicts an equivalent electrical circuit diagram/model for the power amplifier assembly, in operation, depicted, by way of example, in FIG. 2C;

FIG. 5A is a photograph of the exterior of an RF LINAC cavity for a radiofrequency quadrupole accelerator;

FIG. 5B is a photograph of interior quadrants of an RF cavity formed by rigid attachment of four vane structures prior to surface modification and formation of a continuous RF seal;

FIG. 5C is prior art showing major-minor vane construction for an RFQ with alignment shims and RF seals at each interface;

FIG. 6A depicts a cross-sectional view of an illustrative example of surface modification, etching and deposition of thin films on a cavity;

FIG. 6B is a photograph of the example illustrated in FIG. 6A in operation for deposition of high-conductivity copper directly onto a mechanical RF seal;

FIG. 6C depicts a composite RF LINAC cavity comprised of one or more bulk substrate materials with one or more material coatings;

FIG. 6C depicts a composite RF LINAC cavity comprised of one or more bulk substrate materials with one or more material coatings;

FIG. 6D depicts an in-situ sputtering electrode emitting ions and neutral particles to coat one or more substrates;

FIG. 6E depicts a close up view of a composite RF LINAC cavity where a vane material is rigidly affixed to a vacuum housing with mechanical/thermal interface and the thin-film continuous coating serves as an electrical interface;

FIG. 7A depicts an axial internal view of a sputtering electrode emitting ions and neutrals to highlight internal coolant flow, magnetic assemblies and plasma generation on the exterior;

FIG. 7B depicts a cross sectional view of a sputtering electrode to highlight the relative rotation of the target material and magnetic assemblies;

FIG. 7C is a photograph of a 1.5-meter long sputtering electrode illustrative example with a magnetic field arranged to create a single serpentine dense plasma zone around the sputtering electrode;

FIG. 7D is a photograph of an illustrative example of the IMPULSE®+Super Kick™ for cleaning, etching and surface modification;

FIG. 7E is a photograph of an embodiment of the IMPULSE®+Positive Kick™ for implantation, intermixing, adhesion, stress control, morphology control, diffusion barriers and capping layers;

FIG. 7F is a photograph of a 6.3-mm diameter sputtering electrode example with a magnetic field arranged to create multiple dense plasma zones around the sputtering electrode that can be axially translated;

FIG. 8A depicts an illustration of the IMPULSE®+Positive Kick™ for conformal coating of substrates;

FIG. 8B is a photograph using the in-line cylindrical magnetron technology with IMPULSE®, Positive Kick™ and Super Kick™ for conformal thin-film copper coatings to replace conventional electroplating and wet electrochemistry for stainless steel cryogenic accelerator bellows;

FIG. 9A depicts an illustration of sputter target erosion and wear for narrow V trenches;

FIG. 9B depicts an illustration of sputter target erosion with relative movement between the dense plasma regions and sputter target material for uniform erosion;

FIG. 10 depicts a comparison between conventional DC sputtering, pulsed DC, traditional HiPIMS and IMPULSE®+Positive Kick™;

FIG. 11 depicts an illustration of the 1^{st} of 3 phases during an IMPULSE pulse operation—the Ultra-Fast HiPIMS phase;

FIG. 12 depicts an illustration of the 2^{nd} of 3 phases during IMPULSE operation—the Short Kick phase;

FIG. 13 depicts an illustration of the 3^{rd} of 3 phases during IMPULSE operation—the Long Kick phase;

FIG. 14 depicts an illustration of a continuous process using the IMPULSE®+Positive Kick™+Super Kick™ without breaking vacuum, interruptions or staging;

FIG. 15 is an oscilloscope waveform of a Cu sputtering plasma achieving 2 kA peak current in 20 microseconds during the Ultra-Fast HiPIMS phase with subsequent +200V positive pulse showing Short and Long Kick phases;

FIG. 16 is a photograph of an embodiment highlighting deposition and etching using the Positive Kick™ and Super Kick™;

FIG. 17A is an oscilloscope trace illustrating the ˜10-100 kHz RF-like modulation of the positive pulse to generate plasma with a positive RF bias;

FIG. 17B is a photograph of the Super Kick™ in etching mode for plasma generation;

FIG. 18 depicts a schematic representation of the thin-film deposition, etch and surface modification system with IMPULSE® pulse modules and power supplies;

FIG. 19 is an illustration of the structure zone diagram with two independent axes for effective temperature T* and effective sputter particle energy E* that are addressable with the IMPULSE® and Positive Kick™;

FIG. 20A is a photograph of the IMPULSE® 2-2 system;

FIG. 20B is a photograph of the IMPULSE® 20-20 system;

FIG. 21A is the prior art for electroplating stainless steel cryogenic bellows for RF accelerators;

FIG. 21B is the prior art for a superconducting RF accelerator section comprising multiple spools, bellows and RF cavities needing specific material properties;

FIG. 21C is the prior art showing RF power loss and thermal dissipation due to poor electrical conductivity with electroplated copper;

FIG. 22A is the prior art showing surface defects, corrosion, trapped material, inclusions and surface asperities in conventional copper electroplating leading to poor accelerator performance;

FIG. 22B is the prior art showing inclusions in electroplated copper by size and material impurity;

FIG. 23A is a photograph of a representative multilayer metal-insulator-metal stack deposited on a substrate with a barrier interface using the IMPULSE®+Positive Kick™ demonstrating surface smoothness and ability to control layer properties;

FIG. 23B is a scanning electron micrograph of a diamond-like carbon layer deposited with the IMPULSE®+Positive Kick™ technique;

FIG. 23C is a scanning electron micrograph of a diamond-like carbon layer deposited with conventional DC magnetron sputtering highlighting its porosity and voids;

FIG. 24A depicts snapshots of the plasma potential spatial profile for the representative Long Kick case where a vacuum chamber dominates in surface area over both the substrate and the smaller sputtering target, and the distance between the target and substrate is many mean-free paths-very little potential drop reaches the substrate for local conformality;

FIG. 24B depicts snapshots of the plasma potential spatial profile for the representative Long Kick case where the substrate is much larger in surface area than the sputtering target and vacuum chamber components are negligible, and the distance between the target and substrate is many mean free paths—a small potential drop reaches substrate for local conformality;

FIG. 24C depicts snapshots of the plasma potential spatial profile for the representative Long Kick case where the target is on the same order as the substrate area, the vacuum chamber components are negligible, and the distance between the target and substrate is small-nearly all of the potential drop appears on the substrate for excellent conformality of plasma bombardment;

FIG. 25A depicts an illustration of the cases represented in FIG. 24A-C for potential profiles with their corresponding ion energy distribution functions; and

FIG. 25B depicts an illustration of a case where an additional active bias voltage is applied to the substrate for additional ion bombardment energy;

FIG. 26 depicts an illustration for a precision fixturing jig to align and gap RFQ LINAC vanes;

FIG. 27A depicts an illustration of the surface current pathlength, interface losses and multipactoring stress for adjoining RF surfaces and structures for conventionally processed materials;

FIG. 27B depicts an illustration of a surface current pathlength, interface losses and multipactoring stress for adjoining RF surfaces and structures processed with the IMPULSE®+Positive Kick™ and Super Kick™ techniques;

FIG. 27C depicts an illustration of axial position along a cavity with regions of poor electrical contact due to macroscopic effects;

FIG. 28 depicts an illustration of challenges with vane alignment and gapping;

FIG. 29 is a graphical representation of a low-Q cavity requiring more input RF power required to meet cavity stored energy thresholds for particle acceleration and vane tip electric field variation risk;

FIG. 30 is a graphical illustration of a high-Q cavity processed with a precision alignment jig and coating processed with IMPULSE® techniques for lower RF power requirements and reduced vane tip variation to support higher axial accelerating gradients for overall compactness and power savings;

FIG. 31A is a graphical depiction of the three primary modes of operation for the Super Kick technique achieved via modulation of the Positive Kick including photographs showing representative plasma changes for the different modes;

FIG. 31B depicts an illustration of the three primary Super Kick modes with representative values for voltage amplitudes, pulse widths and repetition frequencies for RF-like plasma generation, high-energy ion etching suitable for insulating substrates, and energetic metal ion implant with stress control and densification;

FIG. 32 is an illustration of the prior art depicting prior sputtering technologies;

FIG. 33A is a prior art illustration depicting an example of turn-on jitter process variability under some conditions;

FIG. 33B is a prior art illustration showing the application of a strike pulse at the start of the main negative voltage waveform to accelerate plasma breakdown with increased chance for arc formation;

FIG. 33C provides an illustrative application of a Super Kick waveform to provide preionization immediately prior to the application of the main negative pulse;

FIG. 34A is an illustrative example of an RF-like modulation of voltage over the Super Kick pulse envelope to generate additional plasma for interaction with the substrate with an average voltage greater than zero;

FIG. 34B is an illustrative example of an RF-like modulation of voltage over the Super Kick pulse envelope to generate additional plasma for interaction with the substrate with an average voltage less than zero;

FIG. 35A is an illustrative example of the Super Kick waveform to promote deep ion etching of a substrate with an RF-like modulation of voltage to provide charge clearance via electron bombardment in the negative cycle to refresh the substrate surface for the next ion bombardment cycle;

FIG. 35B is an illustration depicting the ion energy distribution function at the substrate by modification of the super kick pulse envelope effective frequency;

FIG. 36 is a non-RF-like application of the Super Kick illustratively depicted for controlling the ion energy distributions for metal ions from the target sourced from the short kick phase and gas ions in a diffuse plasma sourced from the long kick phase;

FIG. 37A is an illustration depicting the RF-like application of the Super Kick for plasma and radical generation;

FIG. 37B provides additional illustrative detail on the application of the RF-like Super Kick pulse envelope after the termination of the main negative HiPIMS pulse including the enhanced plasma formation, radical and ion generation near the substrate, and low-energy ion bombardment;

FIG. 38A is an illustration depicting the RF-like application of the Super Kick for deep ion etching suitable for insulating substrates;

FIG. 38B provides additional illustrative detail on the application of the RF-like Super Kick pulse envelope after the termination of the main negative HiPIMS pulse with very high energy ion bombardment on the substrate for etching with AC-like electron charge clearance for insulating substrates;

FIG. 39A is an illustration depicting a non-RF application of the Super Kick for high-energy metal ion implantation and low-energy carrier gas ion shot-peening to manage film stress;

FIG. 39B provides additional illustrative detail on the application of the non-RF, multi-step Positive Kick pulse after the termination of the main negative HiPIMS pulse to accelerate metal ions from the magnetic trap while limiting the energy of carrier gas ions arriving at the substrate later in the Super Kick pulse envelope;

FIGS. 40A, 40B and 40C are high-level depictions of the sputtering system configured to support configurable generation of impulse power waveforms including Super Kick and the plasma effects near the substrate surface including ion/radical formation and sheath voltages under different Super Kick modes of operation;

FIG. 41A. is an illustration of a circuit topology used to achieve the user configurable Super Kick pulse generation with four discrete voltage rails (2 positive and 2 negative) with corresponding energy storage capacitors;

FIG. 41B is an illustration of a circuit topology used to achieve the user configurable Super Kick pulse generation with three discrete voltage rails (1 positive, 1 negative and 1 floating) with corresponding energy storage capacitors; and

FIG. 41C is an illustration showing parallel combinations of transistor switches in series used to achieve desired current, power, voltage and repetition rates.

### DETAILED DESCRIPTION OF THE DRAWINGS

The detailed description of the figures that follows is not to be taken in a limiting sense, but is made merely for the purpose of describing the principles of the described embodiments.

A structural assembly and system are described that, in operation, inject RF power directly into an accelerator, such as a radio frequency quadrupole (RFQ) LINAC, while placing both the RF power amplifier itself as well as the RF input circuitry and the biasing circuitry outside of the vacuum environment occupied by the LINAC cavity. A critical aspect of this disclosure is that it allows for the use of the LINAC cavity itself as the output stage of the amplifier, removing any need for transmission lines between the final amplification stage and the LINAC cavity. The described structural assembly arrangement exhibits multiple advantageous features. The arrangement mitigates the deleterious effects of multipactoring associated with placing elements associated with the RF power amplifier in a vacuum environment. Moreover, the arrangement enables inspecting/replacing the RF power amplifier without breaking the vacuum seal of the RF LINAC cavity.

A low capacitance hermetic HV break is of particular importance to the functionality of the RF power amplifier arrangement described herein. The low capacitance characteristic of the hermetic HV break (described in detail herein below) ensures a sufficiently low capacitance between the RF power amplifier's output stage and the LINAC cavity. By way of an illustrative example, the hermetic HV break is a piece of alumina ceramic (or other suitable dielectric material) joined, for example by brazing or other suitable metallic material bonding technique, to copper (or other suitable conductive material) at both ends.

A further aspect of illustrative examples is that both the RF power amplifier's output stage and the antenna are placed at the same DC potential as the LINAC system. Additionally, the illustrative examples provide a mechanism to directly and easily cool the amplifier and antenna elements via a flowing liquid (e.g. water) cooling loop. An illustrative example of this aspect of the disclosure would be to route the cooling loop through the antenna itself, mounted to the anode electrode at one end and ground at the other.

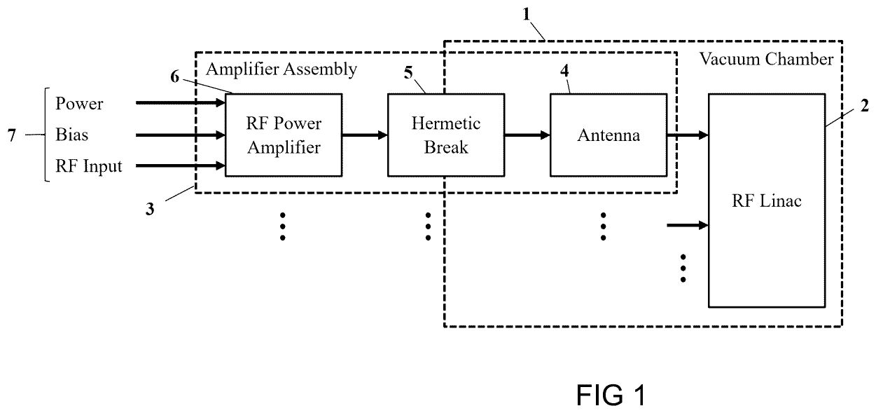

By way of an illustrative example, a system is described herein for injecting RF power directly into an RF LINAC (such as a radio frequency quadrupole (RFQ) accelerator), while placing both the RF power amplifier, the RF input circuitry, and the biasing circuitry outside of the vacuum environment occupied by the LINAC cavity. An illustrative example of such system is schematically depicted in FIG. 1.

Turning to FIG. 1, the primary components of the illustratively depicted system include: a vacuum chamber 1 containing a cavity 2 (e.g. one or more LINAC cavities), one or more of a power amplifier assembly 3 (including an RF power amplifier 6, a hermetic break 5, and an antenna 4) directly coupled to the cavity 2 structure, an electronic circuit interface including a set of inputs 7. The set of inputs 7 of the electronic circuit interface are configured to provide power, bias voltages/currents, and sufficiently high-power radio frequency energy to the one or more of the power amplifier assembly 3. The received radio frequency energy is amplified by the one or more of the power amplifier assembly 3 for transmission into the cavity 2 structure.

By way of further explanation/definition, “directly coupled”, as used above to describe the structural relationship between the power amplifier assembly 3 and the cavity 2, is defined as an electrical energy coupling relationship such that there is a negligible power transmission line between the power amplifier assembly 3 output interface and the cavity 2 structure. In the illustrative example, such direct coupling is achieved by the power amplifier assembly 3 having the hermetic break 5 barrier between the antenna 4 (which couples to the cavity 2 and is held at vacuum) and the RF power amplifier 6 (operating at atmospheric pressure).

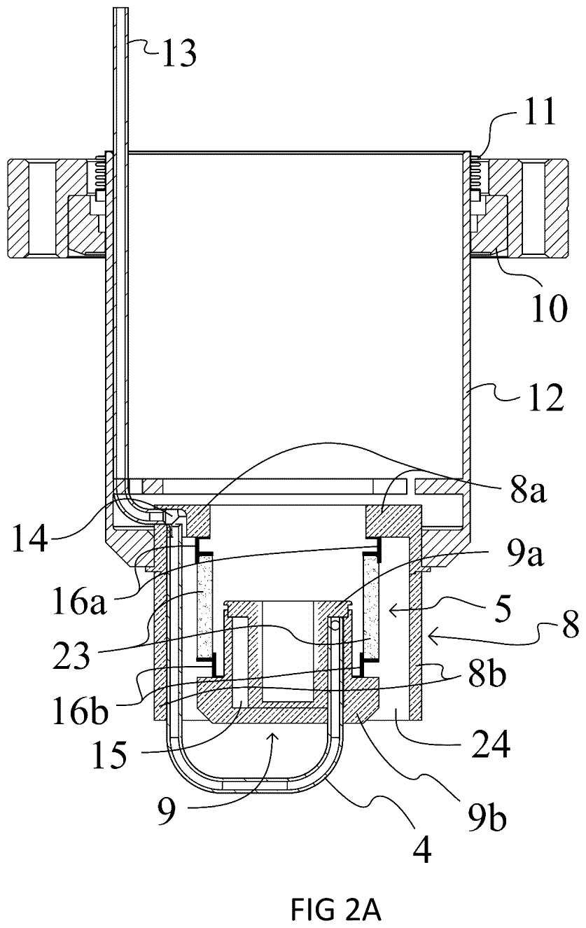

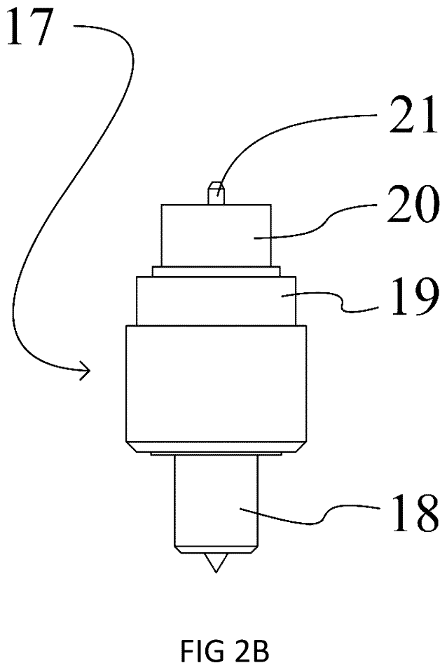

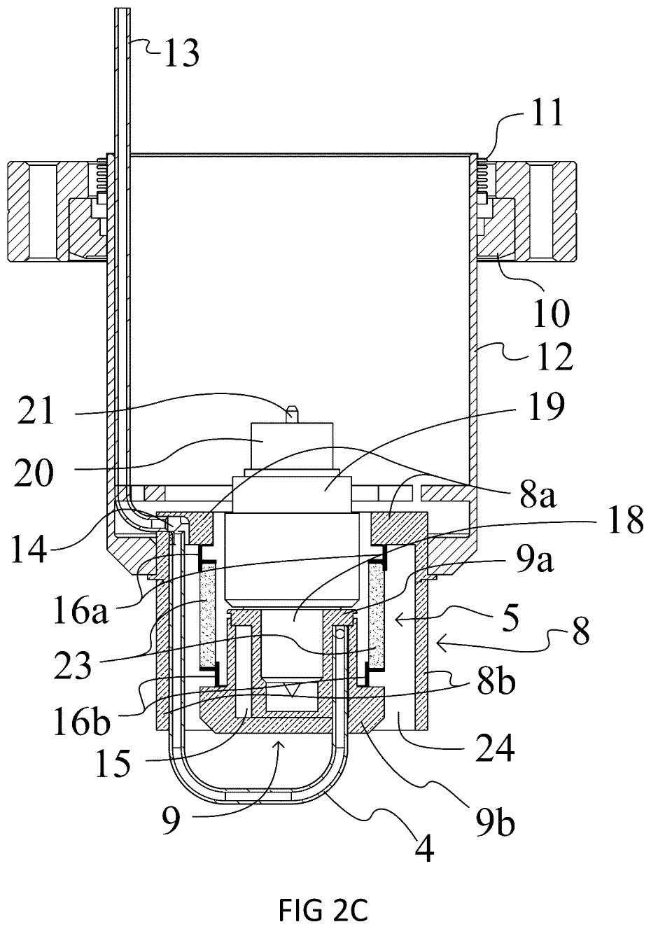

By way of an illustrative example, FIG. 2C depicts a power amplifier assembly that comprises two sub-assemblies. Each of the two sub-assemblies is depicted, by way of further particular example, in FIGS. 2A and 2B. FIG. 2A depicts a sub-assembly including the hermetic break 5. Thereafter, FIG. 2B illustratively depicts, by way of example, an example of the RF power amplifier 6 sub-assembly, in the form of a compact planar triode sub-assembly 17.

Turning to FIG. 2A, the sub-assembly including the hermetic break 5 will now be described by way of a detailed example. By way of illustrative example, the hermetic break 5 is generally cylindrical. The hermetic break 5 includes a dielectric body 23 that is generally cylindrical in shape and made of, for example, a ceramic material. The hermetic break 5 also includes, at opposing ends, the first conductive material 16a and the second conductive material 16b. In the illustrative example, the first conductive material 16a and the second conductive material 16b are generally ring-shaped and occupy the ends of the generally cylindrically shaped dielectric body 23 of the hermetic break 5. The sub-assembly illustratively depicted in FIG. 2A also includes a socket interface 9 to which the output of the RF power amplifier 6 is connected. Turning briefly to FIG. 2B, a suitable structure, a compact planar triode (CPT) 17, for connecting the output of the RF power amplifier 6 to the hermetic break 5 is depicted. With continued reference to both FIGS. 2A and 2B, the CPT 17 is attached at an anode electrode 18 (also referred to as a plate electrode) to the socket interface 9 of the sub-assembly containing the hermetic break 5 structure.

With continued reference to FIG. 2A, the sub-assembly including the hermetic break 5 also includes a fixed potential electrode 8 to which the antenna 4 is connected. The fixed potential electrode 8, by way of example, is also generally cylindrically shaped. Thus, in the illustrative example, a generally cylindrical space 24 is formed between the fixed potential electrode 8 and the dielectric body 23 of the hermetic break 5. The antenna 4, which occupies an area within an approximate range of 0.1 in² to 5 in², is also connected to the socket interface 9 electrode. Due to high currents involved in operation of the illustrative LINAC system, the antenna 4, the socket interface 5, and the fixed potential electrode 8 are all made from, or at least coated with a sufficiently thick layer of, a high-conductivity material, such as copper. The term “sufficiently thick” here is defined as being equal to or greater than one skin depth at the intended operating frequency of the LINAC system. In conjunction with the cavity 2, the above-described conductive structures determine/establish an effective electrical impedance (Z1) observed from the output interface of the RF power amplifier 6.

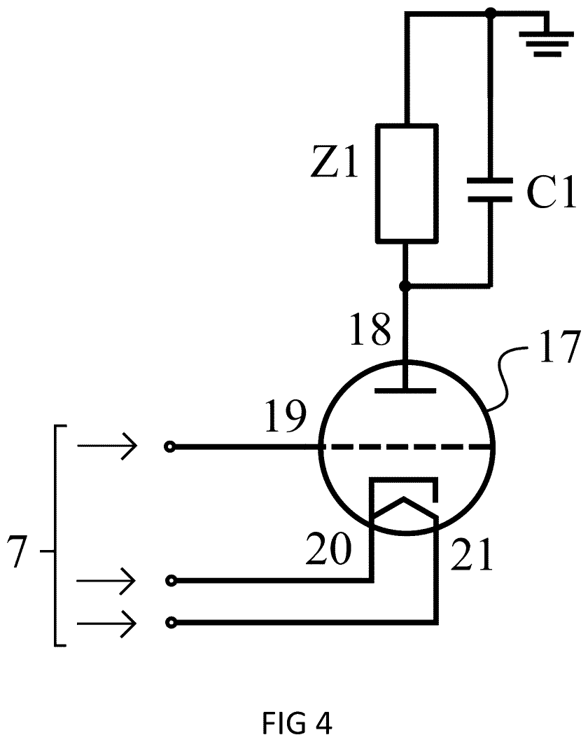

With continued reference to FIG. 2A, the hermetic break 5 is physically connected, at the first conductive material 16a and the second conductive material 16b to the socket interface 9 (provided in the illustrative example as two physically joined pieces 9a and 9b) and the fixed potential electrode 8 (provided in the illustrative example as two physically joined pieces 8a and 8b). The electrically insulating ceramic material of the dielectric body 23 provides a high-voltage break point between the RF output of the RF power amplifier 6, received via the socket interface 9, and the fixed potential electrode 8. The hermetic break 5 also exhibits a characteristic of a sufficiently low interelectrode capacitance, which manifests electronically as a capacitive load C1 in parallel with the load Z1 provided by the combination of the antenna 4 and the cavity 2. The above-described electrical circuit characteristics of the hermetic break 5 are summarized in the effective electrical circuit model of the system schematically depicted in FIG. 4.

By way of further explanation/definition, a “sufficiently low” interelectrode capacitance is defined such that the inverse of the interelectrode capacitance is greater than or equal to the angular frequency of the RF input multiplied by the magnitude of the antenna impedance. In the illustrative example depicted in FIG. 2A, the hermetic break 5 high-voltage break characteristic is carried out by the first conductive material 16a and the second conductive material 16b being joined to the dielectric body 23 by two ceramic-to-metal seals (e.g. alumina-to-copper joints achieved via brazing or diffusion bonding), where each one of the two ceramic-to-metal seals is located at an end of the generally cylindrical dielectric body 23. The metal sides of each joint, which are formed respectively by the first conductive material 16a and the second conductive material 16b, have a mechanical stress-relieving structural characteristic/feature 16 to account for differences in coefficients of thermal expansion between the two dissimilar materials (metal and ceramic) of the hermetic break 5 and thereby facilitate reliable bonding. A variety of insulator break and hermetic sealing configurations are contemplated for signally coupling the RF amplifier output with the cavity structure and vacuum chamber. In a particular illustrative example, directly joining high-conductivity copper (16a and 16b) to the ceramic material (23) yields superior RF power transmission capability-compared to a traditional Kovar to ceramic braze process-avoiding a potentially difficult/challenging further step of subsequently coating exposed metal surfaces in a high-conductivity material, such as copper. While shown as a separate physical feature in FIG. 2A, it is noted that in other illustrative examples the first conductive material 16a may be an integral part of the fixed potential electrode 8 structure. Likewise, the second conductive material 16b may be an integral part of the socket interface 9 structure.

When the antenna 4 configuration is a loop antenna structure, as is the case in the example illustratively depicted in FIG. 2A, the antenna 4 may be constructed from hollow tubing though which coolant may be controllably passed to achieve desired temperature control of system components. A coolant input/output structure 13 is depicted in FIG. 2A. The coolant input/output structure 13 is connected to the antenna 4 (a hollow tube structure) via a set of two channels 14 that pass through the fixed potential electrode 8, into which the coolant input/output structure 13 and the antenna 4 tubes are inserted and then welded, brazed, epoxied or otherwise sealed. Further, a hollow cavity 15 within the socket interface 9 for coolant flow allows for more efficient cooling of the RF power amplifier 6.

In accordance with the illustrative example depicted in FIG. 2A, a ConFlat (CF) flange 10 may be used in conjunction with a bellows 11 to ensure that structural interfaces of the RF power amplifier assembly can be mated to the vacuum chamber while remaining tolerant to manufacturing errors in either the power amplifier assembly 3, the cavity 2, or the vacuum chamber 1 that would require the power amplifier assembly 3 to maintain some variability/adjustability in its positioning.

An alternative to the above approach is to make the vacuum seal permanent instead of demountable. This could, for example, be accomplished by replacing the CF flange 10 by a welded, brazed, or epoxied joint. The fixed potential electrode 8 and the bellows 11 are connected via a cylindrical housing 12, whose function is simply to provide a structurally sound vacuum barrier between where the power amplifier assembly 3 mates to the cavity 2 and mates to the vacuum chamber 1.

Regardless of any specific illustrative example, with the RF power amplifier 6 located on the air-side of the vacuum chamber 1, deleterious effects such as multipactoring and surface flashover can be minimized or even eliminated for the power conditions of a LINAC or other RF cavity structure. This is a significant improvement over the current state of the art. Power dissipation and cooling can further be managed external to the vacuum environment.

Further, with the illustrative examples, the RF power amplifier 6 of the illustrative RF power amplifier assembly, which may comprise several instances of the RF power amplifier 6, can be rapidly changed out for programmed maintenance, or at end of life, without venting the vacuum chamber 1. In the illustrative example depicted in FIG. 2C, this is done by removing the electronic interface through which inputs 7 are applied, and then removing the RF amplifying element 6, which is replaced before re-inserting the physical interface for the inputs 7. In the illustrative example depicted in FIG. 2C, the socket interface 9 includes a threaded socket, into which the threaded anode electrode 18 of the CPT 17 is screwed. Furthermore, in the illustrative example provided in FIG. 2B, a grid electrode 19 a cathode electrode 20 and a filament electrode 21 of the CPT 17 are connected to a connector interface providing the inputs 7.

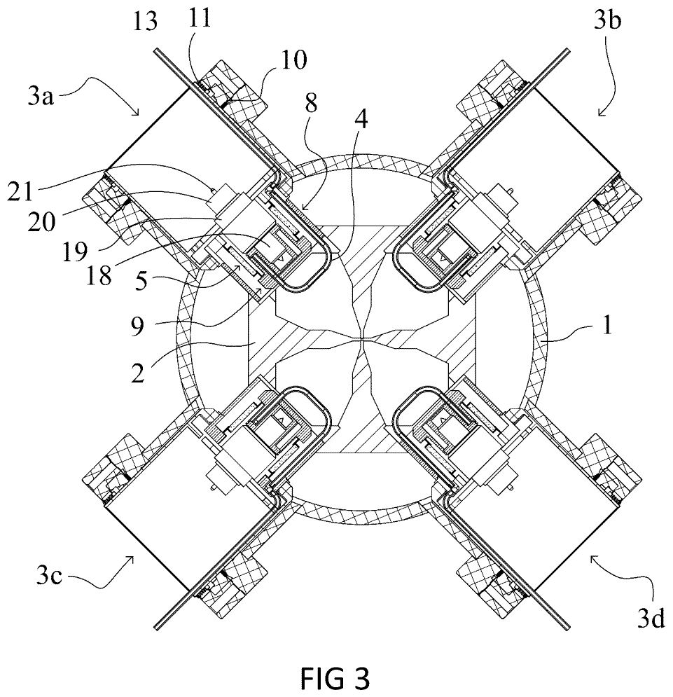

Turning to FIG. 3, an illustrative example of the disclosed system/apparatus includes the integration of 4 to 12 power amplifiers onto a radiofrequency quadrupole accelerator to produce particle beams at energies in an approximate range of 2 to 5 MeV. An illustrative cross section is shown in FIG. 3 showing four power amplifier assemblies 3a, 3b, 3c, and 3d symmetrically arranged around the cavity 2. Such systems could be used for the generation of neutrons, gamma-rays and energetic ions for various scientific, medical or industrial purposes. Integrating the power amplifiers directly onto the radiofrequency quadrupole accelerator eliminates entire racks of equipment, RF power combining equipment, waveguides and power conditioning hardware. Since the RFQ cavity is a power combining cavity in its own nature, the illustratively depicted/described system/apparatus uses the power combining cavity for the dual uses of: (1) combining multiple amplifiers for use on a single LINAC system, and simultaneously (2) setting up electromagnetic fields for accelerating particles to high energies.

It can thus be seen that a new and useful system for coupling/injecting RF power into RF LINACs has been described. In view of the many possible embodiments to which the principles of this disclosure may be applied, it should be recognized that the examples described herein with respect to the drawing figures are meant to be illustrative only and should not be taken as limiting the scope of the disclosure. For example, those of skill in the art will recognize that the elements of the illustrative examples depicted in functional blocks and depicted structures may be implemented in a wide variety of electronic circuitry and physical structures as would be understood by those skilled in the art. Thus, the illustrative examples can be modified in arrangement and detail without departing from the spirit of the invention. Therefore, the invention as described herein contemplates all such embodiments as may come within the scope of the following claims and equivalents thereof.

Traditional structures and systems for fabricating RF LINAC systems involve taking a large billet of special grade material or alloys, such as niobium metal, beryllium metal, ultra-high purity oxygen-free copper, and precision machining to precise dimensional tolerance for narrow frequency band resonant cavities for RF acceleration. For many accelerator components, only a few percent of the bulk material are used with a lot of lost material, time and labor. This is done at great cost to preserve material properties; and to minimize the number of lossy interfaces, tolerance/stack-up errors, hermetic breaks and mismatches. Often a substrate material is used for its superior structural properties at a performance cost of electrical or thermal properties. Tradeoff choices include: using stainless steel instead of copper, or the converse selection of niobium instead of copper. Because electrical properties dominate in the skin-depth for electromagnetic propagation in materials at high-frequencies (e.g. MHz), using a composite structure with a surface layer that exhibits superior electrical and vacuum properties.

With a composite structure, different materials may be selected for different components for thermal characteristics, structural support, expansion and contraction, anti-vibration, etc. With the ability to form composite structures, novel methods for fabrication, alignment, fixturing, and segmentation facilitates reducing cost and improving design flexibility for weight, size and power reduction and ease of integration. In particular, desirable surface material properties (e.g. low electron emission), material purity (e.g. low inclusions, low field concentration), cavity smoothness (e.g. lower field emission, higher gradient), near-surface morphology (e.g. limited whisker growth, spark initiation), and vacuum tolerance (e.g. low vapor pressure, surface mobility) can be engineered to improve the characteristics of the RF LINAC.

The manufacturing operations and techniques described herein also allow replacing bulk, solid niobium materials with thin-layers for superconducting cavities using more robust, thermally-conductive and easier to form/machine/work materials. Because of the diversity of materials that can be deposited onto a range of substrates, the technique allows more options and choices for accelerator cavities and components.

The RFQ LINAC is complex to fabricate due to a precision vane structure requiring vane tip alignment, spacing and assembly into four quadrants of equal size for RF load balancing. Traditional RFQ LINACs are manufactured using major-minor vane configurations comprised multiple axial assemblies integrated together to achieve a desired acceleration length. Typical RFQ LINACs operated about 200-425 MHz are 10s of meters in length for acceleration to several MeV for hydrogen ions. These machines are large, costly and are typically found at national laboratories, medical centers and research universities. Direct sputter coating on the interior can seal the interfaces between components, such as vanes, spacers, tuning rods, bellows, etc. However, the sputter coating methods and structures described herein are broadly applicable to a variety of applications beyond coating the interior surfaces of RFQ LINACs.

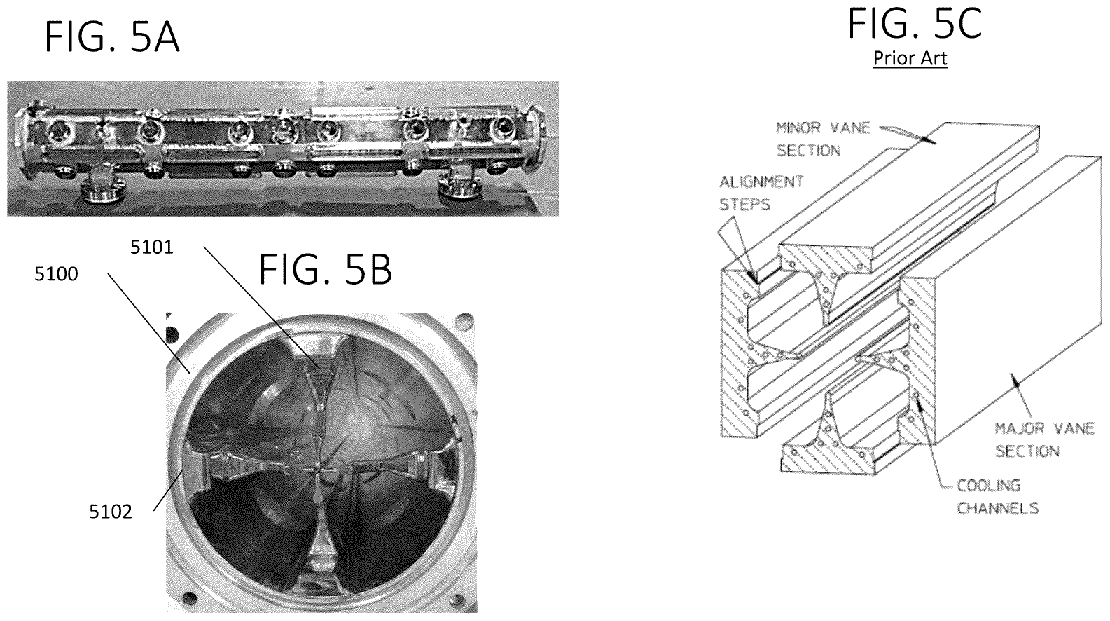

The thin-film deposition, etching and surface modification method herein enables composite construction, low-complexity integration and improvement in surface material properties for higher gradient operation. FIG. 5A is a photograph of an exterior of an RF LINAC cavity for a radiofrequency quadrupole accelerator. In the example show, the RF cavity serves as an external vacuum chamber with multiple ports designed for acceptance of the RF power amplifier assembly depicted in FIG. 1.

FIG. 5B is a photograph of interior quadrants of the example RF cavity formed by the rigid attachment of four vanes structures prior to surface modification and formation of a continuous RF seal. Four vane structures 5101 are inserted into an RF cavity and bonded into place with a material 5102. A precision fixturing jig (not shown) is attached to the four vane structures 5101 and vane tip alignment, positioning, gap spacing and tolerancing is performed ex-situ, prior to insertion into an RF cavity substrate 5100. Once the properly gapped and aligned vane structures 5101 are inserted, the fixtured vanes are rigidly attached to the RF cavity substrate 5100. The attachment structures are varied and include, by way of example, soldering, mechanical screws, turnbuckles, epoxy, low-temperature braze, etc. In the example shown in FIG. 5B, conventional solder is used with a low-temperature bake in an inert oven. As detailed in the following sections, the IMPULSE® thin-film deposition, etch and surface modification technique is used to coat the interface with a high-conductivity copper layer for a continuous cavity surface to achieve high Q. This is in contrast to FIG. 5C that shows a prior art major-minor vane construction for an RFQ with alignment shims and RF seals at each interface. Because the RFQ LINAC is thermally cycled and materials age, the interfaces between the major and minor vanes need additional compression force with restorative contact to maintain low resistance for high surface conductivity to RF currents. As a result, the attainable cavity Q may be 10-80% of the theoretical maximum value under ideal operating conditions, e.g. a cavity Q of 4500 vs. the 10,000 achievable for smooth, solid surface copper. A wide variety of mixed materials, including for example ceramics, semiconductors and metals, can be deposited on the RF cavity walls during a sputtering deposition operation where a majority of RF current and energy will transport using the known IMPULSE®+Positive Kick™. By way of illustrative example, the described sputtering deposition technique provides good coverage and sealing surfaces for room-temperature Cu and superconducting cavities, such as Nb or Nb/NbN, Nb₃Sn or MgB₂.

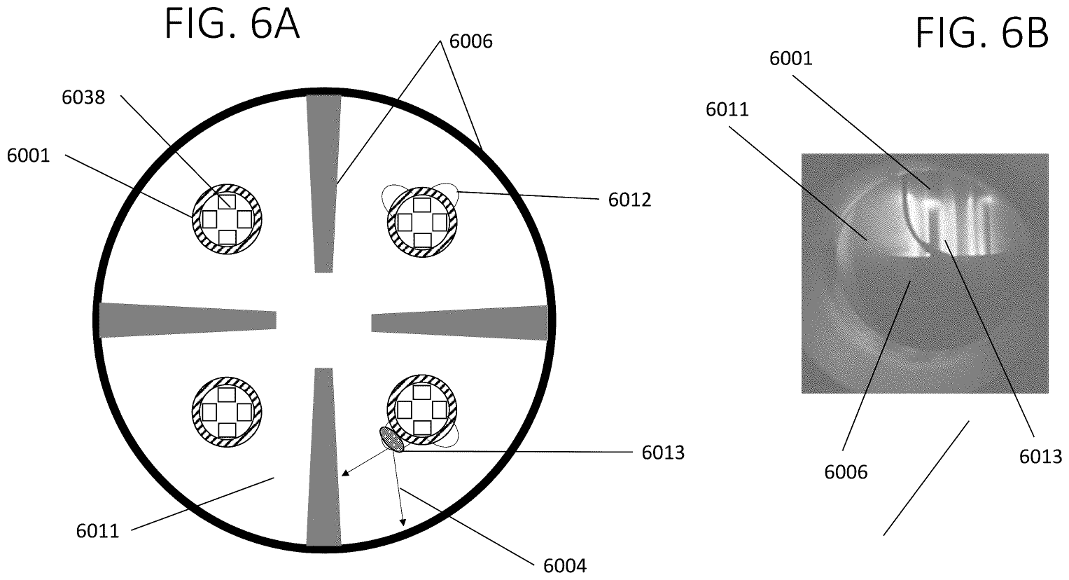

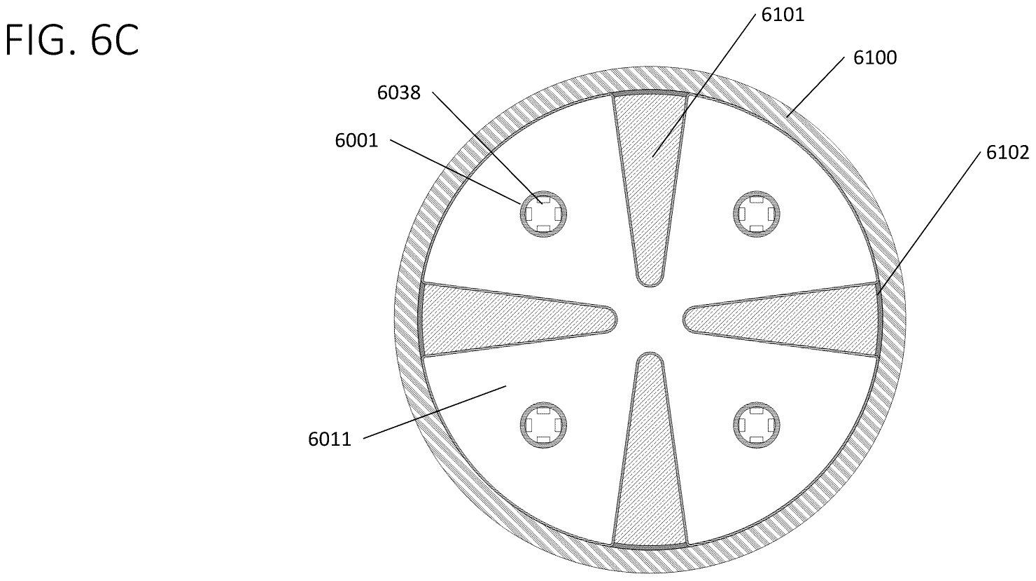

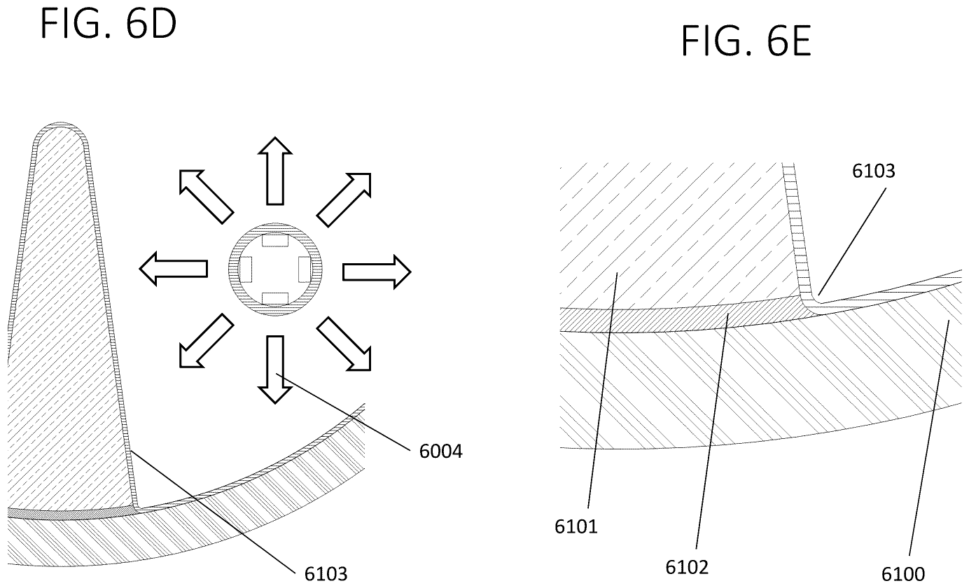

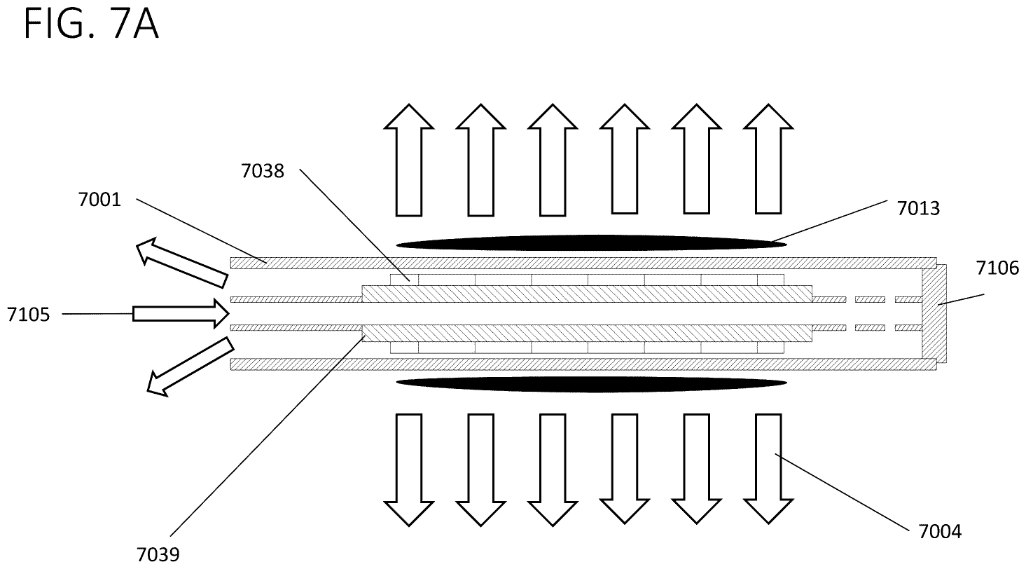

FIGS. 6A & 6B illustratively depict an application of the surface coating system and methods of operation disclosure herein. Namely, thin-film etching and deposition on particle accelerator electrodes and electromagnetic cavity structures are illustratively depicted. FIG. 6A depicts a cross-sectional area of a four-vane radiofrequency quadrupole (RFQ) accelerator cavity. The internal four quadrants of the RFQ accelerator cavity are subjected to intense electromagnetic fields and surface RF currents in operation. To achieve high accelerating gradients during operation, very high electric fields are used. Therefore the quality of the surface coating in the cavity, including the microstructure and electrical conductivity, are critically important to achieve high performance. The surface coating structures and methods disclosed herein facilitate a surface preparation, cleaning, etching, adhesion and deposition of high-quality materials that improve quality and performance of the deposited coatings during operation of the RFQ accelerator. In the illustrative example of FIG. 6A, a sputter target (e.g. sputter target 6001) is inserted inside a vacuum environment 6011 of an accelerator cavity substrate 6006. Magnetic assemblies (e.g. assembly 6038) inside of the sputter target 6001 generate magnetic fields 6012 that generate and sustain dense plasma regions 6013 to generate ions and neutrals 6004 that well deposit on substrate 6006. This is accomplished, for example, by introducing a gas into the vacuum environment 6011 in the range of 0.01-100 mTorr, typically noble gases like Ar or reactive gases like N₂, with voltages in the range of 200-2000V with magnetic fields on the order of 100-1000s of Gauss. During operation of the sputtering deposition operation, the energetic ions and neutral particles 6004 are generated and directed towards substrate 6006.

FIG. 6B is a photograph of the illustrative example in FIG. 6A during an actual operation for deposition of high-conductivity copper directly onto an interior surface of an RFQ accelerator cavity with vane structures fixtured and soldered directly to the RFQ accelerator cavity surface. The sputter deposited copper directly coats the interior surface including the solder material to make a continuous Cu layer exhibiting excellent sealing and surface properties. In FIG. 6B, the four (4) sputtering targets 6001 with the dense plasma regions 6013 are contained in the vacuum environment 6011 with the RFQ cavity substrate 6006 visible during insertion. The dense plasma region 6013 is clearly visible inside the vacuum environment 6011. High-conductivity copper with dense nanograin structure can be deposited with an ultra-smooth surface roughness to withstand high electric field gradients. The nanograin texture is resistant to slip-plane whisker growth that promotes surface electric field concentration and sparking under high electric field gradients. The illustrative examples described herein avoid this problem.

Furthermore, the presently disclosed material deposition operation (described in the context of providing a superior sealed copper conducting surface for an RFQ accelerator cavity) can also be used for superconducting films and layers, such as Nb, Nb/NbN, etc. Using the IMPULSE® and Positive Kick™ and aspects of this disclosure, the film morphology and crystallinity are controlled to achieve preferred grain orientation, grain size, lattice plane matching, surface roughness and other parameters leading to superior residual resistivity ration, current density and magnetic performance.

FIG. 6C depicts a composite RF LINAC cavity comprised of one or more bulk substrate materials with one or more material coatings. Materials making up vanes, such as a vane 6101 are fixtured to a wall of the RFQ accelerator cavity relative to one another according to a particular design for the RFQ accelerator and affixed to an RFQ accelerator cavity substrate 6100 using a bonding material 6102. The material of the cavity substrate 6100 is selected for its desired material properties, such as: structural, thermal, cost and ease of fabrication. The materials that make up the vanes, such as the vane 6101 are selected for their properties, such as thermal conductivity, coefficient of thermal expansion, machinability, compatibility for copper coating, etc. The actual bonding of the vane 6101 to a surface of the cavity substrate 6100 is carried out, for example using the bonding material 6102 using, for example, a combination of mechanical and chemical attachment structures. The sputtering targets, including the sputtering target 6001 with a corresponding magnetic assembly 6038, are inserted into the vacuum environment 6011 for surface modification, etching and deposition. The sputter target 6001 material can be any of a variety of materials selected to obtain different compositions having different properties for particular RFQ accelerator applications.

FIG. 6D depicts a zoomed-in view of the previous figures to provide a more detailed depiction of an in-situ sputtering electrode emitting ions and neutral particles (neutrals) to coat one or more surfaces of the RFQ accelerator cavity substrate 6100. The energetic ion and neutron particle flow 6004 is directed at the surface within the RF cavity and accelerator component to produce a thin or thick film surface coating 6103 with engineered properties.

FIG. 6E depicts a further zoomed in close up view of a composite RF LINAC cavity where the vane 6101 is rigidly affixed to a vacuum housing by a mechanical/thermal interface, and the thin-film continuous coating serves as an electrical interface. The thin/thick film surface coating 6103 provides a continuous, smooth electrical path across a transition from the RFQ accelerator cavity substrate 6100 to a bonding material 6102 to the material on an outer surface of the vane 6101. At MHz RF frequencies an electrical skin-depth for electromagnetic propagation is only a few micrometers. Therefore, from the vantage point of the RF cavity, RF energy cannot reach (“see”) the underlying materials (beyond the skin-depth) and thus performance can be optimized for a multi-layered composite structure where electric field properties are emphasized within the skin-depth range, and mechanical, structuring, cost, manufacturing properties/considerations predominate at distances outside the skin-depth layer.

Conventional wet chemistry and electroplating techniques are limited in substrate material choices, substrate shape, contamination, surface material finish, and adhesion strength. The presently disclosed innovative fabrication features described herein are based on use of conformal physical vapor deposition in combination with surface etching, preparation and modification techniques for a wide range of materials.

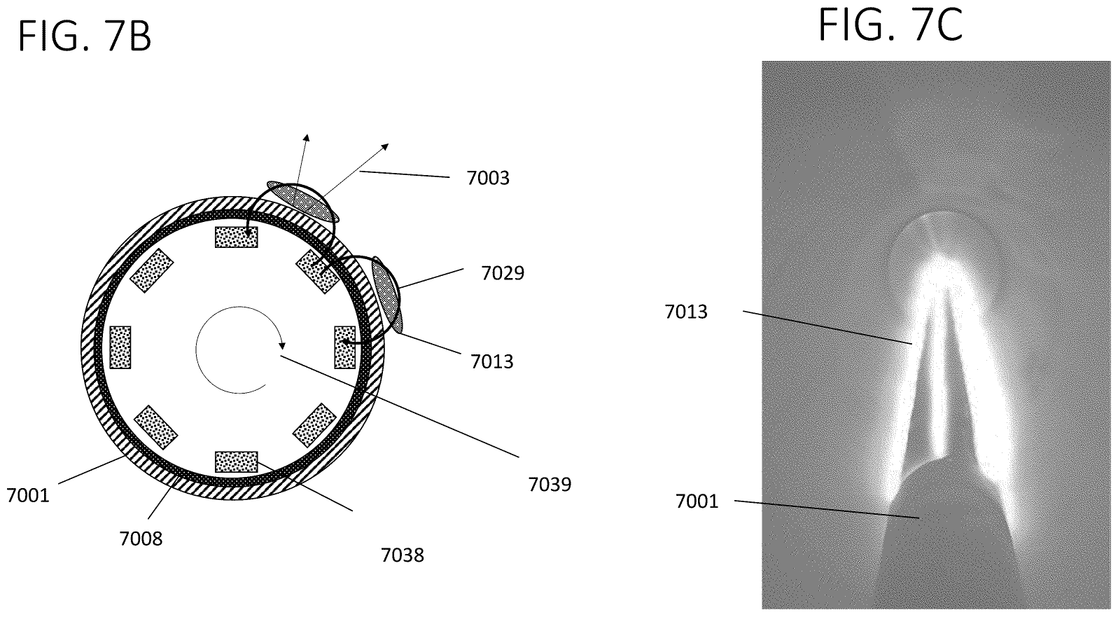

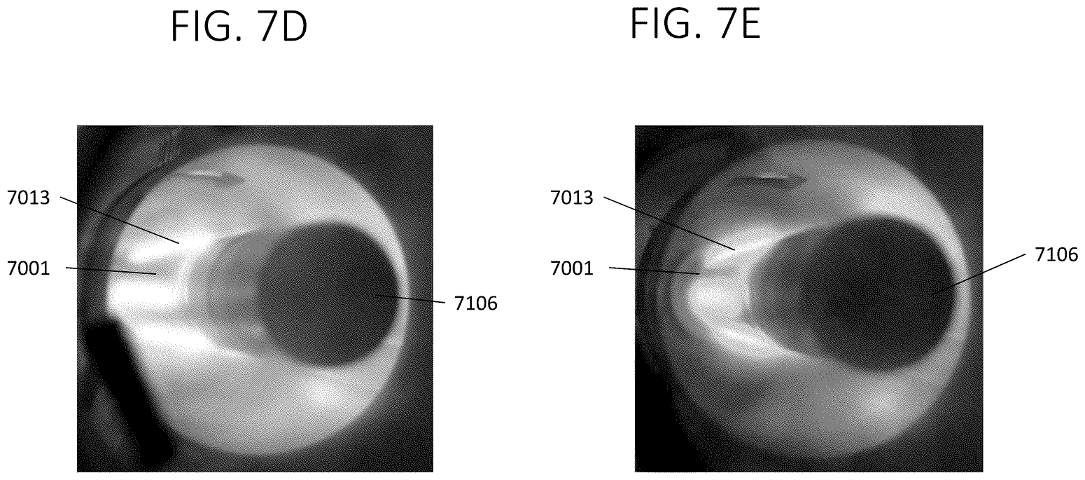

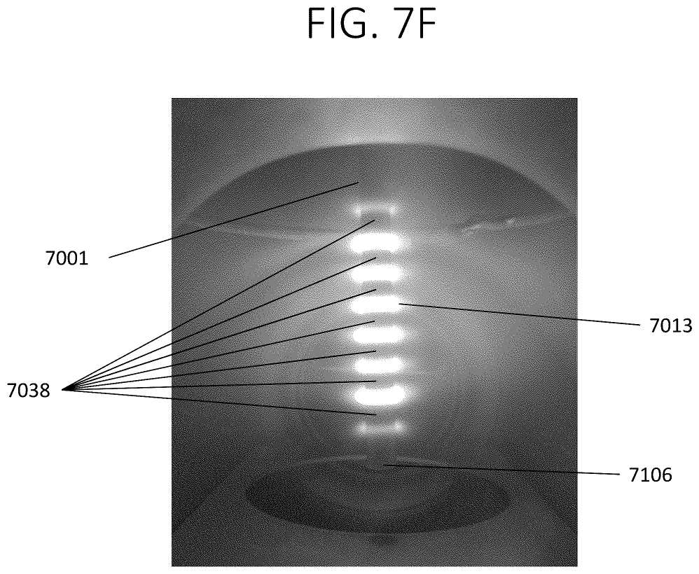

FIG. 7A illustratively depicts an axial internal side cross-sectional view of an end-capped cylindrical magnetron emitting ions and neutrals highlighting internal coolant flow, magnetic assemblies and plasma generation on the exterior. Sputtering target electrode 7001 is mounted onto an end-capped assembly 7106 with an internal cooling channel 7105 flowing coolant over magnetic assemblies 7038 and a sputtering target material 7001. There may be a target holder between the material 7001 and the coolant water and magnetic assemblies 7038. The magnetic assemblies are, for example, mounted to a structure that facilitates a rotation 7039 of the structures providing dense plasma regions 7013 around the sputtering target electrode 7001.

FIG. 7B depicts, in an orthogonal cross sectional view of the structure depicted in side cross-sectional side view in FIG. 7A, a sputtering electrode highlighting the relative rotation of the sputtering target material and magnetic assemblies. The rotation 7039 allows magnetic fields 7029 from magnetic assemblies 7038 to move relative to the target material 7001. In the illustrative example, the magnetic assemblies 7038 are mounted to a target holder 7008. A dense plasma zone 7013 generates energetic ions and neutral particles 7003 that are directed outward from the sputtering target material 7001 towards the surfaces of the RFQ accelerator cavity substrate (not shown) to be coated, etched and modified.

FIG. 7C is a photograph of a 1.5-meter long sputtering electrode embodiment with a magnetic field arranged to create a single serpentine dense plasma zone around a sputtering electrode. Electrons orbit the continuous serpentine racetrack via Hall Effect ExB forces (aka “the magnetron effect”) from the application of voltage on the sputtering target electrode 7001, resulting in generation of an intense plasma zone 7013. Because it is a single racetrack, the plasma density is able to better load balance over the cylindrical magnetron surface for better uniformity over the length. In this specific example, a 1.5 m-long plasma region is formed with good uniformity over the length suitable for azimuthal rotation.

FIG. 7D is a photograph of an end-capped cylindrical magnetron 7106 operating with a single serpentine racetrack dense plasma region 7013 on the sputtering target electrode 7001. In FIG. 7D, the end-capped cylindrical magnetron 7106 employs the IMPULSE®+Super Kick™ technique for generating an electromagnetic field for performing cleaning, etching and surface modification—as evidenced (when viewed live in operation) by a blue-pink-purple color on the copper sputtering target electrode 7001. In this plasma mode, the end-capped cylindrical magnetron 7106 generates high energy Ar+ ions and directs the ions radially outward to clean the surface of objects (e.g. an RFQ accelerator cavity) to be processed.

Advantageously, during a surface processing and treating operation, within less than a second, IMPULSE® operational parameters can be changed to switch operation of the assembly from performing a cleaning/etching operation to deposition/implantation operations. FIG. 7E is a photograph of the same system shown in FIG. 7D employing the IMPULSE®+Positive Kick™ technique for generating an electromagnetic field for performing implantation, intermixing, adhesion, stress control, morphology control, diffusion barriers and capping layers—as evidenced (when viewed live in operation) by a bright green copper plasma color from the sputtering target electrode 7001.

FIG. 7F is a photograph of a 6.3-mm diameter end-capped cylindrical magnetron 7106 with a different illustrative example with magnetic field assemblies 7038 arranged to create multiple dense plasma zones 7013 around the sputtering target electrode 7001 that can be axially translated. This configuration is adapted to treat interior surfaces of structures having very small diameters and coating the interior of small tubes and difficult-to-reach locations. However, the structure may also be used to treat surfaces of larger items as well.

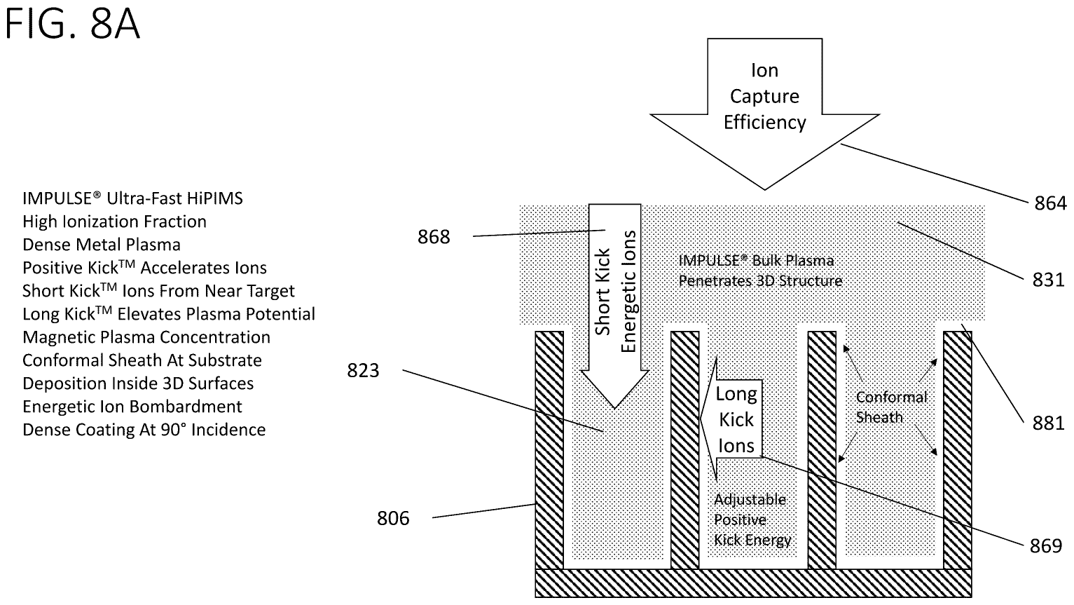

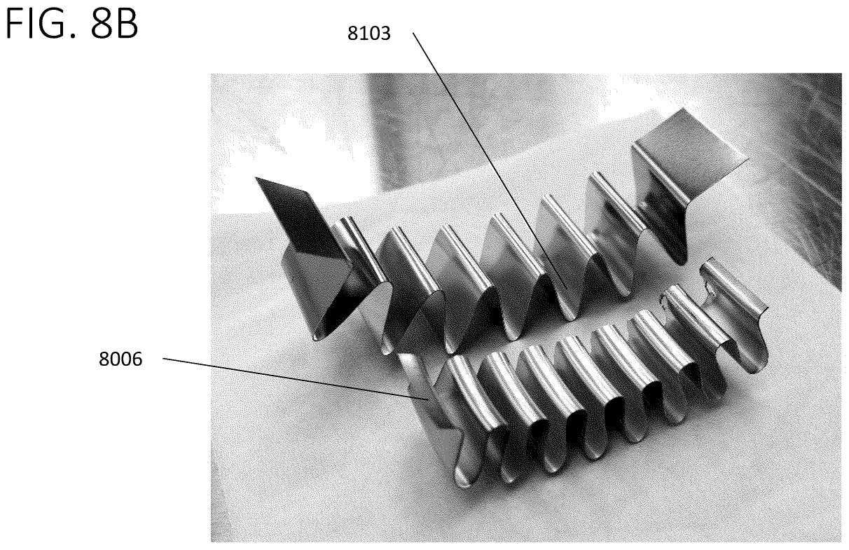

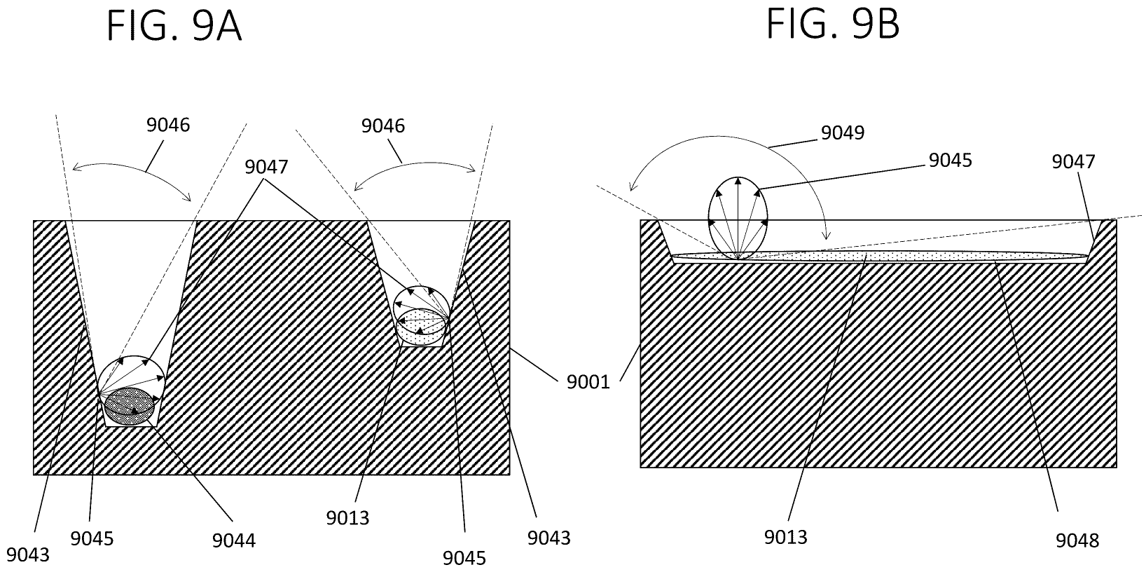

Using cylindrical magnetron configurations discussed herein above, as well as others including inverted cylindrical, planar and rotary, the IMPULSE® ultra-fast high-power impulse magnetron sputtering (HiPIMS) technique can be used to generate a dense metal plasma and an ultra-fast voltage reversal for carrying out Positive Kick™ and Super Kick™ techniques to accelerate ions and plasma to the substrate for modification. FIG. 8A depicts an illustration of an example of using the IMPULSE®+Positive Kick™ for conformal coating of substrates. During HiPIMS pulses the electrical current can be 10-1000× higher than conventional DC sputtering. Combined with ultra-fast IMPULSE® pulsing technology, peak power densities can be achieved <<100 usec leading to very high plasma densities. The Positive Kick™ voltage reversal and positive bias pushes ions and plasma away from the dense magnetic field regions on the magnetron to increase the local plasma density near the substrate during the pulse. This high-density bulk plasma 831 will have a short Debye length allowing it to penetrate 3D structure 823 of the substrate 806. Applying the Positive Kick initially accelerates ions from the magnetic confinement zones with directed energy 868 following Grad B and eventually float bulk plasma potential up such that a conformal sheath 881 will appear around the substrate 806 and accelerate additional ions 869 to the substrate. If the features are larger than several Debye lengths, then conformal deposition will result. An additional result of the Positive Kick is an increase in ion capture efficiency 864 which is important from an economics perspective.

FIG. 8B is a photograph depicting surface coatings achieved using the end-capped cylindrical magnetron technology with IMPULSE®, Positive Kick™ and Super Kick™ for conformal thin-film copper coatings to replace conventional electroplating and wet electrochemistry for stainless steel cryogenic accelerator bellows. In the foreground, the substrate to be coated 8006 is made from hydroformed stainless steel suitable for cryogenic applications. The as-received material is inserted into the cylindrical magneton system and IMPULSE® applied with Positive Kick™ for adhesion and surface adatom mobility and Super Kick™ for etching/cleaning. The continuous thin/thick film 8013 is conformal deep into the bellows channels. The adhesion and film quality are enough to survive a 400 C air bake and immediate immersion into LN2 without spallation, delamination or material failure. The material is cycled through >1000 full-range expand-compress strokes without failure of the film.

Conformal coatings are achieved on accelerator surfaces, including RF cavities, RF seals, bellows, and actual vane tips, I-H structures, dielectric loading structures, tuning elements and electrodes. Low secondary electron emission, smooth and high-field emission limit materials can be deposited and well adhered in high stress locations, whereas high-conductivity bulk material can be coated in areas where low resistance is needed. For the case of the 4-vane RFQ accelerator cavity surfacing, the vane tips are coated with one type of coating for the high field region and the cavity zones are coated with a different type of film structure. For example, ultra-smooth, nano-crystalline or amorphous high-gradient materials on the vane tips and preferred orientation high-conductivity copper in the cavity zones.

FIG. 9A depicts an illustration of sputter target erosion and wear for narrow V trenches. Under HiPIMS conditions, the higher magnetic field location 9044 generates a higher plasma density 9013 leading to more local current and sputtering from location 9045 on cosine 9047 relative to the surface normal. The deeper the V-channel 9043 the less solid angle 9046 for material escape and a higher amount of material recycling occurs, lowering the overall deposition efficiency of the system. For multiple racetracks it is possible to have deeper racetrack grooves on some than others. This accelerates maintenance cycles. FIG. 9B depicts an illustration of sputter target erosion with relative movement between the dense plasma regions and sputter target material for uniform erosion. With rotation or axial adjustment of magnetic field relative to the target, improved uniformity and less groove 9047 can be achieved for greater solid angle emission 9049 and target utilization 9048.

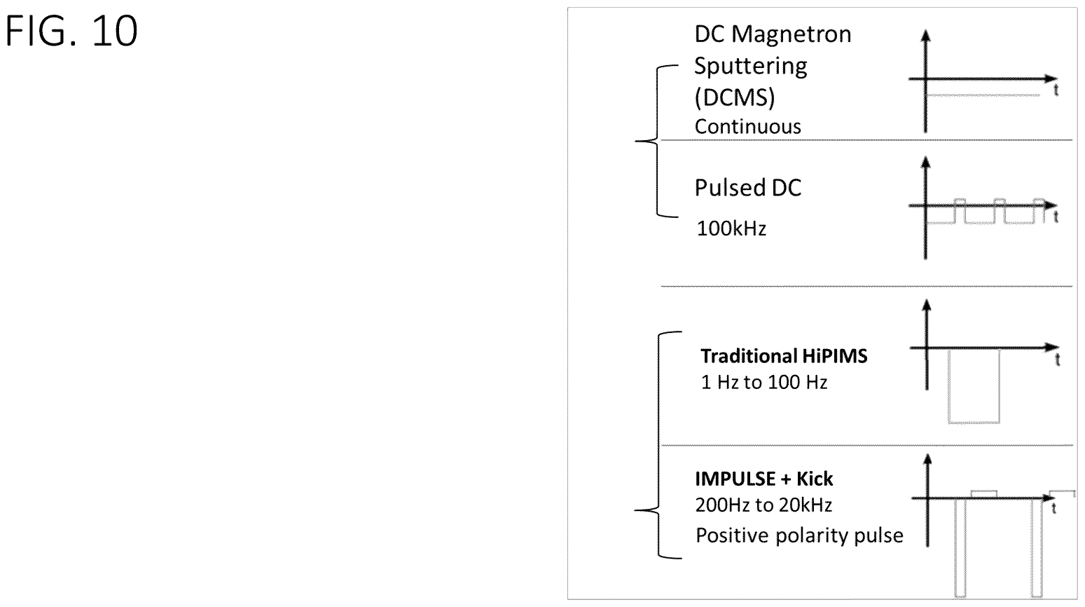

FIG. 10 illustratively depicts a comparison of traditional DC magnetron sputtering (low current, low ionization), pulsed DC (lower current, low ionization but better for reactive gases), traditional HiPIMS (high current, high ionization but low deposition rates), and IMPULSE®+Positive Kick™ (high current, higher ionization rates and higher deposition rates). Typically, HiPIMS plasma current densities are ˜0.3 A/cm2. Using an ultra-fast impulse followed by a Positive Kick pulse can exceed 3 A/cm2 with good film properties and is used as a factor in designing the inverted magnetron structure for high peak powers for more intense ionization, conformal plasma etching and deposition.

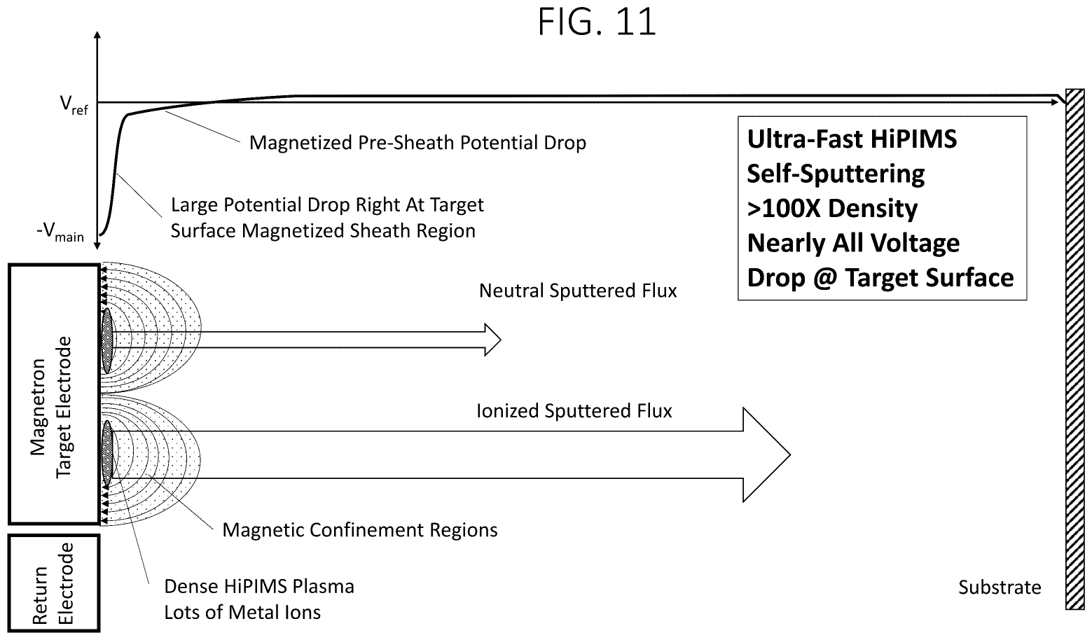

FIG. 11 depicts an illustration of the 1^{st} of 3 phases during an IMPULSE pulse operation—the Ultra-Fast HiPIMS phase. FIG. 11 is adapted from US Application Publication US20180358213A1 and illustratively depicts an ultra-fast high-power impulse magnetron sputtering and the potential distribution between the sputter target and the substrate.

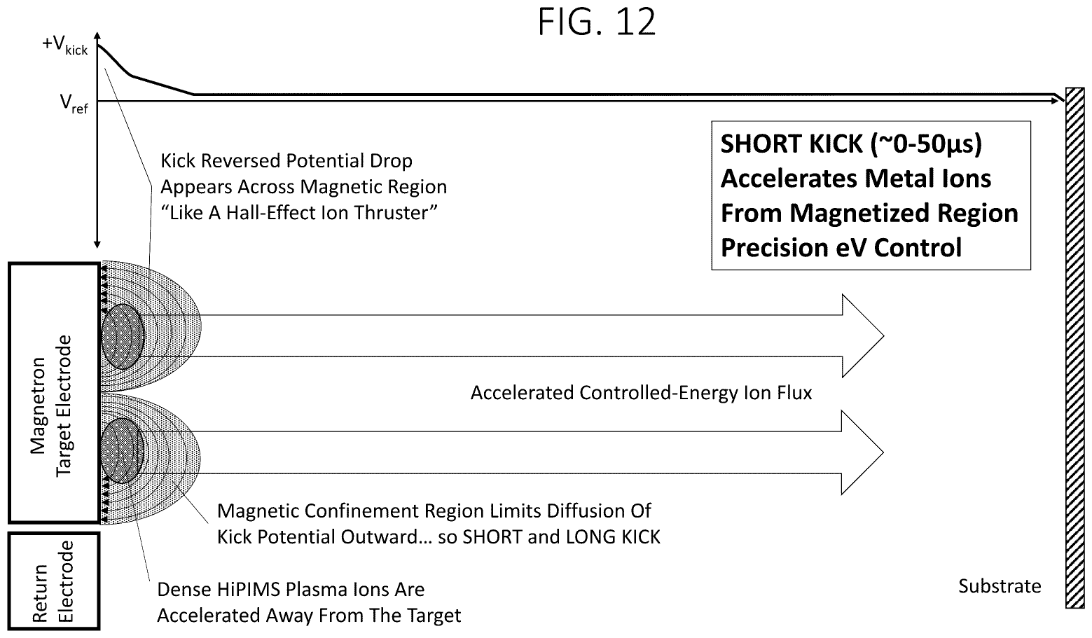

FIG. 12 depicts an illustration of the 2^{nd} of 3 phases during IMPULSE® operation—the Short Kick phase. FIG. 12 is adapted from US20180358213A1 and illustratively depicts an ultra-fast switching and positive voltage reversal on the target electrode to a positive voltage and the evolution of the potential distribution across the magnetic confinement region near the target electrode—the Short Kick accelerating ions from the dense HiPIMS plasma region away from the target electrode typically perpendicular to magnetic field lines.

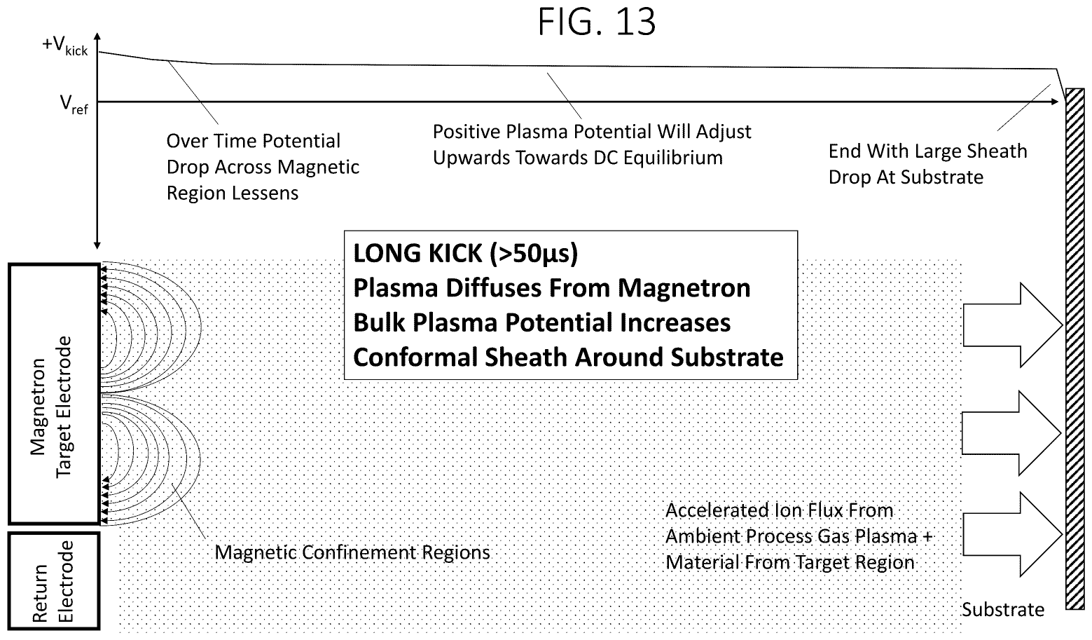

FIG. 13 depicts an illustration of the 3rd of 3 phases during IMPULSE® operation—the Long Kick phase. FIG. 13 is adapted from US20180358213A1 and illustratively depicts a positive potential evolution into the Long Kick phase where the plasma potential of the bulk is increased and conformal sheaths form on the substrate and other surfaces where the bulk plasma is commuted.

An aspect of the disclosure provided herein is the ability to control, during operation of the apparatus described herein, the flux and energy of ions deposited/impacted onto substrates for the preparation and deposition of thin-films with engineered properties. A high level of customization afforded with the combination of ultra-fast high-current pulsing with rapid positive voltage reversal with the cylindrical magnetron configuration enables superior and novel films, including advanced nanolayer composites and functionally-graded materials with specific attributes, including high-electrical gradient standoff, high-voltage tolerance, high-electrical conductivity, ultra-smooth surfaces, oxidation resistance, thermal fracture toughness, crack arresting features, diffusion barriers and anti-wear, anti-corrosion, ductile vs. stiffness, lubricious properties, etc. Specifically, the deposition of superconductor-insulator-superconductor layers with low bulk temperature highly sought after by superconducting wire, magnetic tape, RF cavity and accelerator engineers.

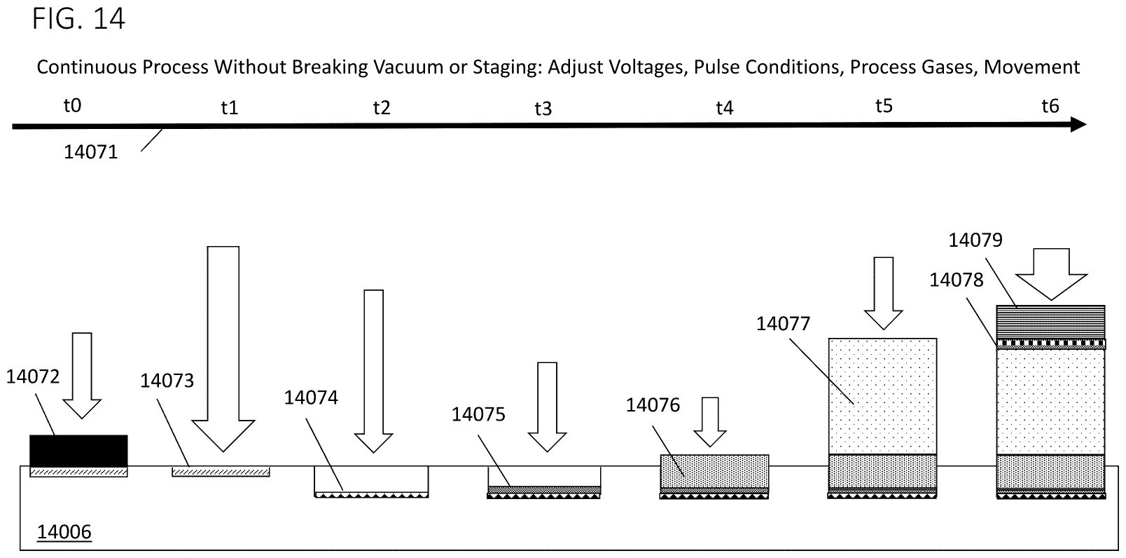

FIG. 14 illustratively depicts a central advantage in terms of combining cleaning 14072, etching 14073, ion implantation 14074, adhesion control 14075, stress management 14076, bulk material deposition 14077, diffusion barriers or insulating layers 14078, and reactive/capping layer 14079 depositions. With precision ion energy control, the ultra-fast IMPULSE® with positive voltage reversal can remove surface contaminants, etch near-surface damage, develop a mixing interface for a good adhesion layer, to support stress-controlled layer(s)s that enables bulk films to be grown with suitable interface and capping layer(s). FIG. 14 depicts an illustration of a continuous process 14071 using the IMPULSE®+Positive Kick™+Super Kick™ without breaking vacuum, interruptions or staging.

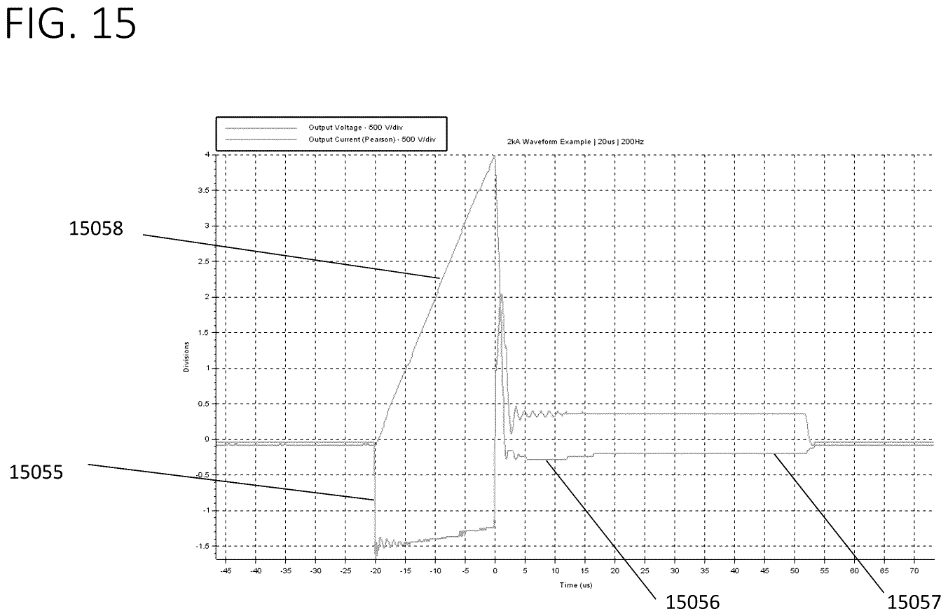

FIG. 15 is an oscilloscope waveform of a Cu sputtering plasma achieving 2 kA peak current in 20 microseconds during the Ultra-Fast HiPIMS phase with subsequent +200V positive pulse showing Short and Long Kick phases. The voltage waveform 15055 and a current waveform 15058 for a −750V, 2 kA peak current HiPIMS pulse achieving a plasma current density of 5 A/cm2 on the cylindrical magnetron with a copper sputtering target with a positive kick pulse of +200V, 125 A peak current highlighting a short kick 15056 and a long kick 15057. The IMPULSE® technology described herein drives plasma generation at high dI/dt to achieve rapid ionization for subsequent voltage reversal and Positive Kick™ to accelerate ions and plasma into substrates for superior cleaning, etching, preferred-orientation deposition and deposition with stress and morphology control. The technology also allows for synchronization with pulsed DC bias supplies for time windowed acceleration into the substrate for additional control as taught in US20180358213A1.

Depending on local factors such as pre-ionization, target material, magnetic field, pressure, geometric curvature, sputtering gas, surface chemistry, adsorbed gases, etc, the main negative pulses on the voltage waveform 15055 are typically in the range of −400V to −1200V. Using the ultra-fast switching topology typical high-current pulse widths are less than 100 usec, with a typical range of 20-50 usec. The Positive Kick™ amplitude on the voltage waveform 15055 are typically in the range of +0-600V. For users who do not want the short kick ion population group to be accelerated away from the sputter target, shown in the current waveform for the short kick 15056, the onset delay in the positive kick would be set to after this time period typically set at 20-40 usec. The ionization rate and plasma density near the sputtering target is highly coupled with the effective current density. Effective current densities are in the range of 0.1-10 A/cm2.

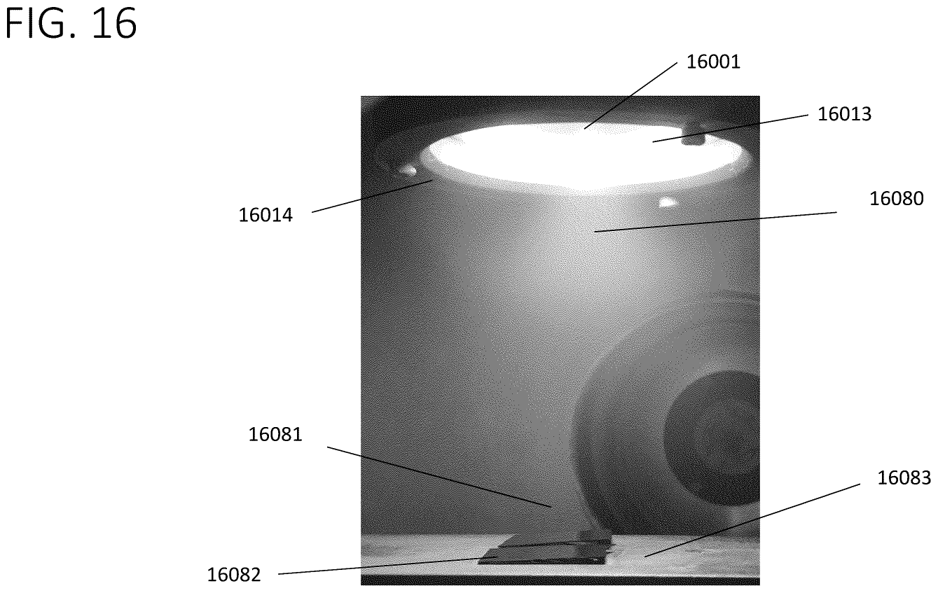

FIG. 16 is a photograph of a conventional planar magnetron operating with ultra-fast short main pulse for deposition and subsequent RF-like modulation of the Positive Kick™ pulse to generate and sustain a secondary plasma with positive potential relative to the substrate for etching. Each pulse cycle would be a combination of deposition and etching—in the case with a copper sputtering target to achieve preferred orientation copper deposition such as Cu(211) vs. Cu(111) vs. Cu(100). The etching parameters are adjusted for preferred orientation and epitaxial growth conditions. A sputter target 16001 is processing both a negative main pulse and an RF-modulated positive pulse. The dense plasma region 16013 over the racetrack is brilliant white-green from the Cu I and Cu II optical emission lines. A central plasma region 16080 excited by the RF-modulation of the positive voltage is colored pink from Ar I and Ar II excitation. The central plasma region 16080 extends all the way down to an insulating substrates 16082 exhibiting combination for deposition and etching a surface 16083. A conformal plasma sheath 16081 extends down to the insulated substrates 16082. Using the combination for deposition and etching preferred orientation films can be deposited.

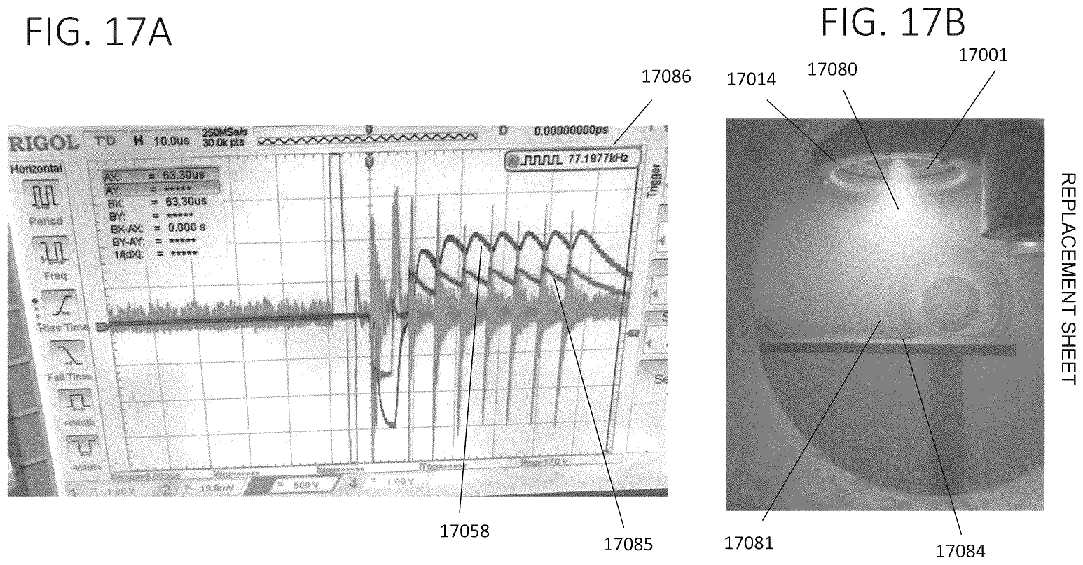

FIG. 17A is an oscilloscope trace illustrating the ˜10-100 kHz RF-like modulation (such as frequency and/or amplitude) of the positive pulse to generate plasma with a positive RF bias. FIGS. 17A and 17B are photographs highlighting the Super Kick™ mode for extended plasma generation away from the magnetic field and etching on substrates with a sample oscilloscope waveform 17086 (FIG. 17A) showing 77 kHz operation, current waveforms 17058 for the RF-like oscillation and voltage waveforms of an RF-like voltage application 17085. The photograph in FIG. 17B shows a bare target electrode 17001 without the bright visible emission from the racetrack region. The absence of any dense plasma region shows there is no sputtering of the target occurring. A bright central plasma region 17080 follows the magnetic nozzle/cusp expansion into the target electrode and is a commuted to a target electrode 17001 at elevated positive potential. The resulting etching plasma extends down to a substrate 17084 with a visible plasma sheath 17081 conforming on the samples. The Super Kick™ mode can be indefinitely sustained under a range of operational conditions for direct etching. The Super Kick™ can also be used in conjunction with a negative DC bias on the substrate for additional flexibility in materials processing.

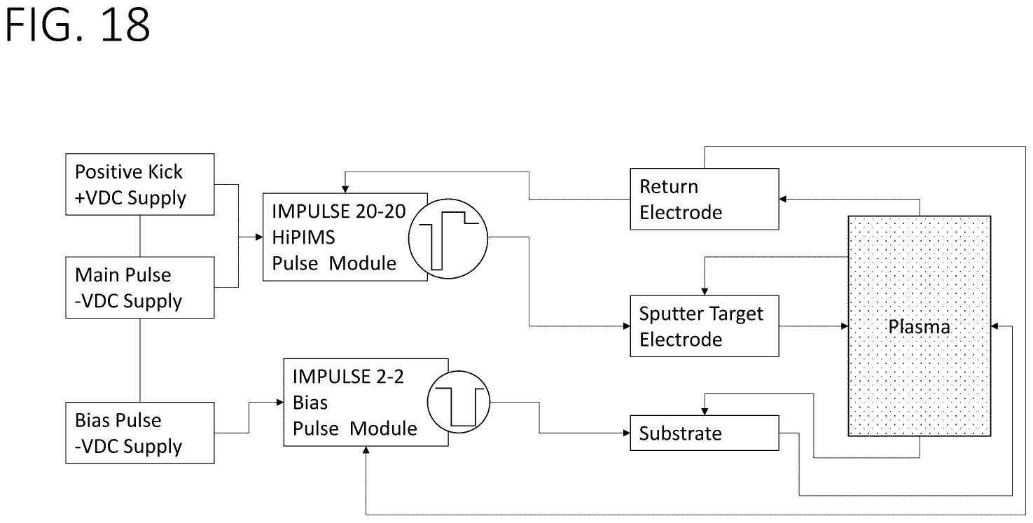

FIG. 18 depicts a schematic representation of the thin-film deposition, etch and surface modification system with IMPULSE® pulse modules and power supplies. FIG. 18 is a schematic a block diagram showing an illustrative example of an electrical component/circuitry arrangement between a sputter target electrode, a return electrode, a substrate, a plasma in a vacuum environment and one or more IMPULSE® HiPIMS pulse module(s) (its main and kick supplies) and any IMPULSE® bias pulse module supplies. The schematic block diagram in FIG. 18 outlines a generic setup of IMPULSE® systems for deposition and etching. High voltage electrical pulses are provided from the external pulsed power modules directly to the sputter target through appropriate insulation and low-impedance connections. By rotating the magnetic assemblies, this allows for low-impedance electrical connections to the sputter target holder for efficient power transfer and coupling. The IMPULSE® modules are designed for parallel synchronous and asynchronous operation. Therefore, multiple units can pulse in parallel to delivery needed power, risetime and plasma density for a sputtering target electrode configuration.

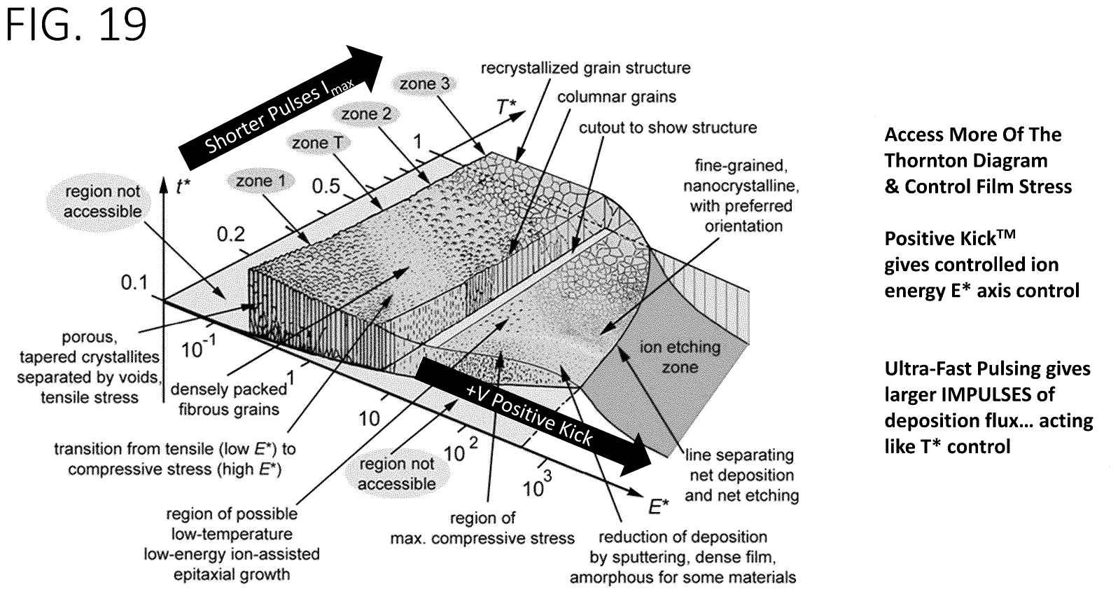

FIG. 19 illustratively depicts an example structure zone diagram with two independent axes for effective temperature (T*) and effective sputter particle energy (E*) that are addressable with the IMPULSE® and Positive Kick™. FIG. 19 expands on the control of thin-film microstructure and morphology via illustration of the Andre Anders' modified Thornton Structure Zone Diagram for generalized energetic condensation. Adjustment of the HiPIMS pulse amplitude, pulse width, timing, peak current density, repetition rate and pressure for a given substrate-to-sputter target distance, magnetic field geometry and field distribution, allows control over the main pulse particle flux (T*) which is approximate as a thermal spike. More intense short pulses with higher particle loading over shorter periods has a high temperature effect allowing the deposited material to equilibrate and adjust towards fibrous transitional grains (zone T), columnar grains (zone 2) and recrystallized grain structure (zone 3). Adjustment of the positive kick pulse amplitude, short/long kick pulse, onset delay and any super kick effect for RF-like oscillations for a given magnetic field, cusp magnetic null geometry, pressure and available plasma resulting from the main IMPULSE® HiPIMS pulse will allow adjustment of the effective energy (E*) and adjustment of the thin-film microstructure and morphology. Essentially controlling the IMPULSE® and the positive kick allows movement all over the Anders/Thornton SZD, even achieving fine-grained nanocrystalline films with preferred orientation and region of low-temperature low-energy ion-assisted epitaxial growth and dense, amorphous glassy films. The process engineer can move around the SZD to achieve tensile/compressive stress control, columnar growth vs. nanocrystalline with preferred orientation, etc.

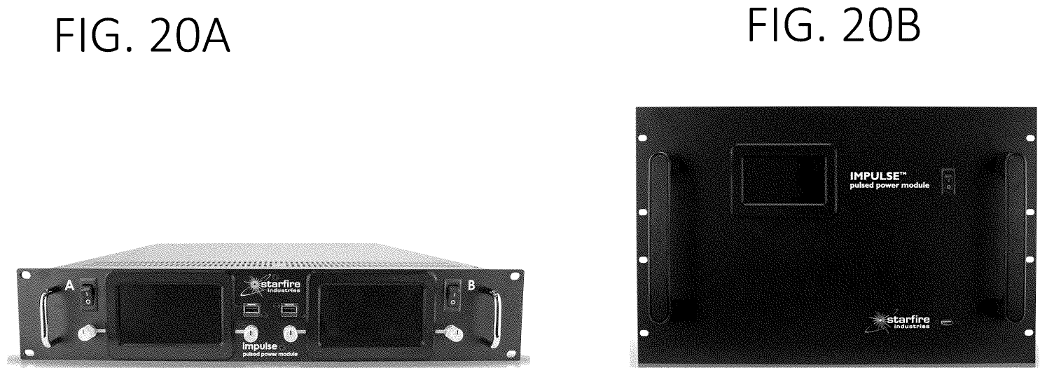

FIG. 20A and FIG. 20B are photographs of an IMPULSE® 2-2 system and an IMPULSE® 20-20 system used as a power supply in the systems described herein in implementations of the present disclosure.

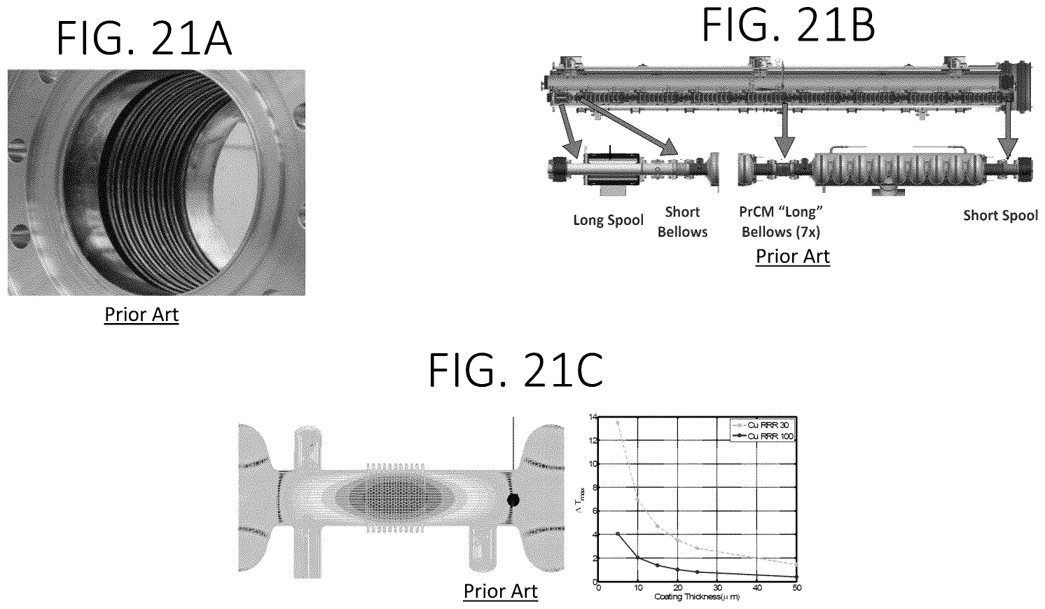

FIG. 21A is an example of a bellows structure having a surface treated/formed using a prior art approach for electroplating stainless-steel cryogenic bellows for RF accelerators. In the image provided in FIG. 21A, the variable quality of the copper plating may be observed with an inability to deposit plate material on the sidewalls of the vacuum bellows section due to masking and nickel strike layer difficulties. Prior art method may be replaced, with beneficial results of better surface treating/plating by use of the deposition/sputtering operations of the present disclosure.

FIG. 21B illustratively depicts a prior art arrangement for a superconducting RF accelerator section comprising multiple spools, bellows and RF cavities needing specific material properties. The present disclosure addresses multiple sections with wide application.

FIG. 21C illustratively depicts performance properties of a prior art showing RF power loss and thermal dissipation due to poor electrical conductivity with electroplated copper. The thickness of the film determines both magnitude of RF losses and ability of the structure to conduct that deposited thermal energy outward. This is important for not only accelerator cavities but also bellows sections, transfer tubes and other beam structures.

Trapped RF modes are a source of heating that exist in accelerator structures such as bellows. For superconducting accelerator cryomodules that are kept at liquid He temperatures, any thermal energy deposited here will be removed solely via conduction along the bellows surface to its edges. To minimize heating, as close to pure (e.g. high RRR) copper films having a thickness of >10 μm is highly desirable for these applications. Starfire's IMPULSE®+Positive Kick™ technology addresses this by enabling stress control in the deposited films. This allows the process engineer to deposit films having little to no internal stress, which is critical for thick, large-area films.

The present disclosure allows very thick, stress-controlled, fully-dense, high-conductivity, well adhered coatings to address this challenge, as shown in FIG. 8B. Low-temperature deposition using the Positive Kick and IMPUSLE allows a higher effective T* and E* to get the right orientation without high bulk temperature that results in interdiffusion of the layers. Added knob of kick voltage/duration is meaningful. Changes T* on the Thornton zone diagram without requiring direct heating of the substrate. Low actual substrate temp prevents diffusion in nanolayered materials (e.g. SIS structures). Adjustable surface mobility good for low defects are critical for SC films.

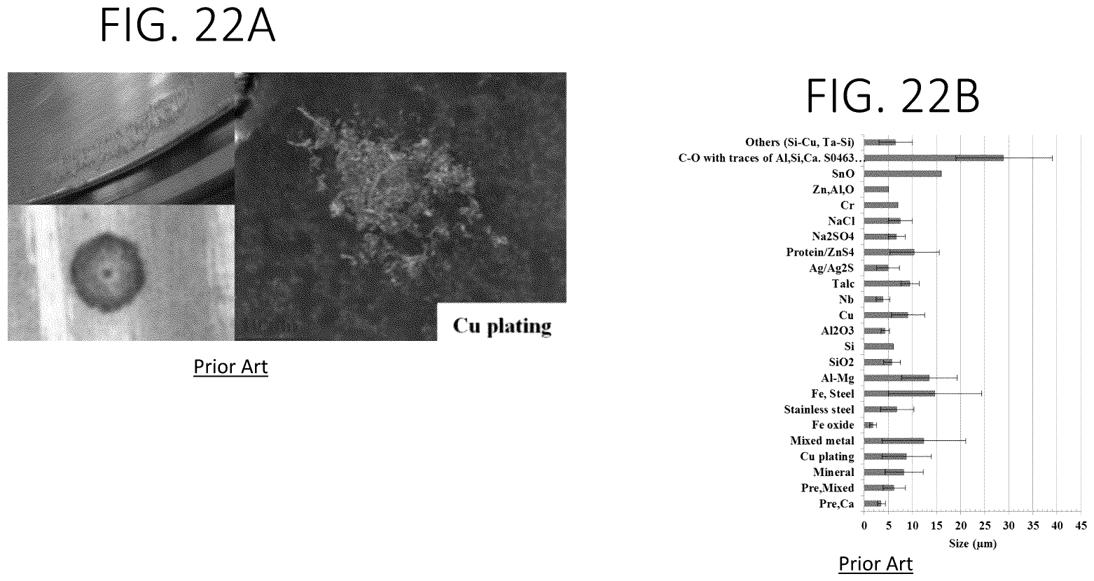

FIG. 22A is a photograph collection for a surface treated according to the prior art showing surface defects, corrosion, trapped material, inclusions and surface asperities in conventional copper electroplating leading to poor accelerator performance. The IMPULSE®+Positive Kick™ and Super Kick™ modes controls net deposition, etching, or doing both for smoothing/roughness-fill. Releveling a surface is beneficial to high-gradient (i.e. spark-resistant or spark-tolerant) accelerator films. The initial spark resistance is in smoothness, but that the overall tolerance comes more from a lack of inclusions that are provided by depositing a controlled film in an atom-by-atom process vs. bulk casting and machining. After a first arc, the local surface is no longer smooth. Therefore, the film impurities/defects/inclusions determine performance of a treated surface.

FIG. 22B is an illustrative summary of performance of surfaces treated according to the prior art. The summary shows the presence of inclusions in electroplated copper by size and material impurity. The surface treatment and formation operations and structures described herein according to the present disclosure enable controlled deposition of materials on an atom-by-atom basis, greatly limiting inclusion size and composition to suppress local field enhancements and multipactoring and sparking.

The proposed illustrative examples using conformal ionized physical vapor deposition replaces wet chemical electroplating (e.g. Cu) for stainless-steel bellows and specialty vacuum components used on accelerator structures. Wet chemical electroplating is being progressively phased out due to its damaging environmental impact, hazardous chemical handling, high cost, and lack of experienced tradespeople in the field. In the EU there are proposals and timelines for the complete phase out of all electroplating in the coming years, making investment in alternative technologies important. There are known issues with surface finish/roughness (including macroscopically visible striations in the plating), inclusions, particulates from both the copper plating itself, as well as those potentially introduced during the electroplating or subsequent surface smoothing steps (e.g. Mo-wool polishing or bead blasting).

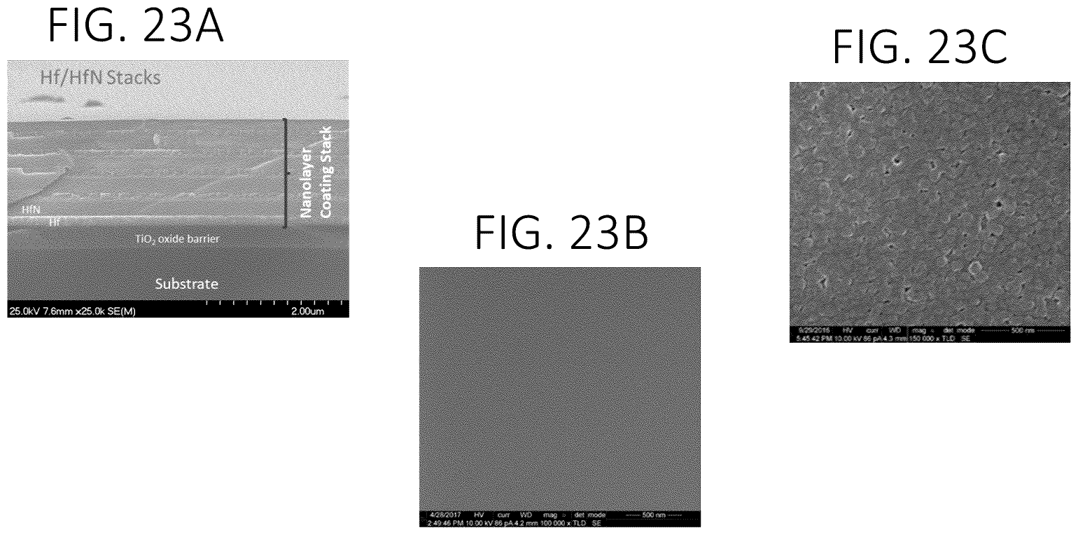

FIG. 23A is a photograph of a representative multilayer metal-insulator-metal stack deposited on a substrate with a barrier interface using the IMPULSE®+Positive Kick™ demonstrating surface smoothness and ability to control layer properties. FIG. 23B is a scanning electron micrograph of a diamond-like carbon layer deposited with the IMPULSE®+Positive Kick™ technique. FIG. 23C is a scanning electron micrograph of a diamond-like carbon layer deposited with conventional DC magnetron sputtering highlighting its porosity and voids. The microstructure and morphology of the thin-film coatings can be controlled using the IMPULSE®+Positive Kick™ as described in U.S. application Ser. No. 16/801,002, filed Feb. 25, 2020, and entitled “METHOD AND APPARATUS FOR METAL AND CERAMIC NANOLAYERING FOR ACCIDENT TOLERANT NUCLEAR FUEL, PARTICLE ACCELERATORS & AEROSPACE LEADING EDGES.” Production of nanocrystalline or preferred orientation films near the surface can minimize surface asperities, whisker growth and slip-plane protraction growth kinetics that are partially responsible for electric-field concentration, multiplication and the formation of sparks/arcs.

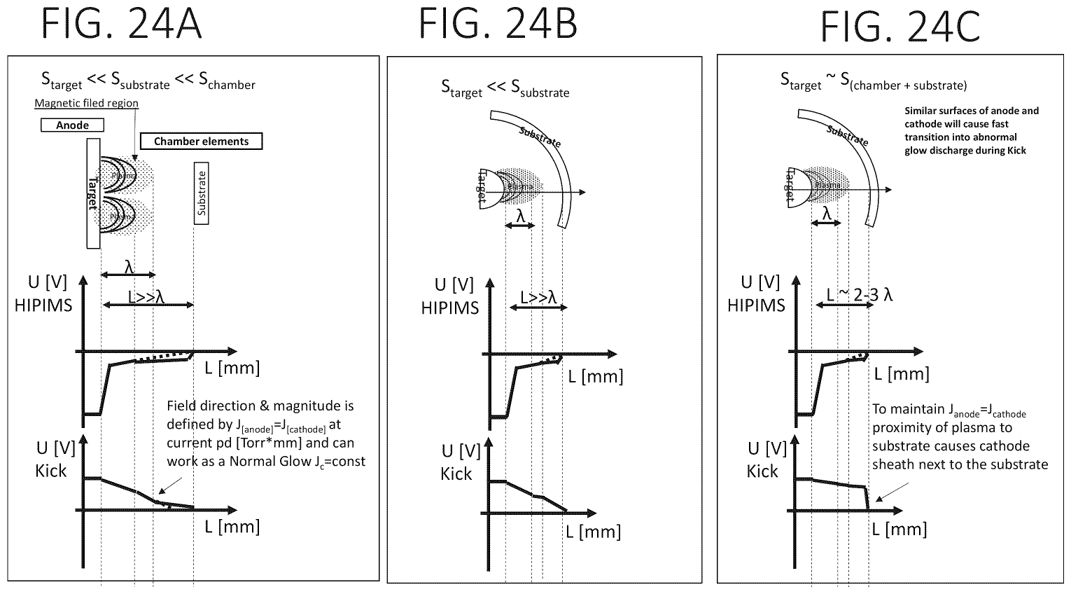

On important aspect for the application of the Positive Kick™ for conformal depositions is the Long Kick and ability to bring dense plasma and local sheath potential drop around the substrate to be coated, as shown in FIG. 8A. If the target plasma area is small compared to the vacuum chamber and the chamber is located proximal to the sputter target, then a large fraction of the Positive Kick™ energy flow will be to the chamber vs. the substrate. FIG. 24A depicts a theoretical snapshot of a plasma potential spatial profile for the representative Long Kick case where a vacuum chamber dominates in surface area over both the substrate and the smaller sputtering target, and the distance between the target and substrate is many mean-free paths-very little potential drop reaches the substrate for local conformality.

FIG. 24B depicts a corresponding snapshot of the plasma potential spatial profile for the representative Long Kick case where the substrate is much larger in surface area than the sputtering target and vacuum chamber components are negligible, and the distance between the target and substrate is many mean free paths—a small potential drop reaches substrate for local conformality. A better condition is illustratively depicted in FIG. 24C that shows a plasma potential spatial profile for the representative Long Kick case where the sputtering target is on the same order as the substrate area to be treated/coated with a material from the sputtering target, the vacuum chamber components are negligible, and a distance between the target and substrate is small-nearly all of the potential drop appears on the substrate for excellent conformality of plasma bombardment.

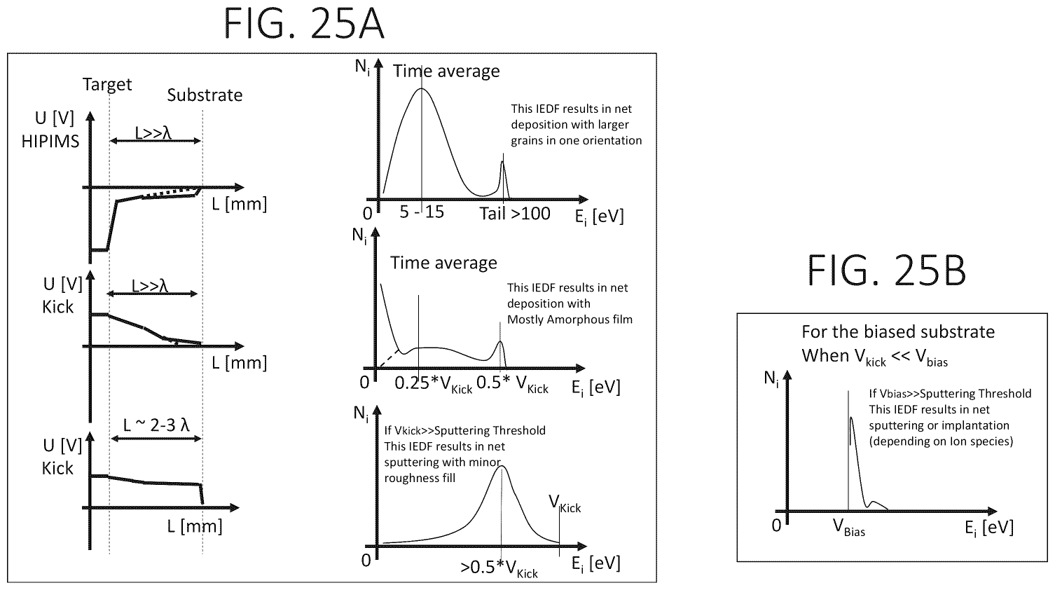

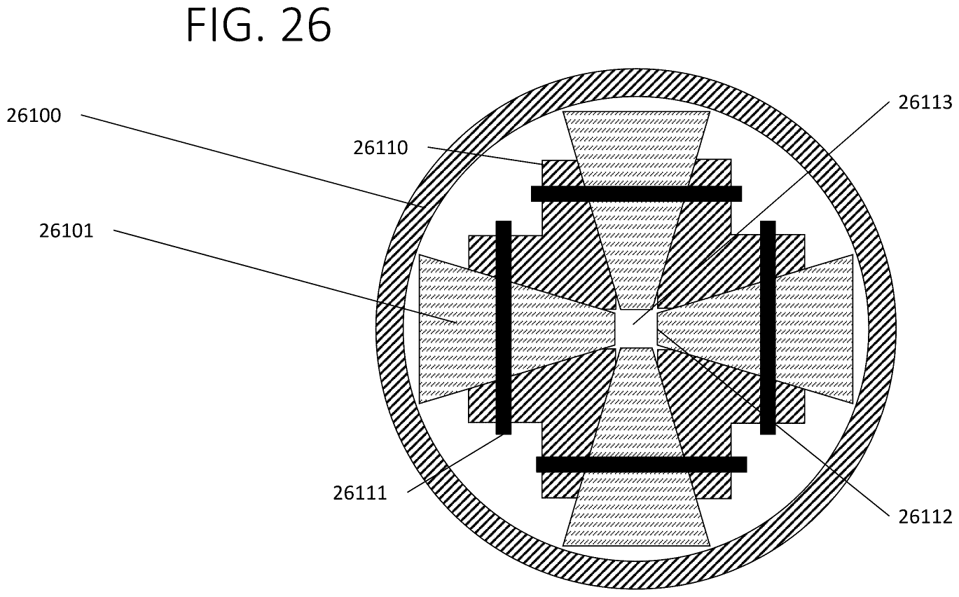

FIG. 25A illustratively depicts cases represented in FIG. 24A-C for potential profiles with their corresponding ion energy distribution functions for the Long Kick. Not shown are the ion contributions for the Short Kick and acceleration away from the dense magnetic region. These illustrations highlight the normal, abnormal and obstructed glow discharge regimes encountered during the Long Kick phases. FIG. 25B depicts an illustration of a case where an additional active bias voltage is applied to the substrate for additional ion bombardment energy.

Because of the high-quality thin and thick films that can be conformally deposited on composite material surfaces from the IMPULSE® techniques, it is possible to separate an often difficult and physically challenging process of RFQ vane tip alignment from fabricating the sealed RFQ cavity structure. As shown in the illustrative prior art depicted in FIG. 5C, the conventional approach to assembling the RF LINAC structures is to fabricate whole 3D section cavities, such as the major-minor vane construction, for assembly. Very precise and complicated construction procedures and machinery are often required, such as a 5 or 6 axis CNC milling machine. Vane sections can be bonded to the RF cavity and thereafter conformally coated in accordance with the present disclosure. This staged approach to fabricating RF LINACs permits less expensive fabrication techniques and smaller sized components to be used.

FIG. 26 illustratively depicts an example of a precision fixturing jig that facilitates aligning and gapping RFQ LINAC vanes. The particle beam channel 26113 is defined by a relative placement of the accelerator vane tips such as a vane tip 26112 that are placed around the center point in the cross-section view provided in FIG. 26. Each of the four vanes, including, for example a vane 26101 are aligned and gapped by a precision jig 26110 and affixed with ones of mechanical supports such as a mechanical support 26111. Vertical, horizontal, angular, vane undulation, intra-vane capacitance, vane tip spacing, and other properties can be measured and controlled, by removable fasteners or other mechanical means such as pins, turnbuckles, shims and spacers, with access to the vanes without the rest of the RF cavity structure introducing additional degrees of freedom and sources of error. The precision alignment jig 26110 additionally includes, for example, measurement slots and ports for conducting diagnostics and inserting probes (e.g., optical, vibrational, acoustic, electro-magnetic, capacitive bead, hairpin probes, etc). The precision alignment jig 26110 can be fabricated of materials that differ from the underlying vane 26101 materials. Depending on the bonding method and the processing conditions used to join vanes 26101 with the rest of the RF cavity body 26100, the precision alignment jig 26110 material may be selected for CTE properties, stiffness, etc. to maintain alignment and gap spacing of the vane tips 26112 during the bonding to the RF cavity 26100.

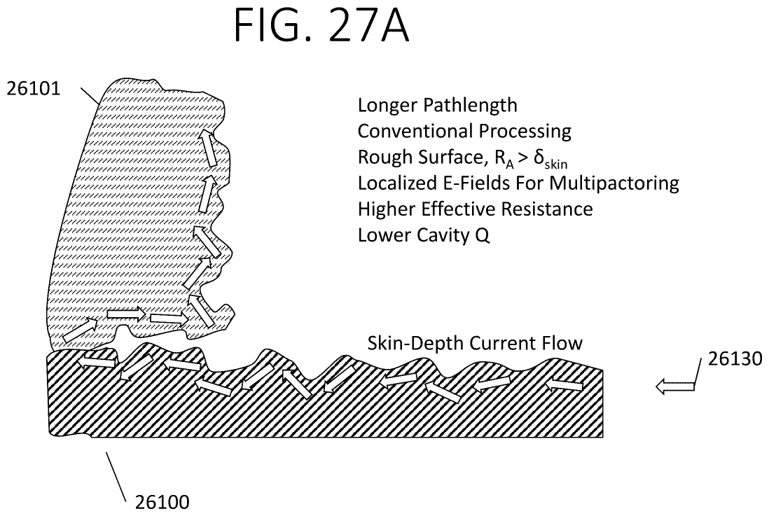

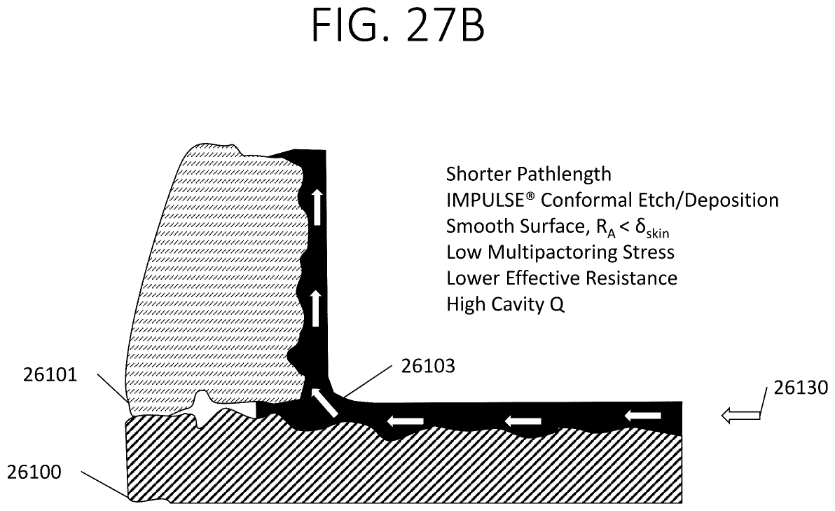

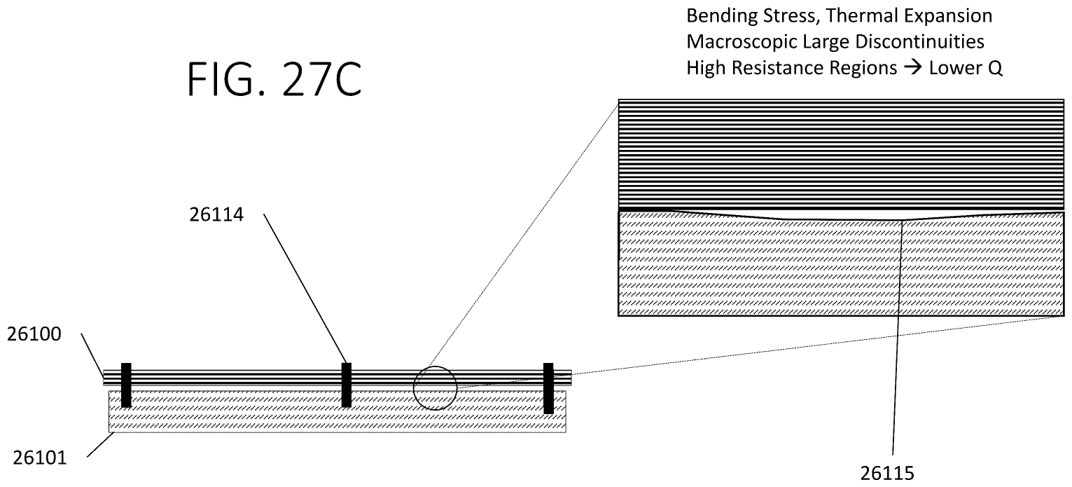

Performance of an RF accelerator greatly depends on electrical properties of the RF accelerator cavity. The electrical properties are influenced by skin-depth effects, surface roughness, grain size and boundaries, microfissures, electron transport and scattering effects off defects and inclusion, local permittivity, permeability and field diffusion, etc. These properties can be modified by the IMPULSE®+Positive Kick™ and Super Kick™ techniques to improve the intrinsic electrical properties. Extrinsic properties are influenced by changes cavity shape and vane tip position and alignment, affecting frequency, eigenmodes, dipole or higher-order modes, etc. Combined with macroscopic shape, variations is shape, interferences, frequency, temperature, expansion effects, and thermal dissipation characteristics, surface roughness, and the ability to maintain and its electrical properties. FIG. 27A, described next, illustratively depicts an illustration of the interface losses for adjoining RF surfaces and structures.

FIG. 27A depicts a cross-section view of an electrical component to illustratively depict surface current pathlength, interface losses and multipactoring stress for adjoining RF surfaces and structures for conventionally processed materials that result in relatively uneven outer conductive surfaces. Conventional room-temperature RF LINACs use electropolished copper coatings or are machined out of a solid block of copper to obtain required/desired surface material properties. Wet chemistry techniques for electropolishing and leveling vary based on conformal anode material construction, water flow, temperatures, orientation of etching/plating system, processing length, solution buffering and complex polarity kinetics with high-current bath power supplies. Even with these techniques, conventional wet chemistry typically achieves surface roughness values exceeding the skin-depth for higher frequency microwave drivers, e.g. >500 MHz. As a result, the skin-depth current flow 26130 travels very close to the surface. Because the skin-depth current flow 26130 is carried near the surface within a few skin depths, the effective current pathlength is significantly more than the perimeter of the RF cavity. This additional pathlength increases the effective resistance of the RF cavity placing an upper limit on cavity Q. Interfaces between different assemblies and materials become more problematic for localized electric field and potential differences.

In the FIG. 27A example, an undercut (gap) between tan RF cavity sidewall 26100 and a vane 26101 adds additional pathlength (the distance added by the path entering into and exiting the undercut (gap). Moreover, a potential difference will appear across the junction leading to multipactoring electron emission site risk.

FIG. 27B illustratively depicts the surface current pathlength, interface losses and multipactoring stress for adjoining RF surfaces and structures arising from RF accelerator cavity surface treatments using the IMPULSE®+Positive Kick™ and Super Kick™ techniques. The surface cleaning and etching process provide leveling effect for hills and allow for resputter to fill the valleys. The deposition processes allow for implantation/intermixing for boundary adhesion and strength for the resulting continuous conducting surface 26103 that can be deposited, by sputtering/deposition using the sealing surface material deposition procedures described herein, to the desired thickness by control of the film stress, nanostructure and orientation. By adjusting the Positive Kick™ values for optimal adatom mobility, ultrasmooth surfaces can be deposited with the IMPULSE® with average roughness less than the skin depth. The resulting ultra-smooth surface pathlength approaches an ideal geometrical case for lower effective resistance. Furthermore, the microfissures and surface interfaces are coated and covered with the continuous film 26103, thus minimizing multipactoring site risk. The continuous film 26103 is selected from a variety of source/sputter target materials according to the desired conductivity of the resulting cavity surface, including superconducting materials. The resulting continuous film 26103 increases the cavity Q to support higher accelerating gradients and/or reduce power consumption.

FIG. 27C illustratively depicts an axial position along a cavity with regions of poor electrical contact due to macroscopic effects such as bending stress, thermal expansion, material mismatch and poor mechanical RF seals at interfaces. For RF LINACs constructed with sections or segments, mechanical fasteners 26114 are used to attach and compress the interfaces. Often RF compression seals are used to make hard metal-to-metal contact, to thereby minimize electrical impedance. Unfortunately, macroscopic discontinuities 26115 form that lead to uneven current flow in the RF cavity, lower Q performance and variability over operation of the accelerator for operating parameters. Desirably, the interface between the RF cavity 26100 and the vane 26101 are continuously fixtured along the entire length of the accelerator cavity structure. This is typically accomplished using high-temperature brazing. Unfortunately, the braze material conductivity is lower than the conductivity of bulk alloys. Moreover, the thermal cycling of the RF LINAC has a major impact on dimensional tolerances and stability. However, the added engineering cost and development is eliminated using the IMPULSE® technique for the resulting continuous coating.

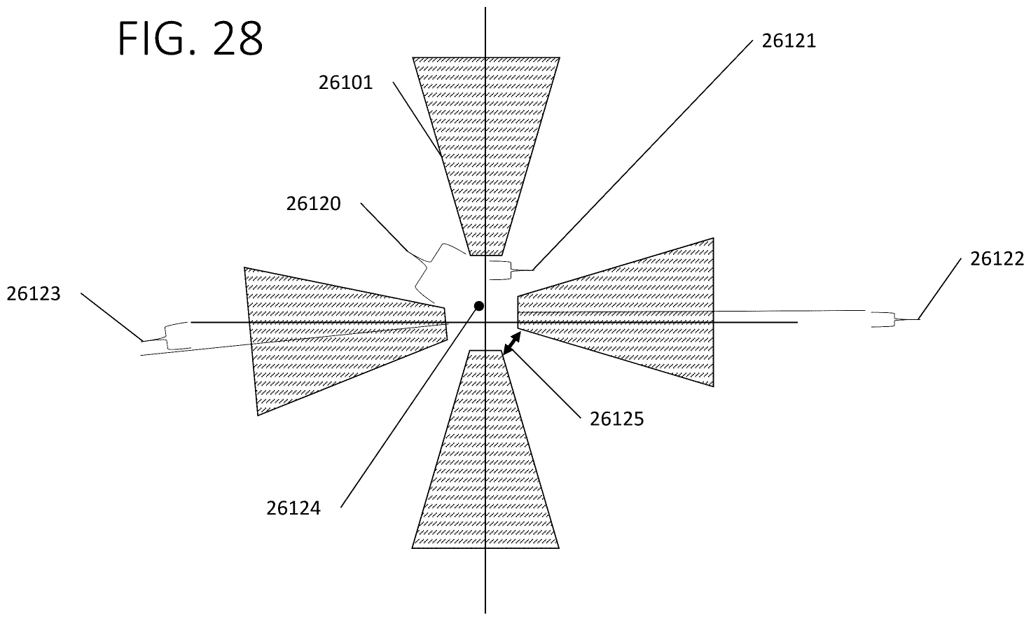

RF LINAC performance is further compromised by cross-sectional misalignment/positioning of vanes and resulting gaping between ends of the vanes, as shown in the illustrative cross-section in FIG. 28. Particle acceleration occurs due to the particle experiencing a quasi-continuous acceleration down the length of a channel formed by a set of vanes at a central location of the RF accelerator cavity. The alternating vane undulations continually change as the particle velocity increases.

FIG. 28 highlights common vane mis-alignments for the critical vane tip region that lead to lost beam transmission and very high electric field in the gap, which leads to vane tip sparking. Vanes 26101 are positioned relative to a beam axis located at the origin of the x-y lines. Basic misalignments include inline shifts along the x-axis 26122, the y-axis 26121 and z axis (not shown). With misalignment introduced (as shown in FIG. 28) the vane tips are no longer equidistant, which affects intra-vane capacitance arising from gaps, such as a gap 26120, in each quadrant. The changed capacitance affects shunt impedance, electromagnetic power balance and lowers the efficiency of power injection into the accelerator. Overcoming the signal degradation by increasing input RF power increases a local electric field 26125 at vane tips, thereby increasing the probability of sparking above a critical field threshold. Misalignment and deformation due to heating can introduce twisting on vanes such as the twisting misalignment on a vane 26123, resulting in changing a surface normal of the vane tips and introducing additional fringing to the local electric field 26125, resulting in an asymmetric focusing field for the quadrupole mode guiding the particles off axis 26124. The net result from these effects are, detuned RF cavity properties, lower cavity Q, increased sparking risk and lost beam transmission. Some of the undesirable effects arising from misalignment of vanes can be compensated with increased RF power, higher vane tip voltages, longer LINAC cavity length for lower overall gradient, etc. However, the precision alignment jig discussed earlier provides the means to mitigate vane misalignment and the IMPULSE® technique allows for continuous coatings for reduced power consumption and/or reduction in LINAC size, weight and power, i.e. the Centurion® RFQ LINAC system.

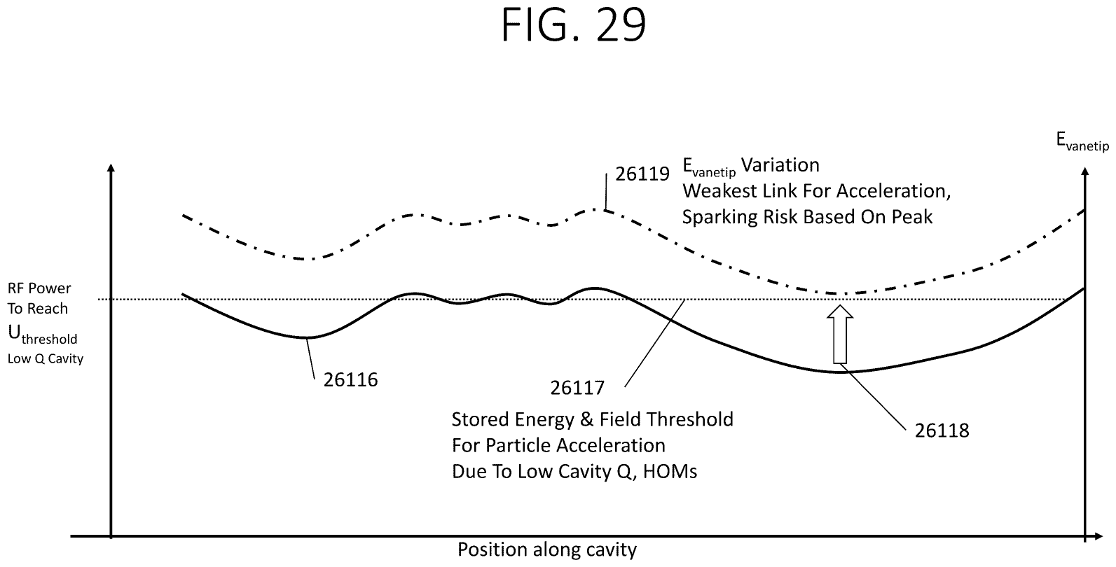

FIG. 29 graphically represents a low-Q cavity requiring high levels of input RF power to meet cavity stored energy thresholds for particle acceleration and vane tip electric field variation risk. In this representation, the cavity stored energy threshold 26117 is a function of the LINAC parameters, such as frequency, accelerating gradient, accelerator length, vane tip spacing and beam envelope, and the effective conductivity of the cavity, shunt impedance and the resulting Q factor. This equates to a nominal vane-tip electric field threshold 26117 for a perfectly aligned system. Variations in the vane alignment will provide a deviation from the optimal case for each position along the cavity, as well as sub optimal surface conductivity, increased pathlength, higher-order modes and de-tuning of the cavity resonance. The resulting vane-tip electric field profile 26116 is upshifted to an elevated vane-tip electric field profile 26119 to achieve the threshold value required for acceleration down the length of the accelerator. The penalty is the increase in RF power 26118 to achieve a desired magnitude of particle acceleration. This comes at a cost since the peak vane-tip electric field 26119 limits the sparking condition and overall risk.

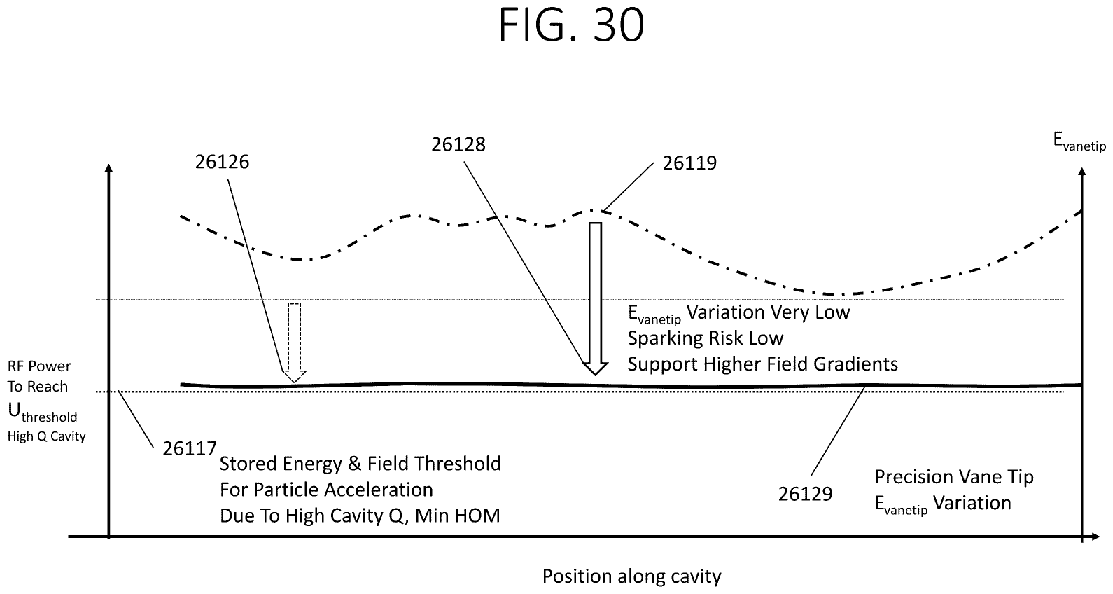

FIG. 30 graphically illustrates a high-Q cavity achieved by fabrication using the manufacturing and surface processing techniques described herein, including using a precision alignment jig and forming a coating that is processed according to IMPULSE® techniques. The resulting improved vane alignment precision and surface quality facilitates production of an RFQ accelerator that achieves lower RF power requirements and reduced vane tip variation to support higher axial accelerating gradients for overall compactness and power savings. With the increase in conductivity and reduction in resistive losses, the higher cavity Q maintains the required cavity stored energy at a lower input RF power threshold 26117 compared to the representation in FIG. 29 by an amount 26126. The peak vane-tip electric field 26119 is greatly decreased by an amount 26128 close to the cavity threshold level 26117 with a well-regulated vane tip electric field profile 26129. The reduction in E-field variation on the vane tips as shown in the profile 26129 allows greater safety margin and relaxes the Kilpatrick Limit for RF breakdown allowing higher accelerating gradients, wider frequency of operation and beam configurations, such as achieving >4 MV/m accelerating gradients for reduced power, size, weight and cost.

In general, the realm of achievable accelerating gradients is limited by arcing/sparking within the cavity itself. This is typically the dominating factor that determines the maximum electric field strengths that are sustainable within the cavity. As an example, the Kilpatrick criterion for breakdown-free operation, which is given by

$$f = ( 1.64 MHz ) {( \frac{E}{1 MV / m} )}^{2} exp ( - 8.5 ( \frac{1 MV / m}{E} ) ) ,$$

states that the maximum electric field (again, for breakdown-free operation) in a 600 MHz copper cavity structure is approximately 23 MV/m. This is effectively a soft limit placed on the maximum electric field at the vane tips of the RFQ structure, with so called ‘bravery factors’ (a multiple of the Kilpatrick criterion) of 1-2 being typical. As the electric field is raised beyond this value, arcing may become increasingly frequent. Since it is the electric field that is responsible for acceleration, this effectively places a limit on the achievable accelerating gradient that sets an upper bound on the vane-tip electric field in FIG. 30.

However, since arcing/sparking occurs almost exclusively at the vane tips in an RFQ structure, where the currents are virtually zero, the ability to either 1) coat the vane tips in an arc/spark-resistant material as a finishing step, such as Be or TiN, or 2) have the arc/spark-resistant material already present (whether as a film coating or as the bulk vane material itself) and then selectively apply the high-conductivity coating everywhere but the vane-tips will allow for an overall structure that is both high-Q and arc/spark-resistant. Simply put, the ability to utilize different materials for the cavity walls (where the currents are high) and the vane tips (where electric fields are high and arcing is a problem) allows the arcing limitations to be effectively decoupled from the material limitations of the high conductivity (Cu) cavity coating. The IMPULSE® techniques improve the smoothness of the vane tip surface to minimize local electric field concentrations. However, the material purity of the coating, work function and field-enhancement/secondary electron emission properties, coating morphology and nanostructure to minimize/inhibit whisker growth and surface atom mobility, and elimination of inclusions and local field concentrators, such as particles and impurities found in traditional wet chemistry, are also important variables controlled by the IMPULSE® and the deposition techniques in this disclosure.

The disclosure provided hereinafter is directed to enhancements to the above-described apparatuses and methods of operating such apparatuses. More specifically, methods and apparatuses enabling carrying out such methods are provided that build upon the disclosure of FIGS. 16, 17A and 17B discussed herein above. In the illustrative examples provided herein, detailed timing diagrams include various specific forms of a Positive Kick, including particular modulations of timing, amplifying and polarity that facilitate achieving specific plasma-dynamic effects for processing materials.

In accordance with the disclosure herein below, modulation of the Positive Kick-herein called the Super Kick—is performed to achieve various (four) separate effects/results. First, modulation of the Super Kick is performed to control/manipulate a diffuse plasma emitted away from a magnetron target for the generation of additional plasma and radicals for treatment of a substrate and/or a surrounding chamber. Second, the Super Kick is manipulated to control/modify generation of energetic ions capable of etching substrates such as, for example, glass, polymers and ceramics. Third, the Super Kick is manipulated to achieve a first voltage value during the Short Kick phase, and a second voltage value during the Long Kick phase. Such control over the Short Kick and the Long Kick phases is particularly applicable to operations of systems having a need for high energy acceleration of metal ions from self-sputtering in a dense plasma confinement zone near the target during a Short Kick phase, and then changing to a low voltage for the Long Kick phase where predominantly argon ions will diffuse to the substrate and transit the sheath only obtaining this lower voltage value to achieve, for example, shotpeening and densification without argon implantation. Fourth, the Super Kick is manipulated to provide the Super Kick prior to triggering a main negative pulse to obtain pre-ionization of particles in the magnetic trap to seed plasma to rapidly pulse plasma currents and minimize turn-on jitter for process repeatability.

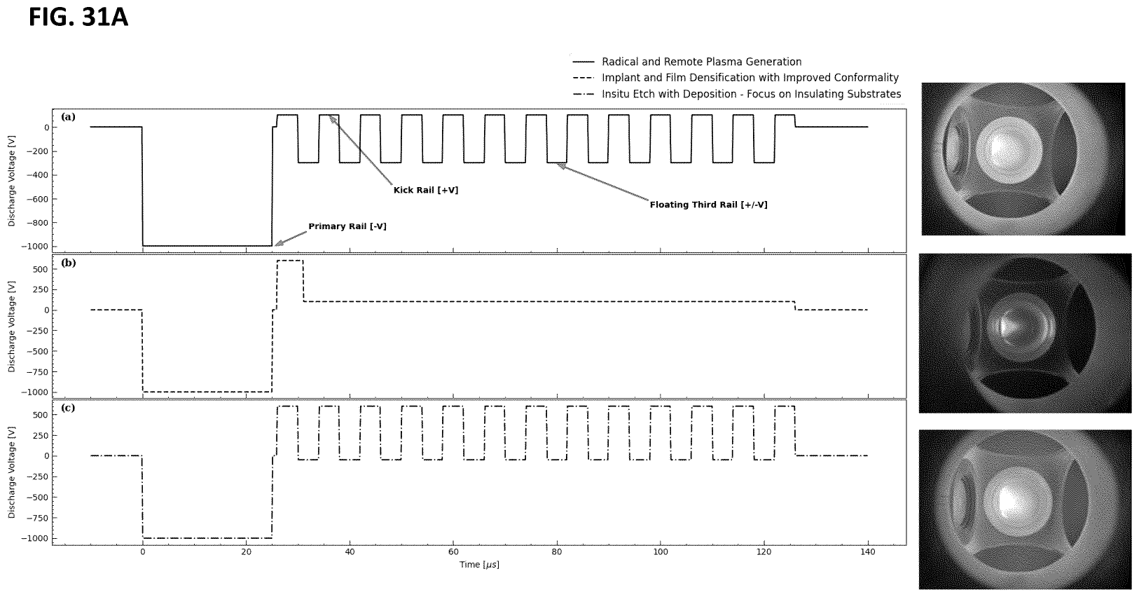

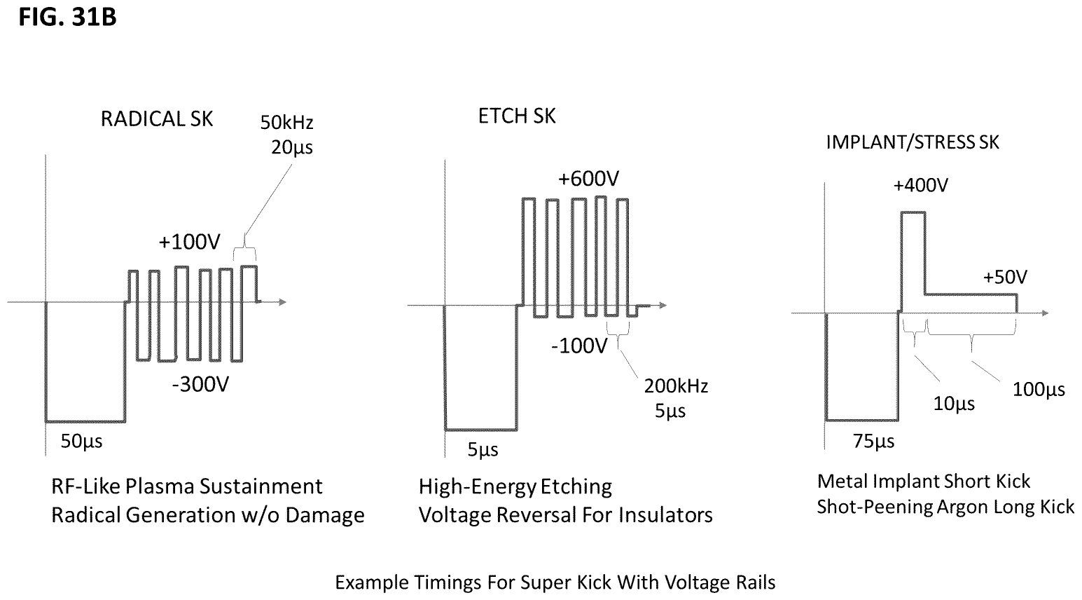

Turning to FIG. 31A, three primary modes of operation for the Super Kick are provided. A first (top) waveform image illustratively depicts a main negative pulse generating a HiPIMS-like discharge having a plasma current density exceeding (greater than) 0.03 A/cm2 over the target area. The Positive Kick portion of the pulse waveform is switched, at a configured modulation frequency, between a low positive voltage and an intermediate negative value. A switching frequency of the positive kick is from 0 Hz (standard positive kick) to about 1 MHz. A recommended switching frequency is in a range 10 kHz to several 100 kHz.

With continued reference to FIG. 31A, a second (middle) waveform image comprises a Positive Kick pulse where the pulse is initially at a high positive voltage (e.g. about 500 volts) having the effect of accelerating metal ions from a near-target magnetic confinement zone towards a substrate during an initial Short kick phase. Thereafter, voltage is reduced to a lower (still positive) voltage value during a Long kick phase. In the illustrative example, a two step effect is shown that is carried out after every main negative HiPIMS pulse. This Positive Kick (middle) waveform has been determined to be effective at achieving metal implantation while at the same time minimizing argon implantation and defects in a surface film.

Lastly, with continued reference to FIG. 31A, a third (bottom) waveform image comprises a Positive Kick pulse waveform determined to provide desirable results when performing etching. In this operating mode, the voltage is modulated at a relatively high positive voltage such that during modulation, the waveform has a high voltage value that is generally greater than 300V and a low voltage that is slightly below zero volts. The modulation of the pulse waveform signal in the third manner facilitates driving an RF-like discharge that is initially seeded with dense HiPIMS plasma and then extended and multiplied by the RF-like discharge from the magnetron target. The slightly negative lower voltage during modulation facilitates charge clearing and refreshing surfaces for a next iteration of the Positive Kick pulse waveform shown at the bottom of FIG. 31A. Depending on the frequency of the Super Kick there will be an ion energy distribution to the substrate. The photographs to the side are representative of, and demonstrate the widely variable nature of the type and quality of discharge for each of the three Positive Kick pulse waveforms depicted in FIG. 31A.

Turning to briefly to FIG. 31B, each of the three Positive Kick pulse waveforms depicted in FIG. 31A are shown with exemplary maximum and minimum voltages for various operating modes of the Positive Kick pulse. The modes are called Radical Super Kick, Etch Super Kick and Implant SK, respectively going from left to right in the set of exemplary waveforms.

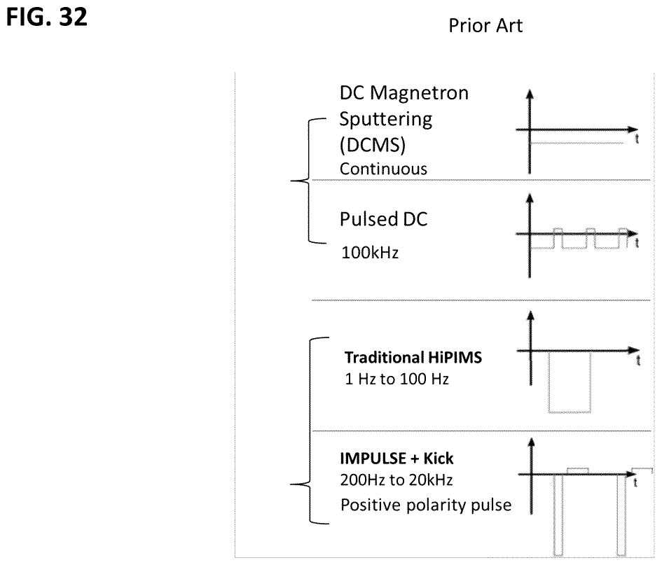

FIG. 32 summarizes prior art pulse waveforms for performing DC sputtering, pulsed DC, traditional HiPIMS with the very long main negative pulse, and Positive Kick. The present disclosure is directed to changes to a basic Kick Pulse to affect the plasma and resulting deposition/etch functionality.

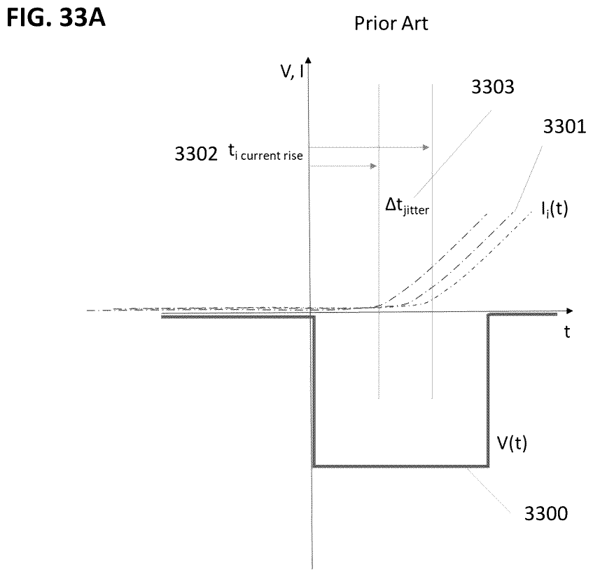

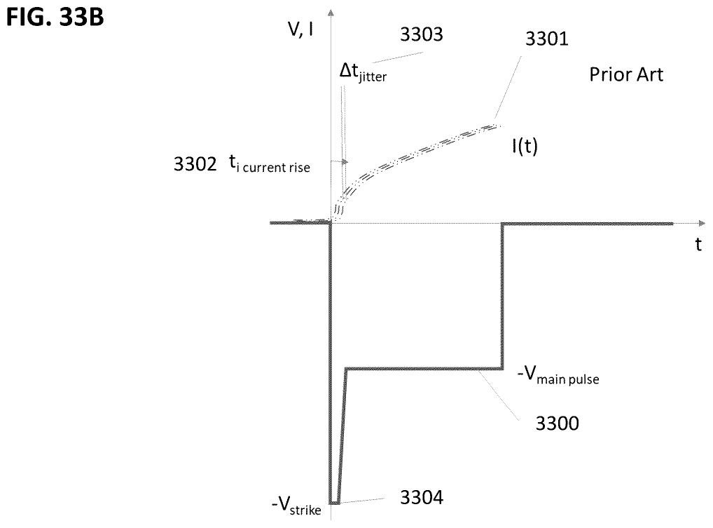

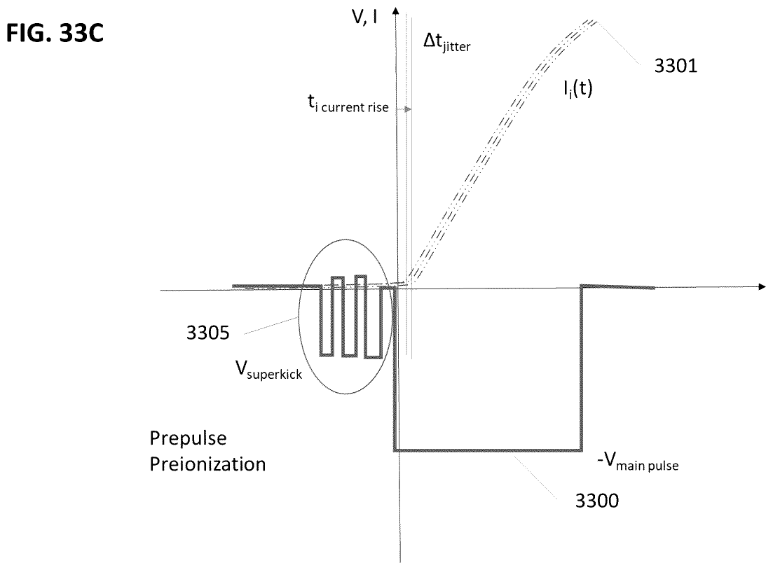

It also is beneficial to improve plasma process reliability. Turning to FIG. 33A, a conventional HiPIMS main negative pulse is shown. At time t=0, a main voltage waveform 3300 is applied. A resulting electrical current waveform 3301 takes an initial time 3302 to bootstrap plasma in a magnetron and increase current density. As a result, there can be a turn-on jitter 3303 that can cause process variations. Such turn-on jitter has been previously addressed by engineering power supplies to supply an initial strike pulse at turn on.

FIG. 33B shows an illustrative waveform with addition of a strike pulse 3304 at a start of the pulse voltage waveform 3300. The strike pulse 3304 may be, for example, more than two times the magnitude of the nominal run condition and therefore poses a technological challenge for operation of HiPIMS devices. With the application of the strike pulse 3304, the high voltage causes a very steep bootstrapping of electrons in the magnetic trip greatly speeding the gaseous multiplication and ionization on the target to achieve higher density and current ramp for self sputtering. While the strike pulse 3304 may be relatively easy (in concept) to implement, incorporating such effect in the HiPIMS waveform causes problems on targets that are dirty, need conditioning or in cases where material type is easily prone to arc formation. In this case, the strike pulse can have a detrimental effect because of particle generation and molten droplet formation that is an anathema for semiconductor fabrication.

FIG. 33C provides an illustrative waveform facilitating features such as providing requisite preionization near the magnetron for bootstrapping of current-without a need for a very high voltage strike pulse (see FIG. 33B) that is prone to arc and droplet particle generation. In FIG. 33C, a modulated Super Kick preionization pulse 3305 is applied immediately prior to the main negative voltage 3300 to achieve high current densities for HiPIMS. Applying an RF-like oscillatory voltage directly to the target electrode, by the nature of the magnetic fields present around the magnetic trap, will cause electrons to oscillate back and forth and gain energy to start ionization cascades having the effect of “seeding” the plasma for this activity. This enables the current, indicated by a current waveform form 3301, to rise rapidly. Note the preionization pulse 3305 waveform can take several forms ranging from an RF-oscillatory signal to a relatively simple application of a short negative voltage pulse of at least 100V magnitude for electrons to cause impact ionization or Penning ionization within the magnetic trap. This allows for consistent striking-especially with difficult to sputter and arc prone materials

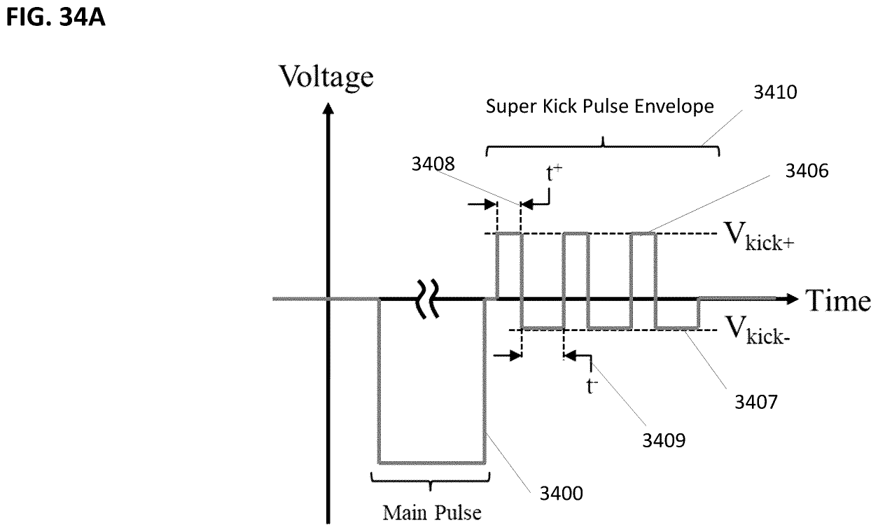

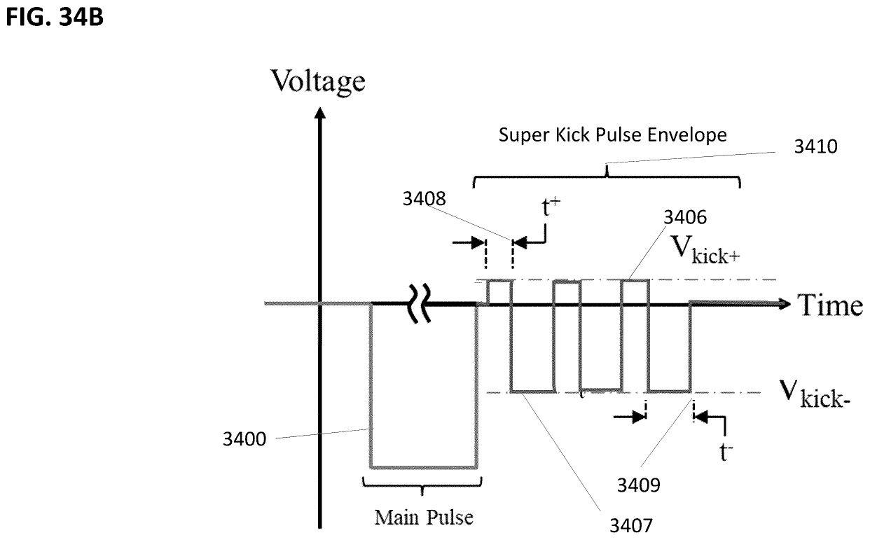

Turning to FIG. 34A a further exemplary Positive Kick pulse waveform is provided that incorporates a RF-like application of the Positive Kick pulse after terminating a main negative voltage waveform 3400. This RF-like application occurs over a Super Kick pulse envelope 3410. The duration of the envelop 3410 is settable to accommodate several RF cycles of during a Super Kick portion of the waveform. There is a V_kick+ positive voltage 3406 and a V_kick− negative voltage 3407. A duration of a pulse width 3408 of the V_kick+ pulse is separately configured/established with respect to a duration of a pulse width 3409 of the V_kick− pulse. Several RF-like oscillations occur within the envelope 3410. In the illustrative example of FIG. 34A, the main negative pulse 3400 generates a dense HiPIMS plasma exceeding a 0.03 A/cm3 threshold. The dense plasma, after generation, then diffuses towards a substrate. The positive width 3408 of the V_kick+ is adjusted in association with adjustments to the negative width 3409 of the Vkick− to produce different fluxes of ions and electrons to the substrate and different results. For substrates that are strong insulators, “clearing of charge” is important to prevent crazing, prevent surface arcs and minimize particle generation and defects. The V_kick+ rail voltage 3406 is set along with the opposite Vkick− rail voltage 3407 to define the upper and lower voltage boundaries of the envelope 3410 during super kick operation. Note that the envelope for Super Kick can have a relatively long time duration. The modulation of the signal within the Super Kick envelope 3410 in FIG. 34A with sufficient voltage differential between Vkick+ 406 and Vkick− 407, results in generation of a quasi RF like discharge.

Turning to FIG. 34B, a Super Kick envelope 3410 is again present with modulation. However, the voltage levels are all reduced in comparison to those shown in FIG. 34A. In particular, the positive Vkick+ voltage is maintained low to minimize ion energy delivered to the substrate from a Vkick+ 3406 (e.g., not greater than 100V). Additionally, the Vkick− 3407 is lowered to provide a needed ˜300V voltage difference between the high and low voltage levels (rails) of the Super Kick envelope 3410. With sufficient voltage level difference between the positive and negative levels within the modulating signal within the envelope 3410, a RF-like nature of electron movement can be sustained and a remote plasma bootstrapped.

In operation, during the main pulse 3400, plasma composed of a working gas and sputtered material from a sputter target is ionized to form a plasma. A bipolar Super Kick pulse follows in the Super Kick envelope 3410. The bipolar Super Kick pulse comprises a series of voltage level modulations between positive voltage levels at Vkick+ 3406 and negative, or less-positive voltage levels at Vkick− 3407 that ionize the working gas and sputtered material, which has the additional effect of generating radicals, both ionized and neutral. The radicals diffuse to a substrate in a case of neutral radicals, or they can be accelerated by a positive potential applied during the bipolar Super Kick pulse train within the envelop 3410. In addition, the persistent plasma sustained by the modulated electric field of during the Super Kick envelop 3410 creates ambipolar potentials at material boundaries, such as the substrate, that also accelerate ionized radicals into the substrate. Moreover, in accordance with illustrative examples, the Vkick+ and Vkick− potentials can be modified in value and/or duration to not only generate plasma and radicals, but also to control an amount of average electrical current delivered to the substrate by the plasma, depending on the chosen values of Vkick+ and Vkick−. The resulting radicals modulate chemical reactions primarily on the substrate, but also in the gas phase, during deposition.

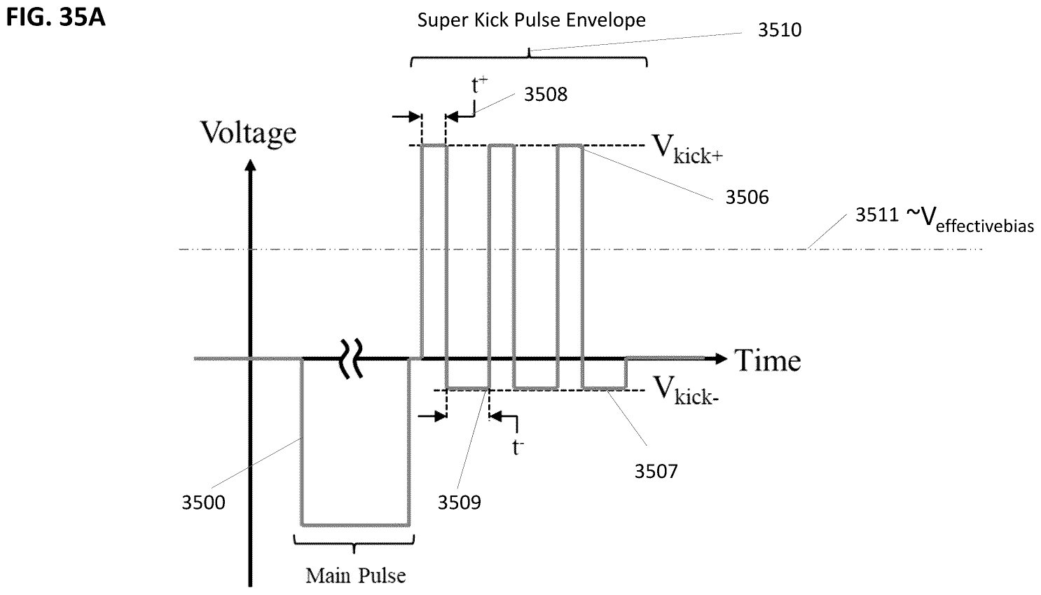

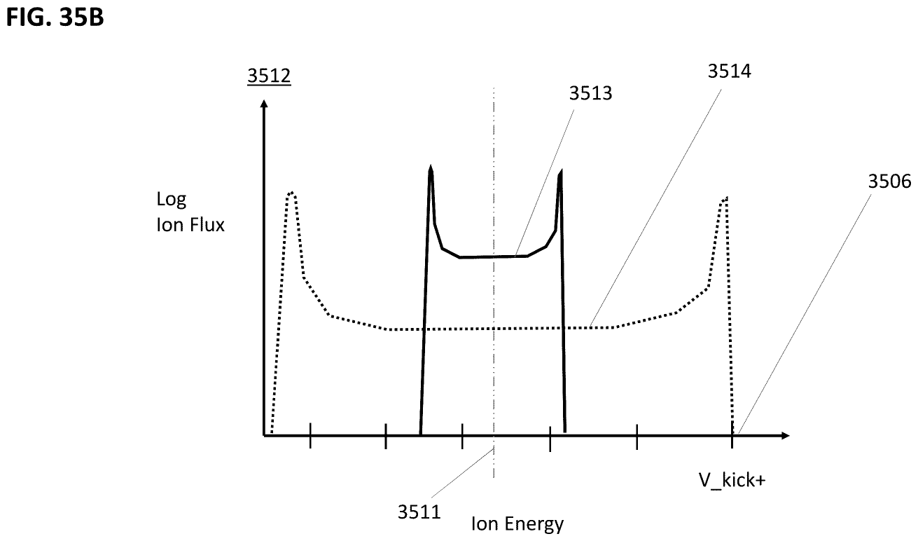

Turning to FIG. 35A, an exemplary Positive Kick waveform is provided for treating insulating substrates that require deep etching. Main negative pulse 3500 is applied to generate a HiPIMS plasma with sufficiency current density to achieve high plasma density and ionization fraction. For very short durations of the main pulse 3500 resulting particle species will be predominantly carrier gas—e.g., Ar. A Super Kick pulse is applied according to a Super Kick envelope 3510 where a positive voltage level is relatively very high for a V kick+ rail 3506 over a pulse width 3508. The very positive voltage commutes through a dense plasma in a target-substrate gap and eventually produces a sheath at the substrate for high voltage ions to bombard. The high voltage ions have sufficient energy to induce etching on the substrate from hundreds of eV ion energy. For insulating substrates the surface can charge up to inhibit and repel future ions from etching. However, such effect is countered by the Super Kick voltage being lowered to a negative voltage potential of a negative rail Vkick− 3507, over a period depicted by a pulse width 3509, multiple times within the period of the Super Kick envelope 3510. The negative bias—typically only a few tens to a few hundreds of volts negative—is sufficient to equilibrate surface charge with the bulk plasma to prepare the substrate for a next instance of the positive super kick pulse depicted in FIG. 35A.

Since the Super Kick is acting quasi RF-like, the effective ion energy to the substrate is modified by the Super Kick Pulse envelope 3510 effective frequency. The modulation of the input voltage within the envelope 3510 at a sufficiently high frequency establishes an effective RF bias 3511. FIG. 35B illustratively depicts an effective ion energy 3512 for the case of a low Super Kick frequency 3514 and a high Super Kick frequency 3513. The low frequency case-typically in the 10-100 kHz range will yield ion energy distribution 3514 with a peak energy 3506 defined by the V_kick+ higher rail voltage with an ion energy in the middle 3511. For modulation of voltage within the Super Kick envelope 3510 at higher repetition rates (e.g. greater than 200 kHz and up to a MHz range), the ion population in the plasma near the substrate becomes less responsive to applied fields with slower transit times, resulting in the ion energy distribution function becoming tighter and more centered in bandwidth on the V_kick+ half value based on a difference between V-Kick+ 3506 and V_kick− 3507.

Following the main negative pulse 3500, a mid-frequency pulse is generated with a higher potential positive pulse. A high voltage Positive Kick pulse, as shown in FIG. 35A, to accelerate ions away from sputter target toward substrate and additional negative pulses at an intermediate potential between the short high kick operate to modify the sputter target surface by one or more of the following processes: neutralizing surface charge, implanting plasma ions into the surface, cleaning the surface, and generating plasma in the sputter-target substrate gap to accomplish plasma activation of the substrate, cleaning of the substrate, implantation of ion species in the substrate (including for generating porosity), and ionizing/activating gas species and particles in the intervening space. Independently controllable pulse widths between rails allow selection and tunability of any one or more of the above-listed target surface treatment processes.

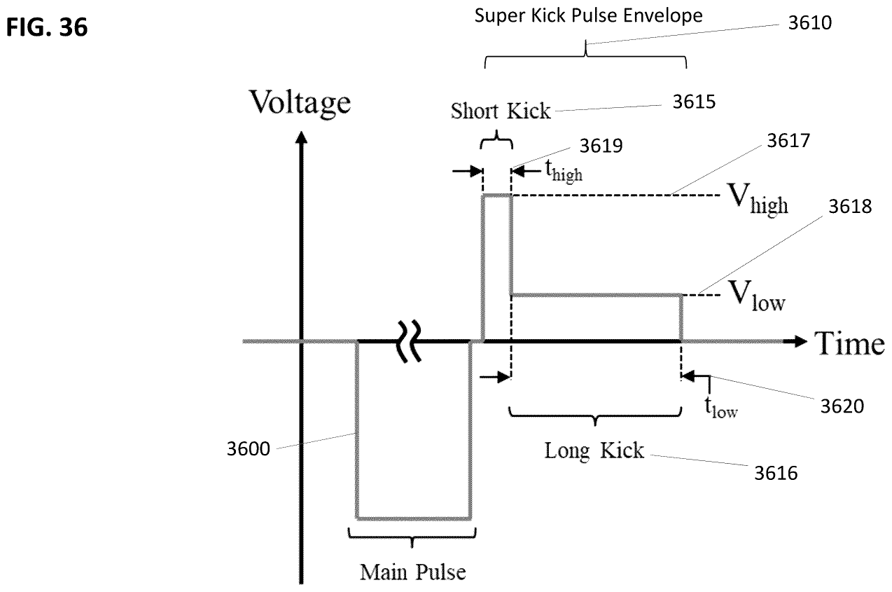

Turning to FIG. 36, a non RF-like application of the Super Kick is illustratively depicted for controlling the ion energy distributions for metal ions from the target and gas ions in a diffuse plasma. A main negative pulse 3600 is applied to generate a HiPIMS plasma with suitable metal ion population in a magnetic trap region having a high density. The main pulse 3600 ends and immediately thereafter, during a Short Kick phase 3615, a relatively very high positive voltage pulse at a voltage level 3617 is applied for a duration of a pulse width 3619 that causes metal ions currently in the magnetic trap region to be accelerated towards a substrate with relatively very high energy in accordance with the relatively high voltage level 3617. The very voltage energetic short kick phase of the pulse during the Short Kick phase 3615 accelerates predominantly metal ions or a high Me/Ar ratio towards the substrate. Implanting metal ions with high energy in the substrate, in turn, causes collision cascades and efficient energy transfer to access a wider region of a structure zone diagram. Operation in the manner summarized in FIG. 36 is very effective for subplanation processing of a substrate where energetic metal ions penetrate through several atomic layers of a substrate, and into sublayers can cause phase change or desired material properties in such layers of the substrate. After completing the short kick phase 3615, the voltage of the Super Kick pulse is lowered to a relatively lower, but still positive voltage level 3618 to lessen positive voltage bias commuted to the diffuse plasma in contact with the substrate. A Long Kick phase 3616 that follows, at the relatively lower voltage, is characterized by acceleration of gas ions and some metal ions that fall into the near-substrate plasma sheath. The Long Kick phase 3616 has a period 3620 having a duration configured to enable depopulating diffuse plasma. Adjusting voltage level of positive voltage level 3618 to a level that minimizes or inhibits implantation allows Ar ions to provide surface mobility, densification and thermal energy without causing defects or embedding Ar into interstitials that can lead to residual compressive stress.

For the Implant and Stress-Control Super Kick, a two-level Super Kick pulse is used that stays positive. As with the other methods, the main pulse 3600 generates a dense plasma rich in sputter target material. The High Vkick+ 3619 would typically be short to accelerate only the ionized sputter-target material toward the substrate while minimizing the amount of working gas accelerated toward the substrate. The higher-energy ions then implant in the substrate surface, which can also promote mixing of materials. The Vkick, low voltage 3618 then accelerates residual plasma, both ionized working gas and ionized sputtered material, toward the substrate. This generates a lower-energy flux of ions at the substrate, which can be used to control film stress by modulating the amount of adatom surface mobility.

Controlling voltage level of the Positive Kick pulse to include a very high initial kick pulse voltage to implant ionized sputter species, followed by a substantially lower voltage pulse between main negative pulse and kick pulse voltage furthermore facilitates controlling one or more of: film stress via lower-energy ion bombardment (shot-peening action) for stress control, porosity control, introduction of ionized gas species, substrate cleaning, and chemical reaction processes. The disclosed voltage level and duration controls are also used to improve the degree of conformality of sputtered films by initially achieving a high ionization fraction of the sputtered atoms that are in-flight and subsequently lowering the applied voltage to contract the plasma sheath and reduce the possibility of resputtering of the substrate surface. Moreover, maintaining high ion fraction after the initial plasma forming main pulse allows for ambipolar diffusion to distribute sputtered material more conformally than that of conventional PVD line-of-sight methods. Additionally, the resulting increased low-energy bombardment has the effect of providing a controllable increase in adatom mobility, which depending on material allows for control over film density and stress as well as further increasing conformality due to a drop in sheath thickness.

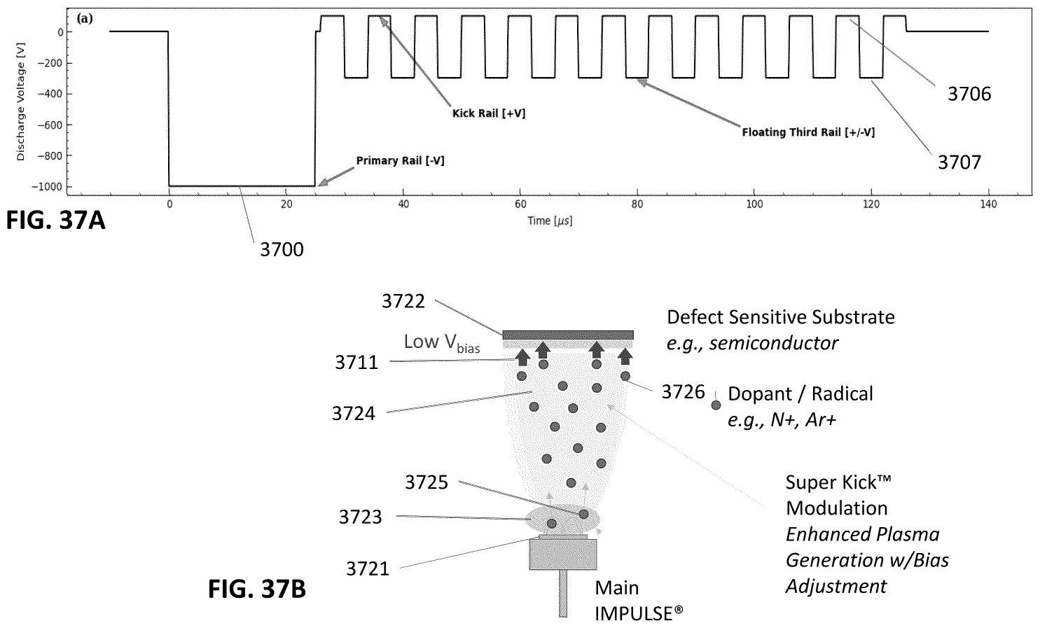

Turning to FIGS. 37A and 37B, a combination of illustrative depictions of a waveform and corresponding physical/electrical effect on magnetron sputtering structures is provided that highlight aspects of voltage/timing control of the Super Kick pulse discussed herein above with reference to FIGS. 34A and 34B. A main negative HiPIMS pulse 3700 voltage applied to a magnetron target 3721 results in generating a dense metal sputtering and plasma within a magnetic confinement zone 3723. Metal ions 3725 are generated and accelerated towards a substrate 3722 when the Super Kick pulse is at a high voltage 3706 of a positive rail that is applied across the magnetic field. The dense plasma 3724 diffuses towards the substrate 3722 and produce a conformal sheath. Modulating the voltage (at sufficiently high frequency—per the discussion above) between a negative rail voltage 3707 and a positive rail voltage 3706 within an envelope of the Super Kick pulse, following the main negative HiPIMS pulse 3700, generates additional plasma in the gap between the target 3721 and the substrate 3722. The positive rail voltage 3706 biases a diffuse plasma 3724 that will acquire an RF bias that bombards the substrate 3722 with a low effective bias 3711. The combined effect of the RF super kick and plasma generation through RF-like modulation of an electric field during the Super Kick phase of operation generates additional radicals and ions 2726 near the substrate 3722. The radicals and ions are potentially beneficially utilized as: dopants, reactive gas bonding material, and surface modifiers.

As with a ‘bipolar’ Super Kick for radical generation, Etching Super Kick uses a series of positive pulses 3506 following the Main Pulse 3500, and lower-voltage, or negative pulses, 3507 between the positive Super Kick pulses. The positive and negative pulse structure in the Super Kick need not be symmetric, meaning the width of a positive pulse 3508 can differ from the pulse width of the negative pulse 3509. For Etching Super Kick, a higher Vkick+ is chosen so that ion reach the substrate with enough energy to remove material via sputter of the substrate. The return of the Super Kick voltage to lower or negative potentials generates the changing electric field and plasma formation necessary to form the ions used to accomplish etching. The size and width of the negative pulses 3509 can be used to control the starting location and species of the ions to be accelerated toward the substrate. For example, a long negative Vkick− 3507 may cause plasma formation predominantly at the sputter surface, so the starting location would be near the sputter-target surface. When the positive polarity reversal occurs, these ions then are accelerated away from the sputter target, often by electric field lines that are substantially perpendicular the magnetic stream lines, resulting in a directional flux of ions toward the substrate surface that can allow deep trench etching/resputter processes. A complementary function can be served with a positive, or less negative, Vkick− 3507 by forming plasma in the volume between the sputter target and the substrate, resulting in a quasiconformal flux of ions on the substrate surface. The negative portions of the Super Kick pulse can also regenerate near-surface species, such as oxides, on the sputter target for sputtering during subsequent Main Pulses.

In summary of the above, the main negative pulse 3700 followed by a Super Kick pulse characterized by modulated voltages between a relatively high and intermediate voltage, results in series of RF-like voltage pulses of positive, negative, or both polarities to generate plasma and accelerate ion species into both the substrate and the sputter target to effect cleaning, ion implantation, surface porosity control, texturing, etching, charge neutralization, ion-species reactions, and stress control. The RF-like pulses, at sufficiently high modulation frequency, generate plasma outside of the magnetic confinement zone 3723 to allow for good conformality across all surfaces, even for insulating films which may charge up to high surface potentials under traditional sputtering conditions. In addition, the RF-like pulses within the Super Kick envelop of the pulse generation scheme summarized in FIG. 37A facilitates controlled addition of ion energy during reactive deposition by ensuring charge clearing on an insulating substrate.

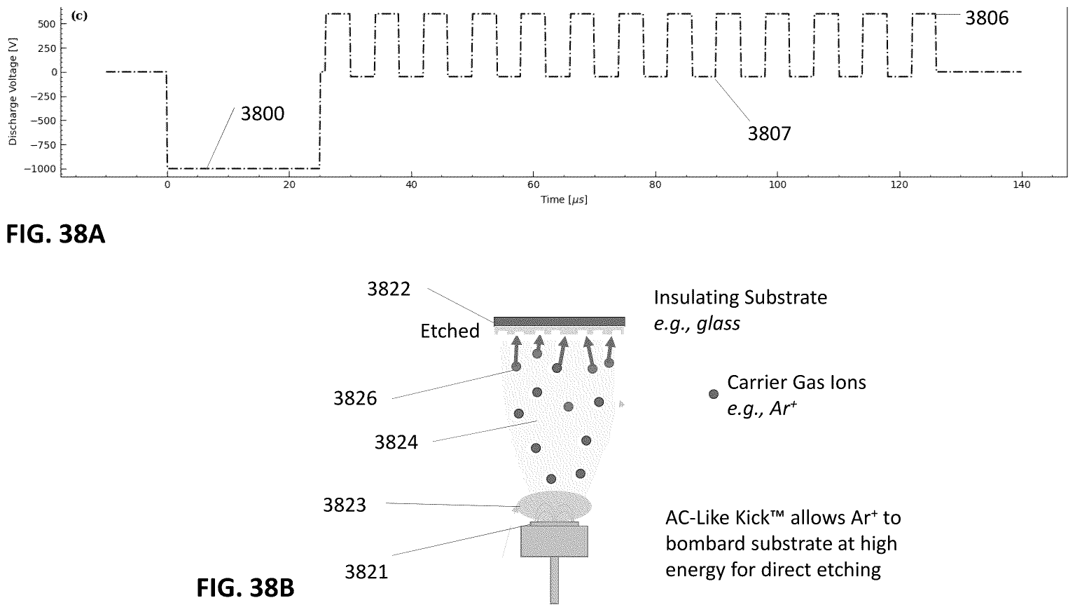

Similarly, referring to FIGS. 38A and 38B, the relatively much higher voltage, etching mode, Super Kick pulse operation is shown with the application of a high voltage 3806 after applying a main negative voltage HiPIMS pulse 3800 that forms plasma. A negative rail voltage 3807 of the Super Kick pulse is slightly negative voltage in order to induce a charge clearing action on a substrate 3822 to prepare for a next wave of ions for bombardment at an effective ion energy based on a repetition rate. A magneton target 3821 is pulsed with a negative electric field created by the main negative voltage HiPIMS pulse 3800, and generates a dense plasma in a magnetic confinement zone 3823. For short main pulse widths the plasma will be relatively high concentration of gas ions versus metal ions, especially if the applied negative rail voltage 3807 is below a self-sputtering threshold. In such scenario, the Super Kick pulse electric field engages and diffuses the dense plasma, in the magnetic confinement zone 3823, towards a target-substrate gap. The Super Kick pulse rail high voltage 3806, as shown in the waveform depicted in FIG. 38A, generates an effective RF bias for etching on plastics, glass, ceramics using the charge equilibration feature of the Super Kick's RF-like response. Energetic ions in the sheath region 3826 are accelerated into the substrate for etching.

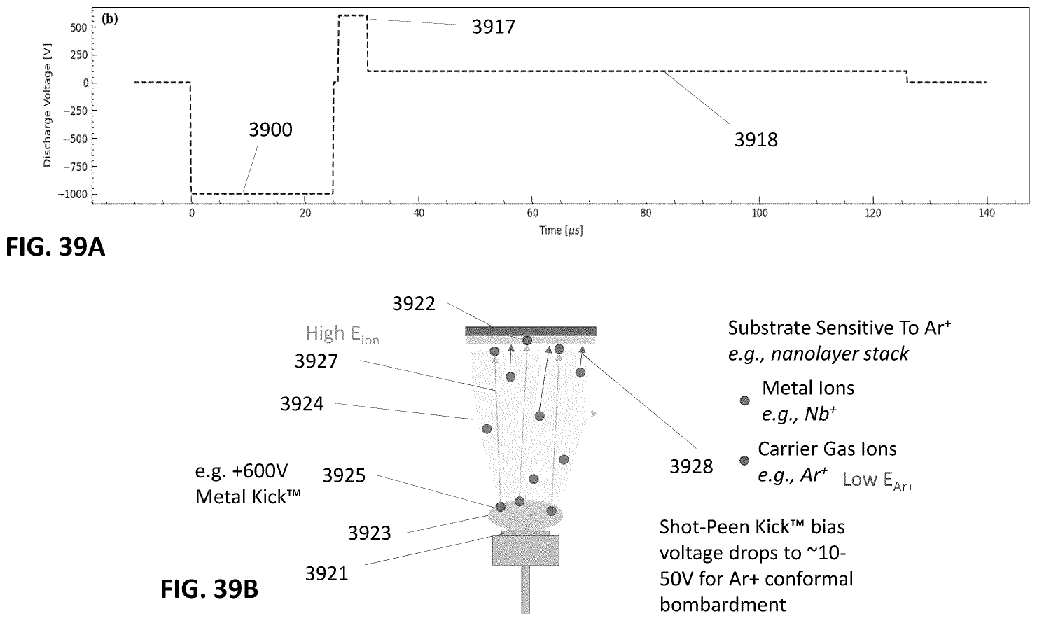

Turning to FIG. 39, yet a further example is provided for controlling voltage of a Positive Kick pulse to achieve particular properties of a resulting surface treatment operation. In the illustrative example, a process for metal ion energy control is quasi independent from generating sputter gas ions. In the illustrative example a main negative HiPIMS pulse 3900 is applied to generate an electric field that engages and generates a dense and metal-dominated plasma from the target 3921 in the magnetic confinement zone 3923. Metal ions 3925 are accelerated, perpendicular to a gradient in a magnetic field 3927, by applying a rapid Positive Kick at a high voltage 3917 to accelerate the metal ions 3925 into a substrate 3922. The high voltage 3917 is applied over a relatively short kick period, and thereafter voltage of the Positive Kick pulse is lowered to a relatively lower voltage 3918 for a relatively long duration shot peening phase where a diffuse plasma 3924 expands to touch the substrate 3922, create a quasi-conform sheath on the substrate 3922 surface and accelerate lower energy carrier gas ions 3928 to provide energy to the substrate 3922 surface without damage.

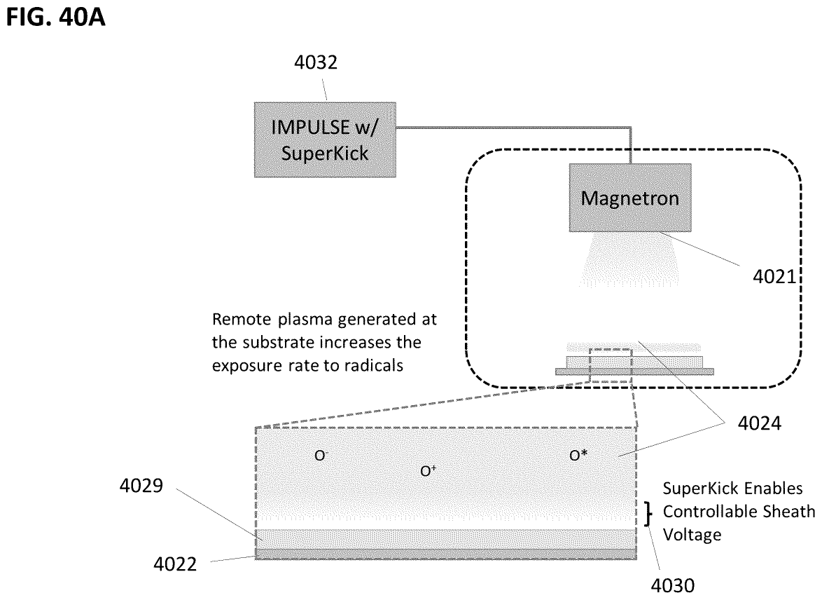

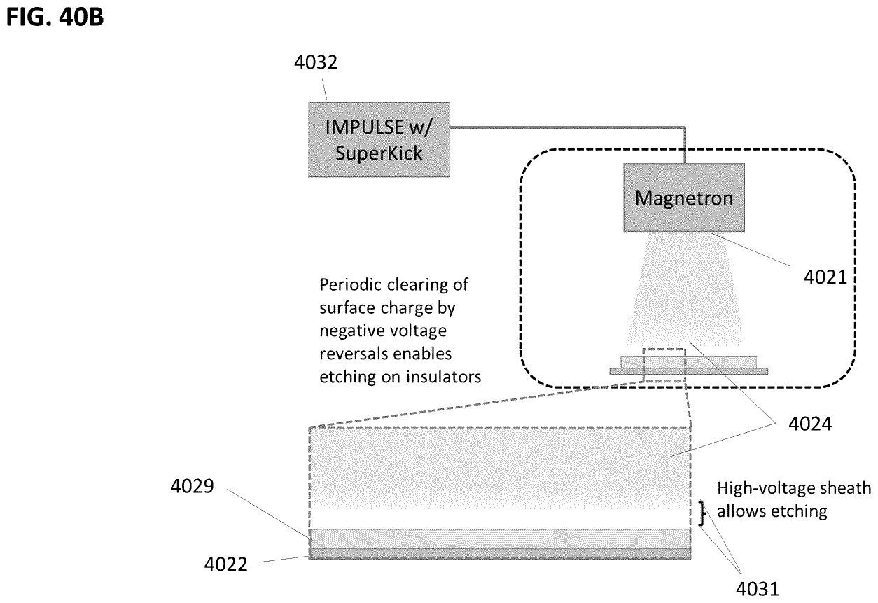

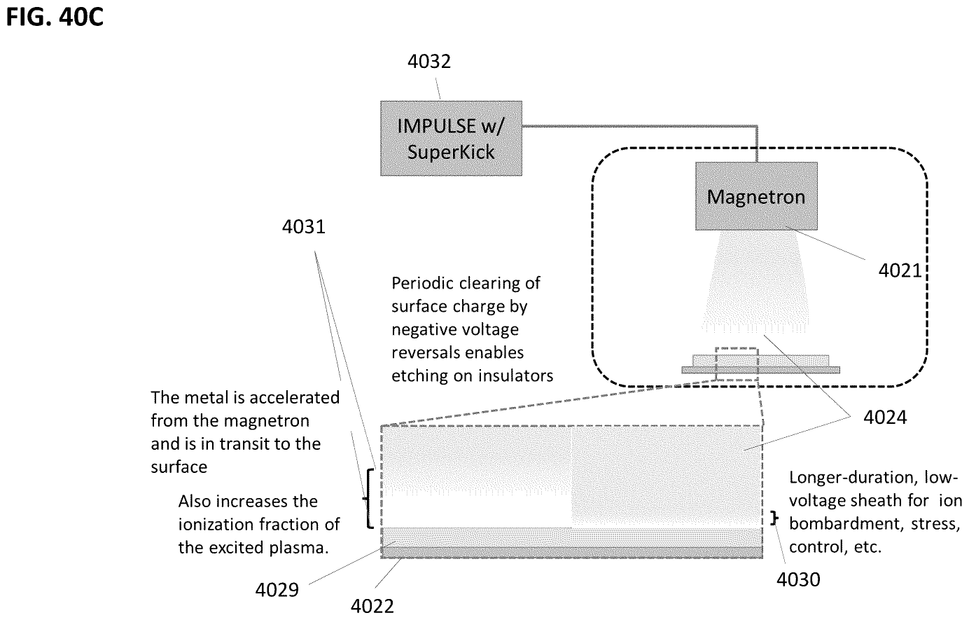

FIG. 40A is another illustration of a remote plasma generation process using a magnetron 4021 with Super Kick power waveform provided by an impulse power module 4032. A diffuse plasma 4024 expands to interact with a substrate 4022 and a resulting thin-film 4029 on the surface. SuperKick voltage modulation controls a sheath 1030 voltage and ion energy and flux.

In accordance with the process summarized in FIG. 40B, increasing the Super Kick rail voltage very high enables effecting at the substrate, from the diffusion plasma with a high-voltage sheath 4031, etching on a film 4029 or a substrate 4022.

In FIG. 40C, the Super Kick pulse generation scenario is adapted for performing metal implantation where ions are accelerated from the magnetron 4021 and transit a chamber towards the substrate 4022 and the film 4029. The metal behaves as an ion gun beam and/or there is a very high sheath distance at the substrates because the plasma has not equilibrated during the short kick phase. Later, a longer duration, relatively low-voltage Kick voltage sheath 4030 produces shot peening and densification with less issues for deposition to metals like Ta.

For the Radical Super Kick mode in FIG. 40A, a typical setpoint is +100V kick positive, −300V super mid rail to have a ‘delta’ of 300-400V at high frequency 0.01-1 MHz to drive an “RF-like” plasma. The positive voltage is limited to about +100V to not cause ion damage on the substrate, while still generating large amounts of plasma radicals for O, N, C, etc. The method was developed to generate additional plasma near substrate for reactive applications, while still taking dense HiPIMS plasma from main negative pulse and kick towards the substrate. Central to the technique is driving asymmetric pulsed-DC/symmetric RF-like plasma at about 0.1 MHz to generate an extended plasma between the substrate and target. Voltage differential is sufficient to sustain plasma but not energetic enough to damage sensitive substrates.

For In-Situ Dep/Etch for insulating substrates as shown in FIG. 40B, a dense HiPIMS plasma is generated by a main negative pulse and thereafter, the ions are accelerated by a high positive kick voltage towards the substrate. An asymmetric pulsed-DC/symmetric RF-like plasma is driven at approximately 0.1 MHz modulation to generate an extended plasma at the substrate. A high +V for Ar+ etching with −V voltage reversal for charge clearing on the insulating substrate. AC-Like Kick™ allows Ar⁺ to bombard substrate at high energy for direct etching.

For the Implant/Stress Control Super Kick Mode shown in FIG. 40C, a typically value is +400-600V kick positive, +20-50V mid rail. This maximizes metal ion implant right at beginning, then shot peeping without Ar implant for stress control. The technique was developed to implant only metal ions during the “short kick” phase and keep Ar shot-peening. During the positive kick pulse phase, dense metal-rich HiPIMS plasma from the main negative pulse is kicked towards the substrate. A short high +V pulse part of the positive kick pulse accelerates metal ions from the magnetic trap for implantation before potential commutation. Thereafter, a relatively long low +V portion of the positive kick pulse provides a conformal sheath around the substrate with low energy for shot peening without etching/implantation.

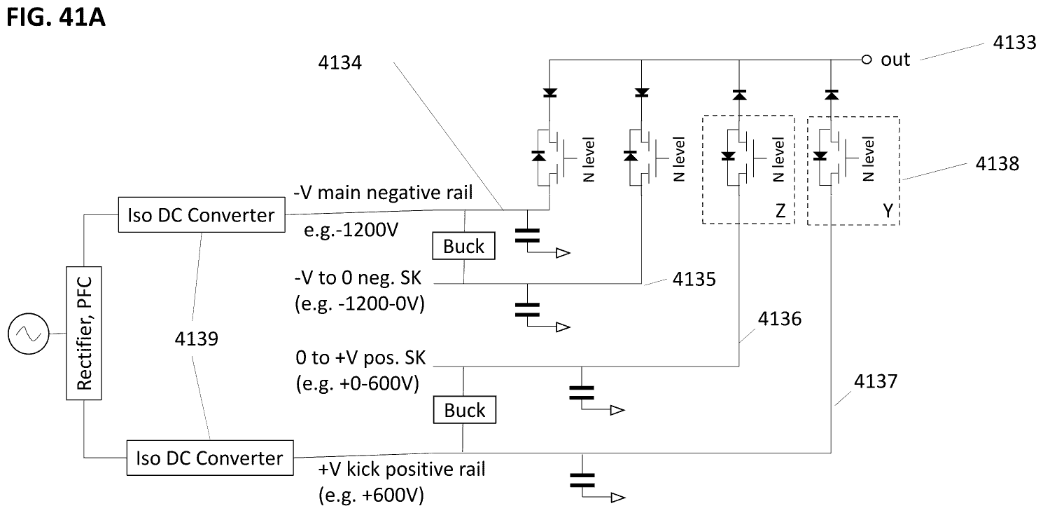

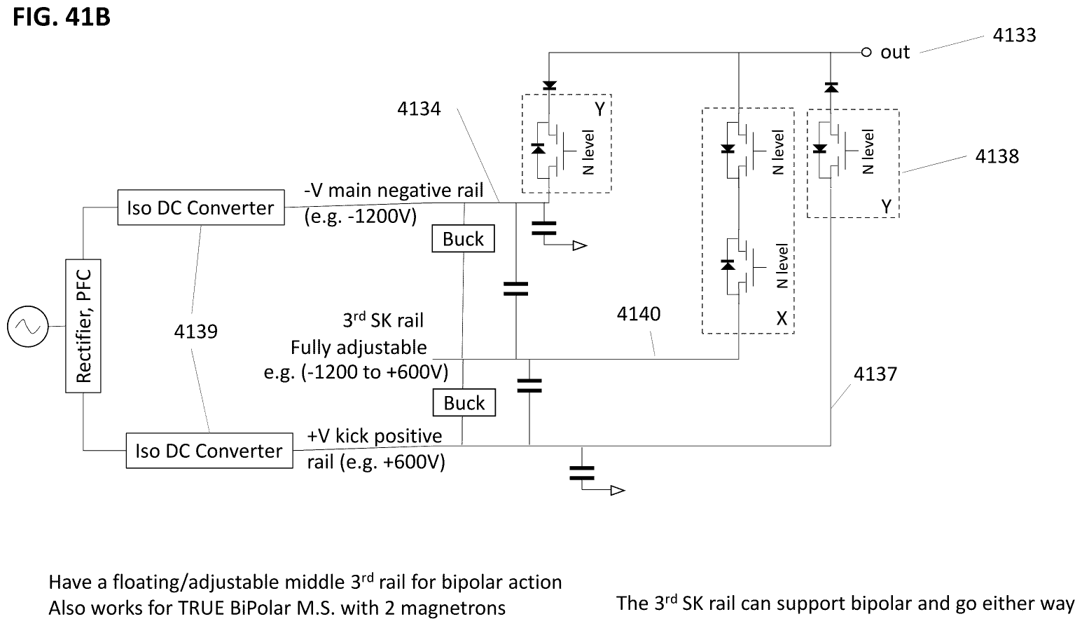

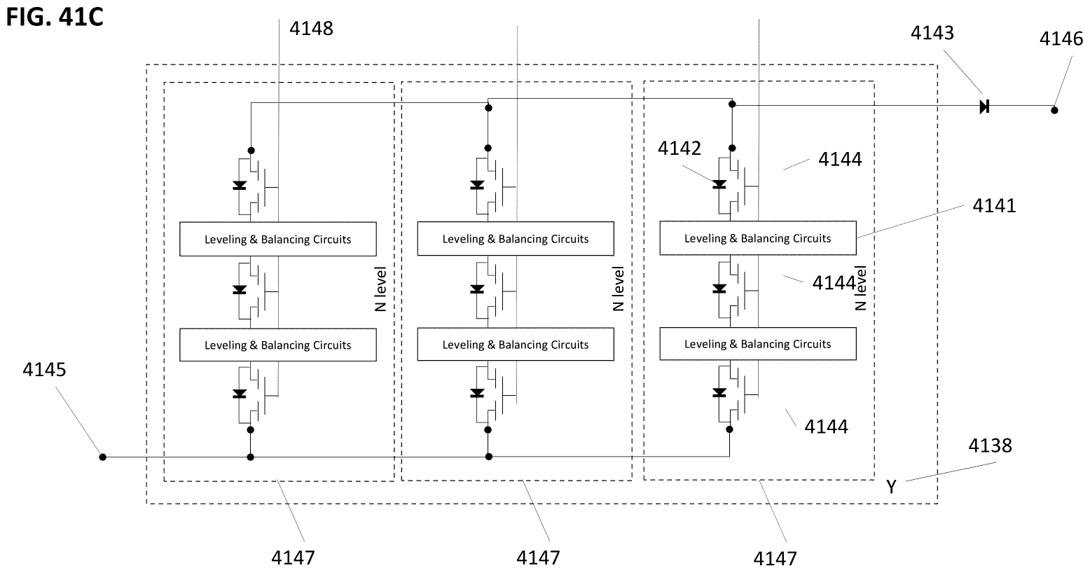

As shown in FIG. 41A, a controllable power supply apparatus for providing power via multiple discrete power sources (rails). The apparatus comprises multiple rails including a −V main negative rail 4134, a + kick positive rail 4137, and an intermediate super kick positive kick pulse rails, the −Vsk and +Vsk rails 4135 and 4136 respectively. Parallel runs of semiconductor high voltage (HV) switches arranged in series for HV standoff 4138 are used to pulse each of the four voltage rails. The power supply can use isolated DC converters for the low side and high side with buck converters for the super kick rails.

FIG. 41B shows a variation on the system of FIG. 41A with only 3 rails. However, in the 3-rail implementation, the positive kick pulse is generated by a floating adjustable rail 4140. In principle the operation of the circuit of FIG. 41B is substantially similar to the operation of the apparatus in FIG. 41A.

The apparatus can include multiple rails to gain higher duty factor for switching. The setup can also work for true bipolar operation where two magnetrons are run and one magnetron serves as the anode return path and the magnetrons flip/alternate roles. The switching topology is based on a platform with many discrete switches for speed, rapid shutoff and excellent arc handling vs. a monolithic brick that has slow response time, low slew di/dt rate and are arrest is problematic. The system can have many N level SiC switches/transistors operating in parallel to get TEMP, I_peak, I_avg, kHz. In one illustrative embodiment the system has a full adjustable super kick rail with +1200V main negative, and +600V positive kick.

Each set of N Level transistors 4138 is further detailed in an illustrative exemplary circuit diagram provided in FIG. 41C. An input line from an energy storage capacitor 4145 feeds multiple parallel N Level Transistor Switching Stacks 4147. Each of the N Level Transistor Switching Stack 4147 is comprised of 1 or more series connected transistors 4144 supported by series transistor leveling and balancing circuitry 4141 to achieve high-voltage switching standoff to support the voltage differentials between the energy storage capacitors 4145 and any other line voltages present on the output line to the output pulse rail 4146. Output blocking diodes 4143 are provided with the suitable polarity for positive or negative pulsing from the N Level Transistors in Parallel 4138. The number of parallel stacks in 4138 is denoted with the designator X or Y and can be as little as 1 to more than 100. In on embodiment, there are 20 N-Level Transistors in parallel 4138 supporting the main negative rail 4134, 20 supporting the positive kick rail 1137 and 5 supporting each of the positive 4137 and negative 4136 superkick rails.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Exemplary embodiments are described herein known to the inventors for carrying out the invention. Variations of these embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A system including a controlled power supply for generating electrical pulses for a plasma discharge source, the controlled power supply comprising:
an output pulse rail;
a direct current power source;
energy storage capacitors, coupled to the direct current power source, wherein the energy storage capacitors are configured to supply via corresponding power rails:
a main negative rail voltage,
a positive kick rail voltage, and
at least one intermediate rail voltage at a voltage amplitude between the main negative rail voltage and the positive kick rail voltage;
a controlled pulse power transistor group comprising:
a plurality of transistors interposed between the energy storage capacitors and the output pulse rail, and
a transmission control configured to control power transmission from the energy storage capacitors to the output pulse rail;
wherein the transmission control is configured to specify, in accordance with user-specified input, a positive kick pulse waveform, and
wherein the positive kick pulse waveform is defined by user-specified parameters that configure operation of the plurality of transistors to control timing and voltage of:
the positive kick rail voltage; and
the at least one intermediate rail voltage.

2. The system of claim 1, further comprising:
a vacuum apparatus containing a sputtering magnetron and a target electrode connected to the output pulse rail;
a substrate;
wherein the controlled power supply is configured to:
generate a high-power pulsed plasma magnetron discharge with application of the main negative rail voltage to the target electrode; and
generate a configurable positive kick pulse applied to the target electrode after applying a negative pulse, by adjusting at least one pulse property taken from the group consisting of: onset delay, duration, pulse width, pulse amplitude, short kick and long kick timing, pulse envelope, and frequency including modulation thereof.

3. The system of claim 1, wherein the controlled pulse power transistor group comprises a quantity Y of transistor switching stacks that can be modulated to fire sequentially or in series to adjust one of more properties of the group consisting of: peak power, peak current and pulse repetition frequency transferred to the output pulse rail.

4. The system of claim 3, wherein each of the Y transistor switching stacks comprises:
a quantity N levels of discrete transistors in series, and
leveling and balancing circuits.

5. The system of claim 2 wherein, during operation, a superkick mode for preionization is utilized to generate an RF-like voltage waveform to the magnetron sputtering target to excite and populate electrons near the magnetron prior to the initiation of the main negative dc pulse.

6. The system of claim 2 wherein, during operation, a superkick mode is selected for RF-like plasma sustainment and radical generation with controlled ion energy at the substrate.

7. The system of claim 2, wherein, during operation, a superkick mode is selected for etching.

8. The system of claim 2, wherein, during operation, a superkick mode is selected for metal implant with the short kick and shot-peening with the long kick.

9. The system of claim 2, wherein the ion energy distribution directed to the substrate is controlled by adjustment of the superkick rail pulse modulation frequency, superkick rail amplitude and positive rail amplitude.

10. A method for providing a pulse power waveform, carried out by a system including a controlled power supply for generating electrical pulses for a plasma discharge source,
wherein the controlled power supply comprises:
an output pulse rail;
a direct current power source;
energy storage capacitors, coupled to the direct current power source, wherein the energy storage capacitors are configured to supply via corresponding power rails:
a main negative rail voltage,
a positive kick rail voltage, and
at least one intermediate rail voltage at a voltage amplitude between the main negative rail voltage and the positive kick rail voltage;
a controlled pulse power transistor group comprising:
a plurality of transistors interposed between the energy storage capacitors and the output pulse rail, and
a transmission control configured to control power transmission from the energy storage capacitors to the output pulse rail;
wherein the transmission control is configured to specify, in accordance with user-specified input, a positive kick pulse waveform, and
wherein the method comprises operating the transmission control, in accordance with the user-specified input, to generate the positive kick pulse waveform that is defined by user-specified parameters that configure operation of the plurality of transistors to control timing and voltage of:
the positive kick rail voltage; and
the at least one intermediate rail voltage.

11. A method for performing surface modification on a substrate by generating and controlling ion flux for high-power impulse magnetron sputtering using superkick modes, wherein the method comprises:
providing a vacuum apparatus containing a sputtering magnetron and target electrode connected to the output pulse rail;
providing a substrate with a surface to be modified by this method;
generating a high-power pulsed plasma magnetron discharge with application of the main negative rail voltage amplitude to the target electrode; and
generating a configurable superkick pulse waveform to the magnetron target electrode after terminating the negative DC pulse to achieve a superkick mode,
wherein the configurable superkick pulse is carried out using capacitive stored power transmitted though one or more pulse power transistor groups to supply positive voltage, negative voltage, or both,
wherein during the generating, a control signal to adjusts at least one superkick pulse property taken from the group consisting of: onset delay, duration, pulse width, pulse amplitude, short kick and long kick timing, and frequency including modulation thereof.

12. The method of claim 11, further comprising:
configuring the superkick mode for enhanced plasma generation in target-substrate region with minimal substrate damage from ion energy;
configuring the positive kick rail in the range of positive 10-100V;
configuring the negative superkick rail in the range of negative 200-300V;
configuring the positive kick and negative superkick pulse period to be 5-50 us;
configuring the super kick pulse envelope to be 100-500 us in duration; and,
wherein the substrate surface is further modified by plasma bombardment.

13. The method of claim 11, further comprising:
configuring the superkick mode for substrate etching with enhanced ion energy;
configuring the positive kick rail in the range of positive 400-600V;
configuring the negative superkick rail in the range of negative 10 to 100V;
configuring the positive kick and negative superkick pulse period to be 5-20 us;
configuring the super kick pulse envelope to be 100-1000 us in duration; and,
wherein the substrate surface is further modified by plasma bombardment.

14. The method of claim 11, further comprising:
configuring the superkick mode for metal ion implantation with the short kick and surface shot peening and densification with the long kick;
configuring the positive kick rail in the range of positive 400-600V;
configuring the positive superkick rail in the range of negative 10 to 50V;
configuring the positive kick pulse width to be 5-20 us;
configurating the positive superkick pulse width to be 20-200 us in duration;
wherein the substrate surface is further modified by plasma bombardment.

15. The method of claim 11, further comprising:
configuring the superkick mode for deep metal ion implantation with the short kick, and performing enhanced plasma generation in target-substrate region with minimal substrate damage from ion energy;
configuring the positive kick rail in the range of positive 400-600V;
configuring the positive kick pulse width to be 5-20 us;
configuring the positive superkick rail in the range of positive 10-100V;
configuring the negative superkick rail in the range of negative 200-300V;
configuring the positive kick and negative superkick pulse period to be 5-50 us;
configuring the super kick pulse envelope to be 100-500 us in duration; and,
wherein the substrate surface is further modified by plasma bombardment.
